(19) United States
(12) Patent Application Publication
(10) Pub. No.: US 2025/0151371 A1
(43) Pub. Date: May 8, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Yun Ju FAN, Hsinchu City (TW); Lo-Heng CHANG, Hsinchu (TW); Huan-Chieh SU, Tianzhong Township (TW); Chih-Hao WANG, Baoshan Township (TW)

(21) Appl. No.: 18/428,603

(22) Filed: Jan. 31, 2024

Related U.S. Application Data
(60) Provisional application No. 63/595,905, filed on Nov. 3, 2023.

(51) Int. Cl. H01L 21/8238; H01L 27/092; H01L 29/06; H01L 29/423; H01L 29/45; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 62/83; H10D 64/62; H10D 84/0186; H10D 84/85

(57) ABSTRACT

Techniques described herein include forming respective (different) types of metal silicide layers for p-type source/drain regions and n-type source/drain regions of nanostructure transistors of a semiconductor device in a selective manner that reduces process complexity. For example, a p-type metal silicide layer may be selectively formed over a p-type source/drain region (e.g., such that the p-type metal silicide layer is not formed over the n-type source/drain region) of a first nanostructure transistor, and an n-type metal silicide layer may be formed over the n-type source/drain region (which may be selective or non-selective) of a second nanostructure transistor. This provides a low Schottky barrier height between the p-type metal silicide layer and the p-type source/drain region, as well as a low Schottky barrier height between the n-type metal silicide layer and the n-type source/drain region. This reduces the contact resistance for both p-type source/drain regions and n-type source/drain regions.

### CROSS-REFERENCE TO RELATED APPLICATION

This Patent application claims priority to U.S. Provisional Patent Application No. 63/595,905, filed on Nov. 3, 2023, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, nanoribbons, nanotubes, multi-bridge channels, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A and 3B are diagrams of an example implementation of a fin formation process described herein.

FIGS. 4A and 4B are diagrams of an example implementation of a shallow trench isolation (STI) process described herein.

FIGS. 5 and 6 are diagrams of an example dummy gate structure formation process described herein.

FIGS. 7A-7D are diagrams of example implementations of a source/drain recess formation process and an inner spacer formation process described herein.

FIG. 8 is a diagram of an example implementation of a source/drain region formation process described herein.

FIG. 9 is a diagram of an example implementation of an interlayer dielectric layer formation process described herein.

FIGS. 10A-10C are diagrams of an example implementation of a replacement gate process described herein.

FIGS. 11A-11I are diagrams of an example implementation of a forming a semiconductor device described herein.

FIGS. 12A-12L are diagrams of an example implementation of a forming a semiconductor device described herein.

FIGS. 13A-13H are diagrams of an example implementation of a forming a semiconductor device described herein.

FIGS. 14A-14L are diagrams of an example implementation of a forming a semiconductor device described herein.

FIG. 15 is a diagram of example components of one or more devices described herein.

FIGS. 16-18 are flowcharts of example processes associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A metal silicide layer may be formed on a top surface of a source/drain region (e.g., an epitaxial region) of a nanostructure transistor prior to formation of a source/drain contact (e.g., a source/drain contact) over the source/drain region. The metal silicide layer may be included so that a low contact resistance can be achieved between a source/drain region and the source/drain contact through Schottky barrier height tuning. The top surface of the source/drain region may be prepared for the metal silicide using a pre-clean process (e.g., an epitaxial pre-clean process, a silicide pre-clean process) to remove residual oxides and other contaminates. After the pre-clean process, a metal layer is formed over the source/drain region, and the wafer is subjected to a high temperature anneal which causes the metal to react with silicon to form the metal silicide layer.

The source/drain regions of nanostructure transistors included in a semiconductor device may be doped with different types of dopants. For example, source/drain regions of a first nanostructure transistor may be doped with a p-type material, and source/drain regions of a second nanostructure transistor may be doped with an n-type material. As a result, if the same type of metal silicide layer is used for both types of source/drain regions (e.g., p-type source/drain regions and n-type source/drain regions), the intrinsic thermionic barrier of the metal silicide layer used for the source/drain regions will be preferential to either n-type source/drain regions or p-type source/drain regions but not both. This can lead to different thermionic barrier properties for the n-type source/drain regions and the p-type source/drain regions, which can result in increased contact resistance for a particular type of source/drain region.

As an example, an n-type metal silicide layer formed over an n-type source/drain region of a first nanostructure transistor may provide a low n-type Schottky barrier height Φ_{Bn}—the distance between the conduction band edge (E_{C}) and the Fermi energy level (E_{F})) at the junction between the n-type metal silicide layer and the n-type source/drain region, and therefore a low contact resistance (e.g., because the junction functions as an ohmic junction). However, the same n-type metal silicide layer over a p-type source/drain region of a second nanostructure transistor may provide a p-type high Schottky barrier height (ΦBₚ—the distance between the valance band edge (E_{V}) and the Fermi energy level (E_{F})) at the junction between the n-type metal silicide layer and the p-type source/drain region, and therefore a high contact resistance because the junction functions as a rectifier junction (e.g., a p-n junction or diode).

Some implementations described herein provide semiconductor manufacturing techniques and associated semiconductor structures for selective dual silicide formation in a semiconductor device. The techniques described herein include forming respective (different) types of metal silicide layers for p-type source/drain regions and n-type source/drain regions of nanostructure transistors of a semiconductor device in a selective manner that reduces process complexity. For example, a p-type metal silicide layer may be selectively formed over a p-type source/drain region (e.g., such that the p-type metal silicide layer is not formed over the n-type source/drain region) of a first nanostructure transistor, and an n-type metal silicide layer may be formed over the n-type source/drain region (which may be selective or non-selective) of a second nanostructure transistor. This provides a low Schottky barrier height between the p-type metal silicide layer and the p-type source/drain region, as well as a low Schottky barrier height between the n-type metal silicide layer and the n-type source/drain region. This reduces the contact resistance for both p-type source/drain regions and n-type source/drain regions.

Some selective dual silicide formation techniques described herein enable a p-type metal silicide layer and an n-type metal silicide layer to be formed in-situ, in that the operations for forming the p-type metal silicide layer and the n-type metal silicide layer are performed under the same vacuum (e.g., without breaking the vacuum between the p-type metal silicide layer formation operation and the n-type metal silicide layer formation operation). This enables the dual silicide formation operations to be performed with only a single pre-clean operation prior to the p-type metal silicide layer formation operation (e.g., as opposed to performing a second pre-clean operation between the p-type metal silicide layer formation operation and the n-type metal silicide layer formation operation, which would be performed to clean the n-type source/drain regions due to breaking the vacuum between operations). This reduces process complexity and reduces the likelihood of dielectric damage and critical dimension enlargement. Moreover, this enables the vacuum to be maintained such that a metal barrier layer for the p-type metal silicide layer and the n-type metal silicide layer may be formed in the same operation, which further reduces process complexity. In addition, the selective dual silicide formation techniques described herein enable precise and independent thickness control to form the p-type metal silicide layer and the n-type metal silicide layer to optimal thicknesses.

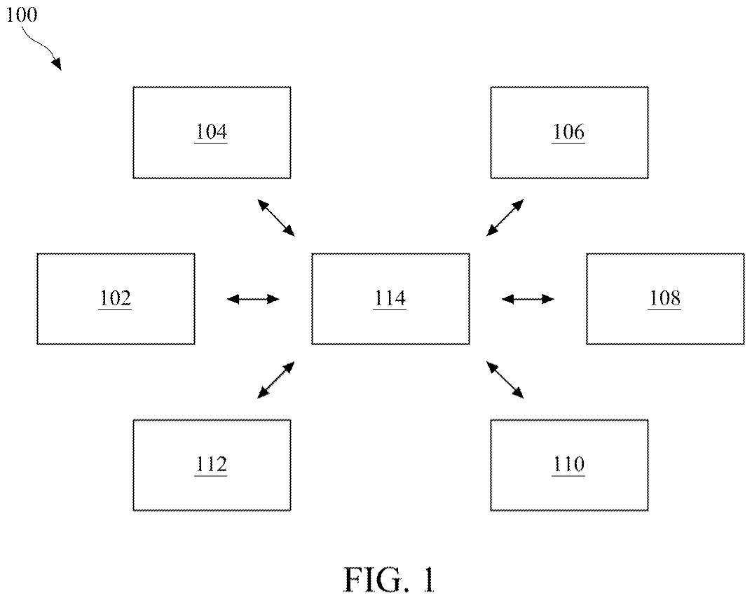

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that can be filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material and/or another material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

As described herein, the semiconductor processing tools 102-112 may perform a combination of operations to form one or more portions of a nanostructure transistor. In some implementations, the combination of operations includes forming a plurality of nanostructure channel layers that are arranged in a direction that is approximately perpendicular to a semiconductor substrate of a semiconductor device; forming a p-type source/drain region adjacent to the plurality of nanostructure channel layers; forming an n-type source/drain region adjacent to the plurality of nanostructure channel layers; forming a gate structure wrapping around each of the plurality of nanostructure channel layers; forming a p-type metal silicide layer on the p-type source/drain region; and/or forming an n-type metal silicide layer on the n-type source/drain region after forming the p-type metal silicide layer on the p-type source/drain region, among other examples.

In some implementations, the combination of operations includes forming a plurality of nanostructure channel layers that are arranged in a direction that is approximately perpendicular to a semiconductor substrate of a semiconductor device; forming a p-type source/drain region adjacent to the plurality of nanostructure channel layers; forming an n-type source/drain region adjacent to the plurality of nanostructure channel layers; forming a gate structure wrapping around each of the plurality of nanostructure channel layers; forming a masking layer on the p-type source/drain region; forming a first metal silicide layer on the n-type source/drain region while the masking layer protects the p-type source/drain region, where the first metal silicide layer comprises an n-type metal silicide; removing, after forming the first metal silicide layer, the masking layer from the p-type source/drain region; and/or forming, after removing the masking layer, a second metal silicide layer on the p-type source/drain region, among other examples.

In some implementations, the combination of operations includes forming a plurality of nanostructure channel layers that are arranged in a direction that is approximately perpendicular to a semiconductor substrate of a semiconductor device; forming a p-type source/drain region adjacent to the plurality of nanostructure channel layers; forming an n-type source/drain region adjacent to the plurality of nanostructure channel layers; forming a gate structure wrapping around each of the plurality of nanostructure channel layers; forming a first metal silicide layer on the p-type source/drain region and on the n-type source/drain region, where the first metal silicide layer includes a first metal type; and/or forming a second metal silicide layer on the first metal silicide layer over the p-type source/drain region and the n-type source/drain region, where the second metal silicide layer includes a second metal type that is different from the first metal type, among other examples.

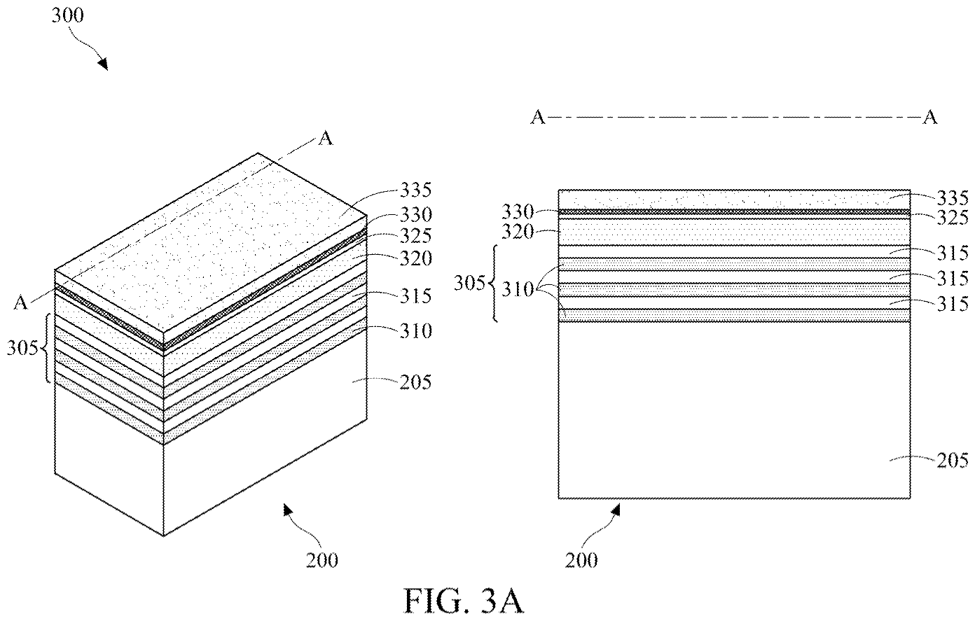

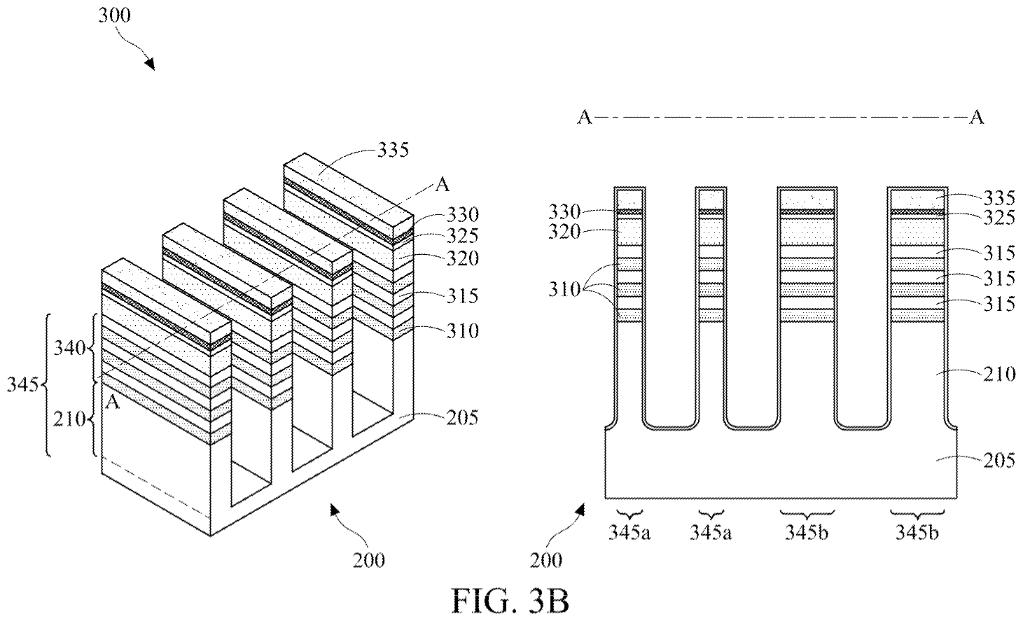

In some implementations, the combination of operations includes one or more operations described in connection with one or more of FIGS. 3A, 3B, 4A, 4B, 5, 6, 7A-7D, 8, 9, 10A-10C, 11A-11I, 12A-12L, 13A-13H, 14A-14L, 16, 17, and/or 18, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

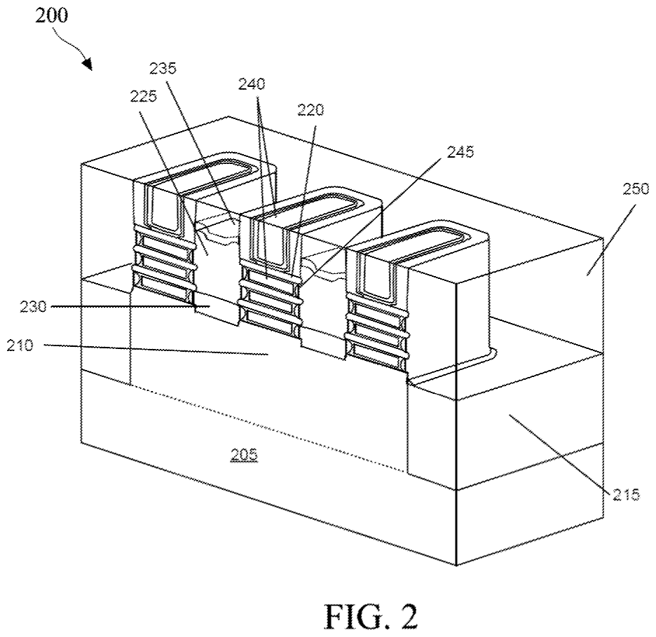

FIG. 2 is a diagram of an example semiconductor device 200 described herein. The semiconductor device 200 includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 200 may include one or more additional devices, structures, and/or layers not shown in FIG. 2. For example, the semiconductor device 200 may include additional layers and/or dies formed on layers above and/or below the portion of the semiconductor device 200 shown in FIG. 2. Additionally, or alternatively, one or more additional semiconductor structures and/or semiconductor devices may be formed in a same layer of an electronic device or integrated circuit (IC) that includes the semiconductor device as the semiconductor device 200 shown in FIG. 2. One or more of FIGS. 3A-12B may include schematic cross-sectional views of various portions of the semiconductor device 200 illustrated in FIG. 2, and correspond to various processing stages of forming nanostructure transistors of the semiconductor device 200.

The semiconductor device 200 includes a semiconductor substrate 205. The semiconductor substrate 205 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The semiconductor substrate 205 may include various layers, including conductive or insulating layers formed on a semiconductor substrate. The semiconductor substrate 205 may include a compound semiconductor and/or an alloy semiconductor. The semiconductor substrate 205 may include various doping configurations to satisfy one or more design parameters. For example, different doping profiles (e.g., n-wells, p-wells) may be formed on the semiconductor substrate 205 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 205 may include an epitaxial layer (epi-layer), may be strained for performance enhancement, and/or may have other suitable enhancement features. The semiconductor substrate 205 may include a portion of a semiconductor wafer on which other semiconductor devices are formed.

Mesa regions 210 are included above (and/or extend above) the semiconductor substrate 205. A mesa region 210 provides a structure on which nanostructures of the semiconductor device 200 are formed, such as nanostructure channels, nanostructure gate portions that wrap around each of the nanostructure channels, and/or sacrificial nanostructures, among other examples. In some implementations, one or more mesa regions 210 are formed in and/or from a fin structure (e.g., a silicon fin structure) that is formed in the semiconductor substrate 205. The mesa regions 210 may include the same material as the semiconductor substrate 205 and are formed from the semiconductor substrate 205. In some implementations, the mesa regions 210 are doped to form different types of nanostructure transistors, such as p-type nanostructure transistors and/or n-type nanostructure transistors. In some implementations, the mesa regions 210 include silicon (Si) materials or another elementary semiconductor material such as germanium (Ge). In some implementations, the mesa regions 210 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The mesa regions 210 are fabricated by suitable semiconductor process techniques, such as masking, photolithography, and/or etch processes, among other examples. As an example, fin structures may be formed by etching a portion of the semiconductor substrate 205 away to form recesses in the semiconductor substrate 205. The recesses may then be filled with isolating material that is recessed or etched back to form shallow trench isolation (STI) regions 215 above the semiconductor substrate 205 and between the fin structures. Source/drain recesses may be formed in the fin structures, which results in formation of the mesa regions 210 between the source/drain recesses. However, other fabrication techniques for the STI regions 215 and/or for the mesa regions 210 may be used.

The STI regions 215 may electrically isolate adjacent fin structures and may provide a layer on which other layers and/or structures of the semiconductor device 200 are formed. The STI regions 215 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 215 may include a multi-layer structure, for example, having one or more liner layers.

The semiconductor device 200 includes a plurality of nanostructure channels 220 that extend between, and are electrically coupled with, source/drain regions 225. Source/drain region(s) may refer to a source or a drain, individually or collectively dependent upon the context. The nanostructure channels 220 are arranged in a direction that is approximately perpendicular to the semiconductor substrate 205. In other words, the nanostructure channels 220 are vertically arranged or stacked above the semiconductor substrate 205.

The nanostructure channels 220 include silicon-based nanostructures (e.g., nanosheets or nanowires, among other examples) that function as the semiconductive channels of the nanostructure transistor(s) of the semiconductor device 200. In some implementations, the nanostructure channels 220 may include silicon germanium (SiGe) or another silicon-based material. The source/drain regions 225 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions, n-type metal-oxide semiconductor (NMOS) nanostructure transistors that include n-type source/drain regions, and/or other types of nanostructure transistors.

In some implementations, a buffer region 230 is included under a source/drain region 225 between the source/drain region 225 and a fin structure above the semiconductor substrate 205. A buffer region 230 may provide isolation between a source/drain region 225 and adjacent mesa regions 210. A buffer region 230 may be included to reduce, minimize, and/or prevent electrons from traversing into the mesa regions 210 (e.g., instead of through the nanostructure channels 220, thereby reducing current leakage), and/or may be included to reduce, minimize and/or prevent dopants from the source/drain region 225 into the mesa regions 210 (which reduces short channel effects).

A capping layer 235 may be included over and/or on the source/drain region 225. The capping layer 235 may include silicon, silicon germanium, doped silicon, doped silicon germanium, and/or another material. The capping layer 235 may be included to reduce dopant diffusion and to protect the source/drain regions 225 in semiconductor processing operations for the semiconductor device 200 prior to contact formation. Moreover, the capping layer 235 may contribute to metal-semiconductor (e.g., silicide) alloy formation.

At least a subset of the nanostructure channels 220 extend through one or more gate structures 240. The gate structures 240 may be formed of one or more metal materials, one or more high dielectric constant (high-k) materials, and/or one or more other types of materials. In some implementations, dummy gate structures (e.g., polysilicon (PO) gate structures or another type of gate structures) are formed in the place of (e.g., prior to formation of) the gate structures 240 so that one or more other layers and/or structures of the semiconductor device 200 may be formed prior to formation of the gate structures 240. This reduces and/or prevents damage to the gate structures 240 that would otherwise be caused by the formation of the one or more layers and/or structures. A replacement gate process (RGP) is then performed to remove the dummy gate structures and replace the dummy gate structures with the gate structures 240 (e.g., replacement gate structures).

As further shown in FIG. 2, portions of a gate structure 240 are formed in between pairs of nanostructure channels 220 in an alternating vertical arrangement. In other words, the semiconductor device 200 includes one or more vertical stacks of alternating nanostructure channels 220 and portions of a gate structure 240, as shown in FIG. 2. In this way, a gate structure 240 wraps around an associated nanostructure channel 220 on multiple sides of the nanostructure channel 220 which increases control of the nanostructure channel 220, increases drive current for the nanostructure transistor(s) of the semiconductor device 200, and reduces short channel effects (SCEs) for the nanostructure transistor(s) of the semiconductor device 200.

Some source/drain regions 225 and gate structures 240 may be shared between two or more nanoscale transistors of the semiconductor device 200. In these implementations, one or more source/drain regions 225 and a gate structure 240 may be connected or coupled to a plurality of nanostructure channels 220, as shown in the example in FIG. 2. This enables the plurality of nanostructure channels 220 to be controlled by a single gate structure 240 and a pair of source/drain regions 225.

Inner spacers (InSP) 245 may be included between a source/drain region 225 and an adjacent gate structure 240. In particular, inner spacers 245 may be included between a source/drain region 225 and portions of a gate structure 240 that wrap around a plurality of nanostructure channels 220. The inner spacers 245 are included on ends of the portions of the gate structure 240 that wrap around the plurality of nanostructure channels 220. The inner spacers 245 are included in cavities that are formed in between end portions of adjacent nanostructure channels 220. The inner spacer 245 are included to reduce parasitic capacitance and to protect the source/drain regions 225 from being etched in a nanosheet release operation to remove sacrificial nanosheets between the nanostructure channels 220. The inner spacers 245 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The semiconductor device 200 may also include an inter-layer dielectric (ILD) layer 250 above the STI regions 215. The ILD layer 250 may be referred to as an ILDO layer. The ILD layer 250 surrounds the gate structures 240 to provide electrical isolation and/or insulation between the gate structures 240 and/or the source/drain regions 225, among other examples. Conductive structures such as contacts and/or interconnects may be formed through the ILD layer 250 to the source/drain regions 225 and the gate structures 240 to provide control of the source/drain regions 225 and the gate structures 240.

As indicated above, FIG. 2 is provided as an example. Other examples may differ from what is described with regard to FIG. 2.

FIGS. 3A and 3B are diagrams of an example implementation 300 of a fin formation process described herein. The example implementation 300 includes an example of forming fin structures for the semiconductor device 200 or a portion thereof. The semiconductor device 200 may include one or more additional devices, structures, and/or layers not shown in FIGS. 3A and 3B. The semiconductor device 200 may include additional layers and/or dies formed on layers above and/or below the portion of the semiconductor device 200 shown in FIGS. 3A and 3B. Additionally, or alternatively, one or more additional semiconductor structures and/or semiconductor devices may be formed in a same layer of an electronic device that includes the semiconductor device 200.

FIG. 3A illustrates a perspective view of the semiconductor device 200 and a cross-sectional view along the line A-A in the perspective view. As shown in FIGS. 3A, processing of the semiconductor device 200 is performed in connection with the semiconductor substrate 205. A layer stack 305 is formed on the semiconductor substrate 205. The layer stack 305 may be referred to as a superlattice. In some implementations, one or more operations are performed in connection with the semiconductor substrate 205 prior to formation of the layer stack 305. For example, an anti-punch through (APT) implant operation may be performed. The APT implant operation may be performed in one or more regions of the semiconductor substrate 205 above which the nanostructure channels 220 are to be formed. The APT implant operation is performed, for example, to reduce and/or prevent punch-through or unwanted diffusion into the semiconductor substrate 205.

The layer stack 305 includes a plurality of alternating layers that are arranged in a direction that is approximately perpendicular to the semiconductor substrate 205. For example, the layer stack 305 includes vertically alternating layers of first layers 310 and second layers 315 above the semiconductor substrate 205. The quantity of the first layers 310 and the quantity of the second layers 315 illustrated in FIG. 3A are examples, and other quantities of the first layers 310 and the second layers 315 are within the scope of the present disclosure. In some implementations, the first layers 310 and the second layers 315 are formed to different thicknesses. For example, the second layers 315 may be formed to a thickness that is greater relative to a thickness of the first layers 310. In some implementations, the first layers 310 (or a subset thereof) are formed to a thickness in a range of approximately 4 nanometers to approximately 7 nanometers. In some implementations, the second layers 315 (or a subset thereof) are formed to a thickness in a range of approximately 8 nanometers to approximately 12 nanometers. However, other values for the thickness of the first layers 310 and for the thickness of the second layers 315 are within the scope of the present disclosure.

The first layers 310 include a first material composition, and the second layers 315 include a second material composition. In some implementations, the first material composition and the second material composition are the same material composition. In some implementations, the first material composition and the second material composition are different material compositions. As an example, the first layers 310 may include silicon germanium (SiGe) and the second layers 315 may include silicon (Si). In some implementations, the first material composition and the second material composition have different oxidation rates and/or etch selectivity.

As described herein, the second layers 315 may be processed to form the nanostructure channel 220 for subsequently-formed nanostructure transistors of the semiconductor device 200. The first layers 310 are sacrificial nanostructures that are eventually removed and serve to define a vertical distance between adjacent nanostructure channels 220 for a subsequently-formed gate structure 240 of the semiconductor device 200. Accordingly, the first layers 310 are referred to herein as sacrificial layers, and the second layers 315 may be referred to as channel layers.

The deposition tool 102 deposits and/or grows the alternating layers of the layer stack 305 to include nanostructures (e.g., nanosheets) on the semiconductor substrate 205. For example, the deposition tool 102 grows the alternating layers by epitaxial growth. However, other processes may be used to form the alternating layers of the layer stack 305. Epitaxial growth of the alternating layers of the layer stack 305 may be performed by a molecular beam epitaxy (MBE) process, a metalorganic chemical vapor deposition (MOCVD) process, and/or another suitable epitaxial growth process. In some implementations, the epitaxially grown layers such as the second layers 315 include the same material as the material of the semiconductor substrate 205. In some implementations, the first layers 310 and/or the second layers 315 include a material that is different from the material of the semiconductor substrate 205. As described above, in some implementations, the first layers 310 include epitaxially grown silicon germanium (SiGe) layers and the second layers 315 include epitaxially grown silicon (Si) layers. Alternatively, the first layers 310 and/or the second layers 315 may include other materials such as germanium (Ge), a compound semiconductor material such as silicon carbide (SiC), gallium arsenide (GaAs), gallium phosphide (GaP), indium phosphide (InP), indium arsenide (InAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The material(s) of the first layers 310 and/or the material(s) of the second layers 315 may be chosen based on providing different oxidation properties, different etching selectivity properties, and/or other different properties.

As further shown in FIG. 3A, the deposition tool 102 may form one or more additional layers over and/or on the layer stack 305. For example, a hard mask (HM) layer 320 may be formed over and/or on the layer stack 305 (e.g., on the top-most second layer 315 of the layer stack 305). As another example, a capping layer 325 may be formed over and/or on the hard mask layer 320. As another example, another hard mask layer including an oxide layer 330 and a nitride layer 335 may be formed over and/or on the capping layer 325. The one or more hard mask (HM) layers 320, 325, 330, and 335 may be used to form one or more structures of the semiconductor device 200. The oxide layer 330 may function as an adhesion layer between the layer stack 305 and the nitride layer 335, and may act as an etch stop layer for etching the nitride layer 335. The one or more hard mask layers 320, 325, 330, and 335 may include silicon germanium (SiGe), a silicon nitride (SiₓN_{y}), a silicon oxide (SiOₓ), and/or another material. The capping layer 325 may include silicon (Si) and/or another material. In some implementations, the capping layer 325 is formed of the same material as the semiconductor substrate 205. In some implementations, the one or more additional layers are thermally grown, deposited by CVD, PVD, ALD, and/or are formed using another deposition technique.

FIG. 3B illustrates a perspective view of the semiconductor device 200 and a cross-sectional view along the line A-A. As shown in FIG. 3B, the layer stack 305 and the semiconductor substrate 205 are etched to remove portions of the layer stack 305 and portions of the semiconductor substrate 205. The portions 340 of the layer stack 305, and mesa regions 210 (also referred to as silicon mesas or mesa portions), remaining after the etch operation are referred to a fin structures 345 above the semiconductor substrate 205 of the semiconductor device 200. A fin structure 345 includes a portion 340 of the layer stack 305 over and/or on a mesa region 210 formed in and/or above the semiconductor substrate 205. The fin structures 345 may be formed by any suitable semiconductor processing technique. For example, the deposition tool 102, the exposure tool 104, the developer tool 106, and/or the etch tool 108 may form the fin structures 345 using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

In some implementations, the deposition tool 102 forms a photoresist layer over and/or on the hard mask layer including the oxide layer 330 and the nitride layer 335, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking element (or pattern) in the photoresist layer. In some implementations, patterning the photoresist layer to form the masking element is performed using an electron beam (e-beam) lithography process. The masking element may then be used to protect portions of the semiconductor substrate 205 and portions the layer stack 305 in an etch operation such that the portions of the semiconductor substrate 205 and portions the layer stack 305 remain non-etched to form the fin structures 345. Unprotected portions of the substrate and unprotected portions of the layer stack 305 are etched (e.g., by the etch tool 108) to form trenches in the semiconductor substrate 205. The etch tool may etch the unprotected portions of the substrate and unprotected portions of the layer stack 305 using a dry etch technique (e.g., reactive ion etching), a wet etch technique, and/or a combination thereof.

In some implementations, another fin formation technique is used to form the fin structures 345. For example, a fin region may be defined (e.g., by mask or isolation regions), and the portions 340 may be epitaxially grown in the form of the fin structures 345. In some implementations, forming the fin structures 345 includes a trim process to decrease the width of the fin structures 345. The trim process may include wet and/or dry etching processes, among other examples.

As further shown in FIG. 3B, fin structures 345 may be formed for different types of nanostructure transistors for the semiconductor device 200. In particular, a first subset of fin structures 345a may be formed for p-type nanostructure transistors (e.g., p-type metal oxide semiconductor (PMOS) nanostructure transistors), and a second subset of fin structures 345b may be formed for n-type nanostructure transistors (e.g., n-type metal oxide semiconductor (NMOS) nanostructure transistors). The second subset of fin structures 345b may be doped with a p-type dopant (e.g., boron (B) and/or germanium (Ge), among other examples) and the first subset of fin structures 345a may be doped with an n-type dopant (e.g., phosphorous (P) and/or arsenic (As), among other examples). Additionally or alternatively, p-type source/drain regions may be subsequently formed for the p-type nanostructure transistors that include the first subset of fin structures 345a, and n-type source/drain regions may be subsequently formed for the n-type nanostructure transistors that include the second subset of fin structures 345b.

The first subset of fin structures 345a (e.g., PMOS fin structures) and the second subset of fin structures 345b (e.g., NMOS fin structures) may be formed to include similar properties and/or different properties. For example, the first subset of fin structures 345a may be formed to a first height and the second subset of fin structures 345b may be formed to a second height, where the first height and the second height are different heights. As another example, the first subset of fin structures 345a may be formed to a first width and the second subset of fin structures 345b may be formed to a second width, where the first width and the second width are different widths. In the example shown in FIG. 3B, the second width of the second subset of fin structures 345b (e.g., for the NMOS nanostructure transistors) is greater relative to the first width of the first subset of fin structures 345a (e.g., for the PMOS nanostructure transistors). However, other examples are within the scope of the present disclosure.

As indicated above, FIGS. 3A and 3B are provided as an example. Other examples may differ from what is described with regard to FIGS. 3A and 3B. Example implementation 300 may include additional operations, fewer operations, different operations, and/or a different order of operations than those described in connection with FIGS. 3A and 3B.

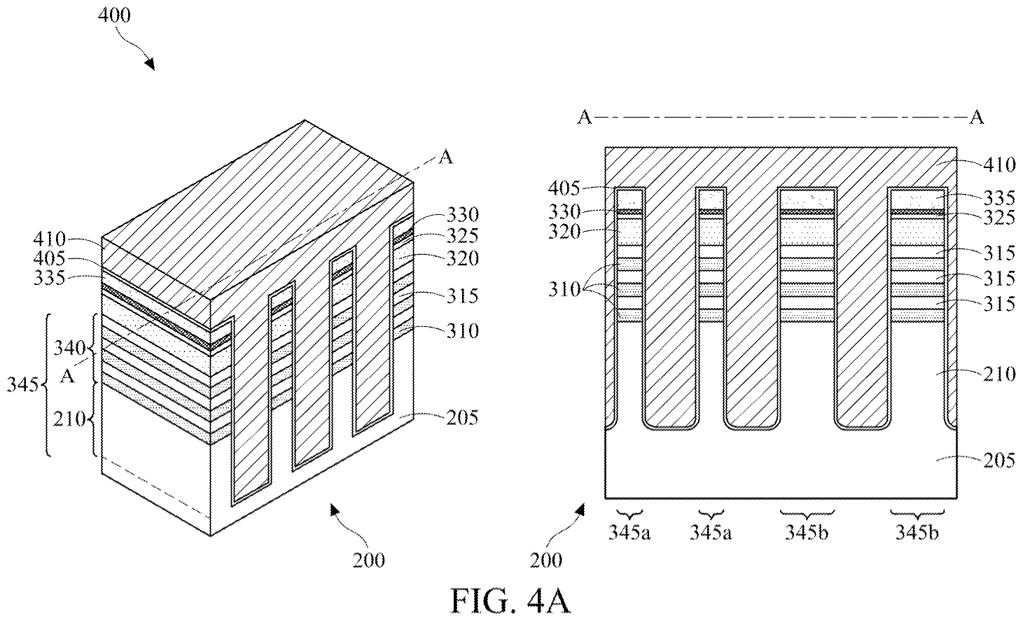

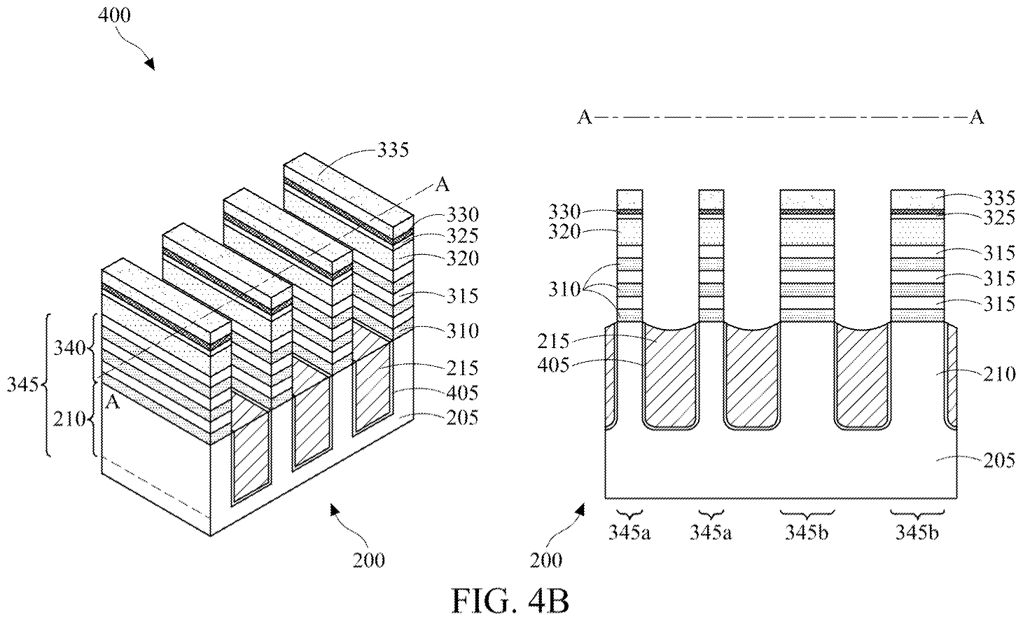

FIGS. 4A and 4B are diagrams of an example implementation 400 of an STI formation process described herein. The example implementation 400 includes an example of forming STI regions 215 between the fin structures 345 for the semiconductor device 200 or a portion thereof. The semiconductor device 200 may include one or more additional devices, structures, and/or layers not shown in FIGS. 4A and/or 4B. The semiconductor device 200 may include additional layers and/or dies formed on layers above and/or below the portion of the semiconductor device 200 shown in FIGS. 4A and 4B. Additionally, or alternatively, one or more additional semiconductor structures and/or semiconductor devices may be formed in a same layer of an electronic device that includes the semiconductor device 200. In some implementations, the operations described in connection with the example implementation 400 are performed after the processes described in connection with FIGS. 3A and 3B.

FIG. 4A illustrates a perspective view of the semiconductor device 200 and a cross-sectional view along the line A-A. As shown in FIG. 4A, a liner 405 and a dielectric layer 410 are formed above the semiconductor substrate 205 and interposing (e.g., in between) the fin structures 345. The deposition tool 102 may deposit the liner 405 and the dielectric layer 410 over the semiconductor substrate 205 and in the trenches between the fin structures 345. The deposition tool 102 may form the dielectric layer 410 such that a height of a top surface of the dielectric layer 410 and a height of a top surface of the nitride layer 335 are approximately a same height.

Alternatively, the deposition tool 102 may form the dielectric layer 410 such that the height of the top surface of the dielectric layer 410 is greater relative to the height of the top surface of the nitride layer 335, as shown in FIG. 4A. In this way, the trenches between the fin structures 345 are overfilled with the dielectric layer 410 to ensure the trenches are fully filled with the dielectric layer 410. Subsequently, the planarization tool 110 may perform a planarization or polishing operation (e.g., a CMP operation) to planarize the dielectric layer 410. The nitride layer 335 of the hard mask layer may function as a CMP stop layer in the operation. In other words, the planarization tool 110 planarizes the dielectric layer 410 until reaching the nitride layer 335 of the hard mask layer. Accordingly, a height of top surfaces of the dielectric layer 410 and a height of top surfaces of the nitride layer 335 are approximately equal after the operation.

The deposition tool 102 may deposit the liner 405 using a conformal deposition technique. The deposition tool 102 may deposit the dielectric layer using a CVD technique (e.g., a flowable CVD (FCVD) technique or another CVD technique), a PVD technique, an ALD technique, and/or another deposition technique. In some implementations, after deposition of the liner 405, the semiconductor device 200 is annealed, for example, to increase the quality of the liner 405.

The liner 405 and the dielectric layer 410 each includes a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. In some implementations, the dielectric layer 410 may include a multi-layer structure, for example, having one or more liner layers.

FIG. 4B illustrates a perspective view of the semiconductor device 200 and a cross-sectional view along the line A-A. As shown in FIG. 4B, an etch back operation is performed to remove portions of the liner 405 and portions of the dielectric layer 410 to form the STI regions 215. The etch tool 108 may etch the liner 405 and the dielectric layer 410 in the etch back operation to form the STI regions 215. The etch tool 108 etches the liner 405 and the dielectric layer 410 based on the hard mask layer (e.g., the hard mask layer including the oxide layer 330 and the nitride layer 335). The etch tool 108 etches the liner 405 and the dielectric layer 410 such that the height of the STI regions 215 are less than or approximately a same height as the bottom of the portions 340 of the layer stack 305. Accordingly, the portions 340 of the layer stack 305 extend above the STI regions 215. In some implementations, the liner 405 and the dielectric layer 410 are etched such that the heights of the STI regions 215 are less than heights of top surfaces of the mesa regions 210.

In some implementations, the etch tool 108 uses a dry etch technique to etch the liner 405 and the dielectric layer 410. Ammonia (NH₃), hydrofluoric acid (HF), and/or another etchant may be used. The plasma-based dry etch technique may result in a reaction between the etchant(s) and the material of the liner 405 and the dielectric layer 410, including:

SiO₂+4HF→SiF₄+2H₂O

where silicon dioxide (SiO₂) of the liner 405 and the dielectric layer 410 react with hydrofluoric acid to form byproducts including silicon tetrafluoride (SiF₄) and water (H₂O). The silicon tetrafluoride is further broken down by the hydrofluoric acid and ammonia to form an ammonium fluorosilicate ((NH₄)₂SiF₆) byproduct:

SiF₄+2HF+2NH₃→(NH₄)₂SiF₆

The ammonium fluorosilicate byproduct is removed from a processing chamber of the etch tool 108. After removal of the ammonium fluorosilicate, a post-process temperature in a range of approximately 100 degrees Celsius to approximately 250 degrees Celsius is used to sublimate the ammonium fluorosilicate into constituents of silicon tetrafluoride ammonia and hydrofluoric acid.

In some implementations, the etch tool 108 etches the liner 405 and the dielectric layer 410 such that a height of the STI regions 215 between the first subset of fin structures 345a (e.g., for the PMOS nanostructure transistors) is greater relative to a height of the STI regions 215 between the second subset of fin structures 345b (e.g., for the NMOS nanostructure transistors). This primarily occurs due to the greater width the fin structures 345b relative to the width of the fin structures 345a. Moreover, this results in a top surface of an STI region 215 between a fin structure 345a and a fin structure 345b being sloped or slanted (e.g., downward sloped from the fin structure 345a to the fin structure 345b, as shown in the example in FIG. 4B). The etchants used to etch the liner 405 and the dielectric layer 410 first experience physisorption (e.g., a physical bonding to the liner 405 and the dielectric layer 410) as a result of a Van der Waals force between the etchants and the surfaces of the liner 405 and the dielectric layer 410. The etchants become trapped by dipole moment force. The etchants then attach to dangling bonds of the liner 405 and the dielectric layer 410, and chemisorption begins. Here, the chemisorption of the etchant on the surface of the liner 405 and the dielectric layer 410 results in etching of the liner 405 and the dielectric layer 410. The greater width of the trenches between the second subset of fin structures 345b provides a greater surface area for chemisorption to occur, which results in a greater etch rate between the second subset of fin structures 345b. The greater etch rate results in the height of the STI regions 215 between the second subset of fin structures 345b being lesser relative to the height of the STI regions 215 between the first subset of fin structures 345a.

As indicated above, FIGS. 4A and 4B are provided as an example. Other examples may differ from what is described with regard to FIGS. 4A and 4B. Example implementation 400 may include additional operations, fewer operations, different operations, and/or a different order of operations than those described in connection with FIGS. 4A and 4B.

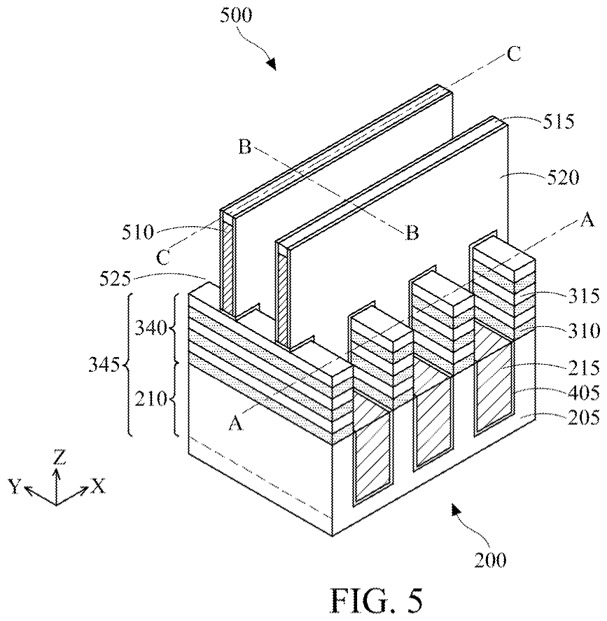

FIG. 5 is a diagram of an example implementation 500 of a dummy gate formation process described herein. The example implementation 500 includes an example of forming dummy gate structures for the semiconductor device 200 or a portion thereof. The semiconductor device 200 may include one or more additional devices, structures, and/or layers not shown in FIG. 5. The semiconductor device 200 may include additional layers and/or dies formed on layers above and/or below the portion of the semiconductor device 200 shown in FIG. 5. Additionally, or alternatively, one or more additional semiconductor structures and/or semiconductor devices may be formed in a same layer of an electronic device that includes the semiconductor device 200. In some implementations, the operations described in connection with the example implementation 500 are performed after the processes described in connection with FIGS. 3A-4B.

FIG. 5 illustrates a perspective view of the semiconductor device 200. As shown in FIG. 5, dummy gate structures 505 (also referred to as dummy gate stacks or temporary gate structures) are formed over the fin structures 345. The dummy gate structures 505 are sacrificial structures that are to be replaced by replacement gate structures or replacement gate stacks (e.g., the gate structures 240) at a subsequent processing stage for the semiconductor device 200. Portions of the fin structures 345 underlying the dummy gate structures 505 may be referred to as channel regions. The dummy gate structures 505 may also define source/drain (S/D) regions of the fin structures 345, such as the regions of the fin structures 345 adjacent and on opposing sides of the channel regions.

A dummy gate structure 505 may include a gate electrode layer 510, a hard mask layer 515 over and/or on the gate electrode layer 510, and spacer layers 520 on opposing sides of the gate electrode layer 510 and on opposing sides of the hard mask layer 515. The dummy gate structures 505 may be formed on a gate dielectric layer 525 between the top-most second layer 315 and the dummy gate structures 505. The gate electrode layer 510 includes polycrystalline silicon (polysilicon or PO) or another material. The hard mask layer 515 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 520 include a silicon oxycarbide (SiOC), a nitrogen free SiOC, or another suitable material. The gate dielectric layer 525 may include a silicon oxide (e.g., SiOₓ such as SiO₂), a silicon nitride (e.g., SiₓN_{y} such as Si₃N₄), a high-K dielectric material and/or another suitable material.

The layers of the dummy gate structures 505 may be formed using various semiconductor processing techniques such as deposition (e.g., by the deposition tool 102), patterning (e.g., by the exposure tool 104 and the developer tool 106), and/or etching (e.g., by the etch tool 108), among other examples. Examples include CVD, PVD, ALD, thermal oxidation, e-beam evaporation, photolithography, e-beam lithography, photoresist coating (e.g., spin-on coating), soft baking, mask aligning, exposure, post-exposure baking, photoresist developing, rinsing, drying (e.g., spin-drying and/or hard baking), dry etching (e.g., reactive ion etching), and/or wet etching, among other examples.

In some implementations, the gate dielectric layer 525 is conformally deposited on the semiconductor device 200 and then selectively removed from portions of the semiconductor device 200 (e.g., the source/drain areas). The gate electrode layer 510 is then deposited onto the remaining portions of the gate dielectric layer 525. The hard mask layers 515 are then deposited onto the gate electrode layers 510. The spacer layers 520 may be conformally deposited in a similar manner as the gate dielectric layer 525 and etched back such that the spacer layers 520 remain on the sidewalls of the dummy gate structures 505. In some implementations, the spacer layers 520 include a plurality of types of spacer layers. For example, the spacer layers 520 may include a seal spacer layer that is formed on the sidewalls of the dummy gate structures 505 and a bulk spacer layer that is formed on the seal spacer layer. The seal spacer layer and the bulk spacer layer may be formed of similar materials or different materials. In some implementations, the bulk spacer layer is formed without plasma surface treatment that is used for the seal spacer layer. In some implementations, the bulk spacer layer is formed to a greater thickness relative to the thickness of the seal spacer layer. In some implementations, the gate dielectric layer 525 is omitted from the dummy gate structure formation process and is instead formed in the replacement gate process.

FIG. 5 illustrates reference cross-sections that are used in subsequent figures described herein. Cross-section A-A is in an x-z plane (referred to as a y-cut) across the fin structures 345 in source/drain areas of the semiconductor device 200. Cross-section B-B is in a y-z plane (referred to as an x-cut) perpendicular to the cross-section A-A, and is across the dummy gate structures 505 in the source/drain areas of the semiconductor device 200. Cross-section C-C is in the x-z plane parallel to the cross-section A-A and perpendicular to the cross-section B-B, and is along a dummy gate structures 505. Subsequent figures refer to these reference cross-sections for clarity. In some figures, some reference numbers of components or features illustrated therein may be omitted to avoid obscuring other components or features for ease of depicting the figures.

As indicated above, FIG. 5 is provided as an example. Other examples may differ from what is described with regard to FIG. 5. Example implementation 500 may include additional operations, fewer operations, different operations, and/or a different order of operations than those described in connection with FIG. 5.

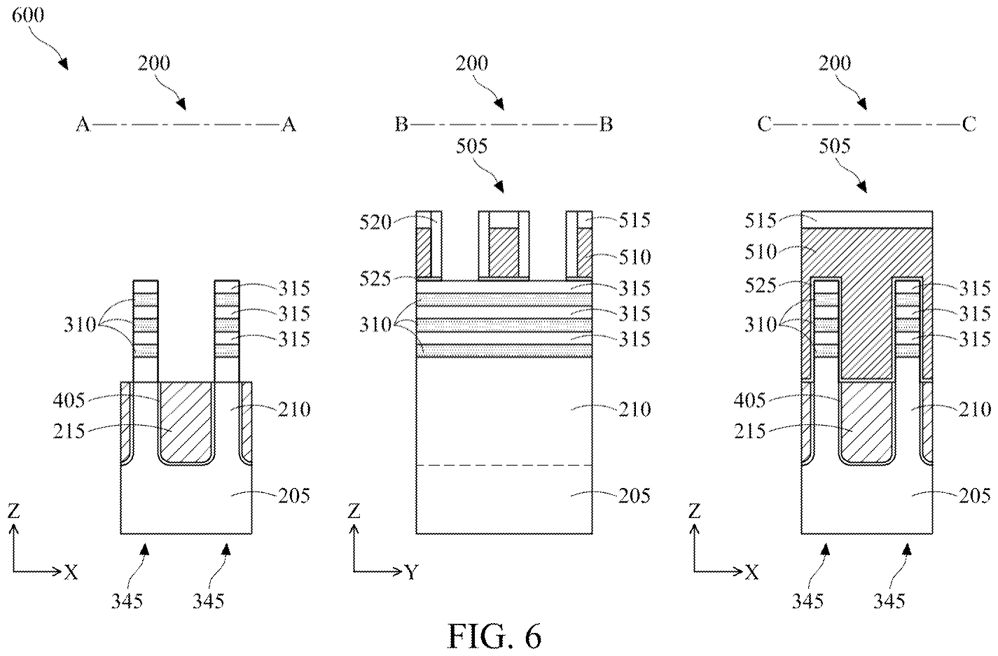

FIG. 6 is a diagram of an example implementation 600 of the semiconductor device 200 described herein. FIG. 6 includes cross-sectional views along the cross-sectional planes A-A, B-B, and C-C of FIG. 5. As shown in the cross-sectional planes B-B and C-C in FIG. 6, the dummy gate structures 505 are formed above the fin structures 345. As shown in the cross-sectional plane C-C in FIG. 6, portions of the gate dielectric layer 525 and portions of the gate electrode layers 510 are formed in recesses above the fin structures 345 that are formed as a result of the removal of the hard mask layer 320.

As indicated above, FIG. 6 is provided as an example. Other examples may differ from what is described with regard to FIG. 6. Example implementation 600 may include additional operations, fewer operations, different operations, and/or a different order of operations than those described in connection with FIG. 6.

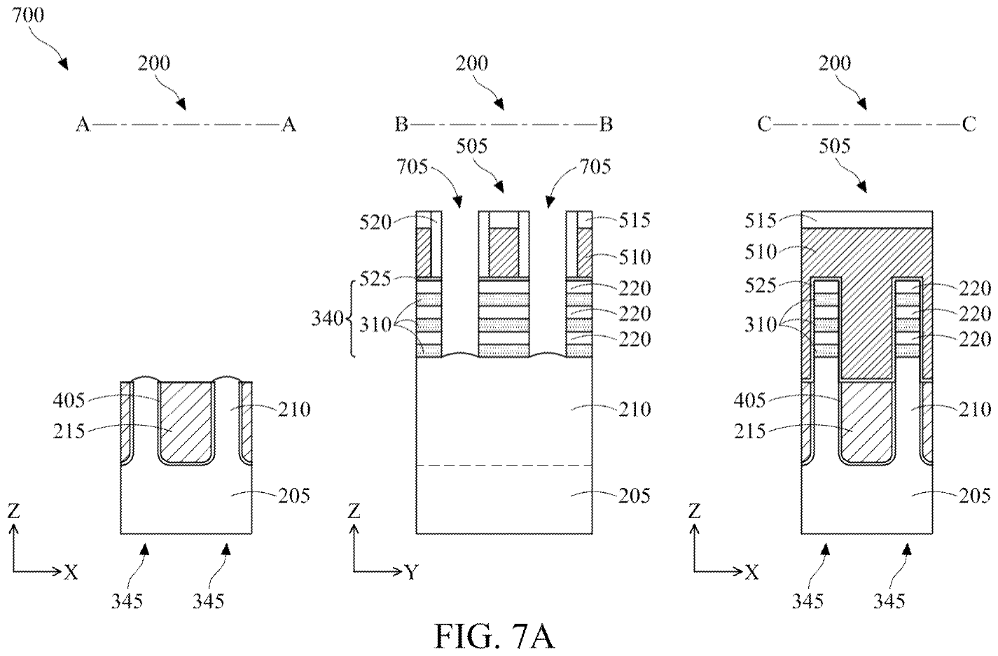

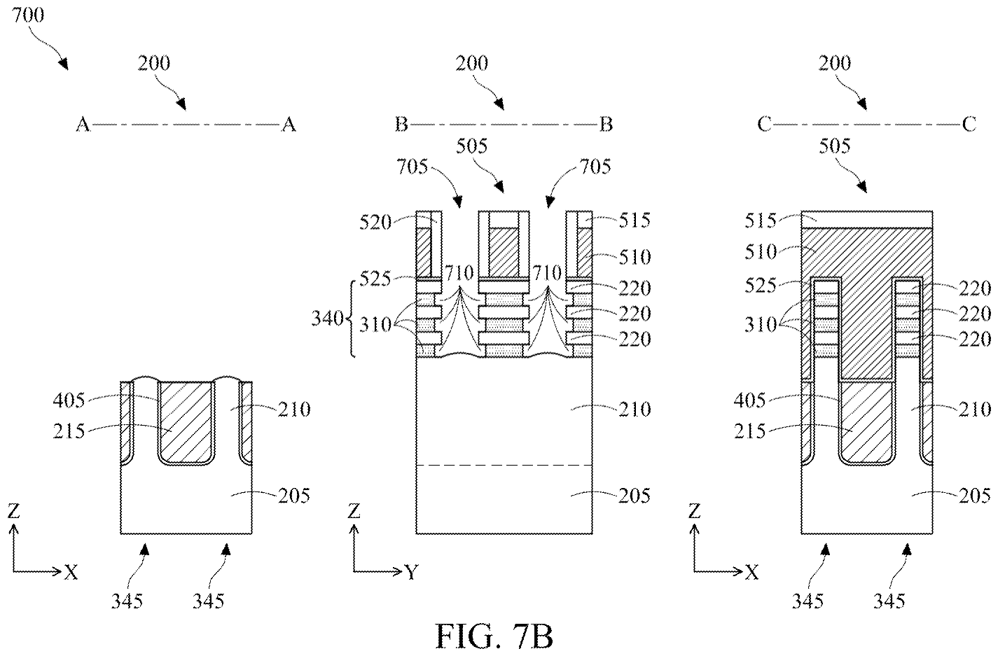

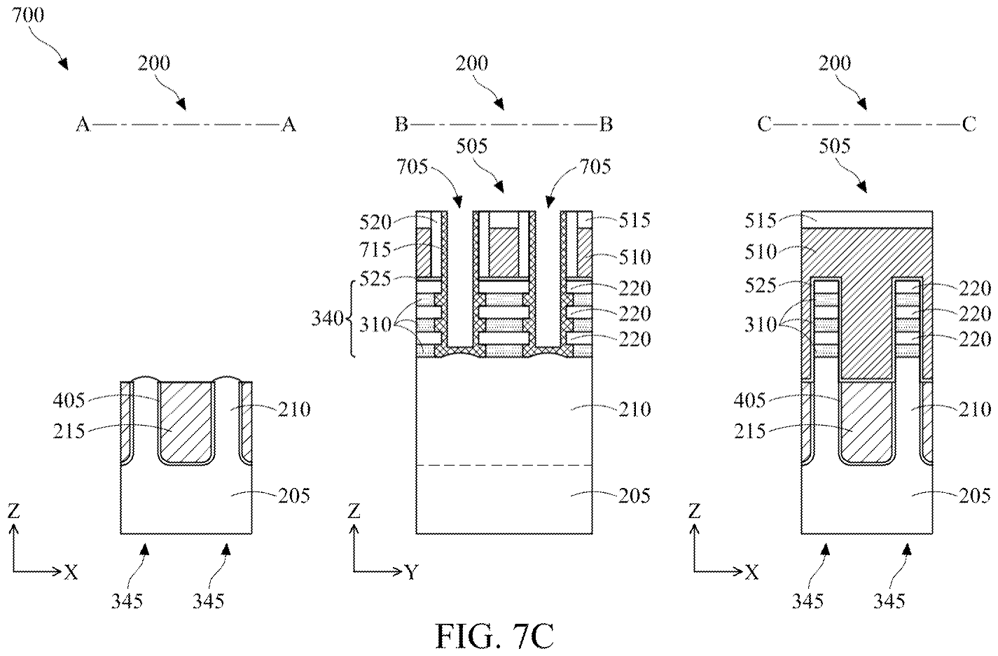

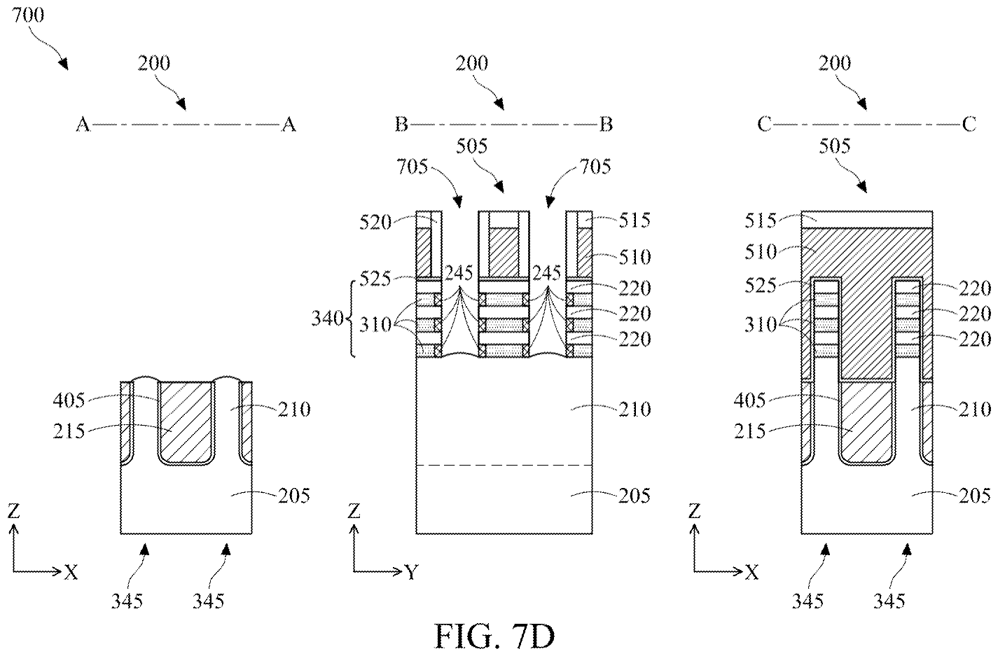

FIGS. 7A-7D are diagrams of an example implementation 700 of a source/drain recess formation process and an inner spacer formation process described herein. The example implementation 700 includes an example of forming source/drain recesses and the inner spacers 245 for the semiconductor device 200. FIGS. 7A-7D are illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 700 are performed after the processes described in connection with FIGS. 3A-6.

As shown in the cross-sectional plane A-A and cross-sectional plane B-B in FIG. 7A, source/drain recesses 705 are formed in the portions 340 of the fin structure 345 in an etch operation. The source/drain recesses 705 are formed to provide spaces in which source/drain regions 225 are to be formed on opposing sides of the dummy gate structures 505. The etch operation may be performed by the etch tool 108 and may be referred to a strained source/drain (SSD) etch operation. In some implementations, the etch operation includes a plasma etch technique, a wet chemical etch technique, and/or another type of etch technique.

In some implementations, the source/drain recesses 705 also extend into a portion of the mesa regions 210 of the fin structure 345. In these implementations, the source/drain recesses 705 may penetrate into a well portion (e.g., a p-well, an n-well) of the fin structure 345. In implementations in which the semiconductor substrate 205 includes a silicon (Si) material having a (100) orientation, (111) faces are formed at bottoms of the source/drain recesses 705, resulting in formation of a V-shape or a triangular shape cross section at the bottoms of the source/drain recesses 705. In some implementations, a wet etching using tetramethylammonium hydroxide (TMAH) and/or a chemical dry etching using hydrochloric acid (HCl) are employed to form the V-shape profile. However, the cross section at the bottoms of the source/drain recesses 705 may include other shapes, such as round or semi-circular, among other examples.

As shown in the cross-sectional plane B-B and the cross-sectional plane C-C in FIG. 7A, portions of the first layers 310 and portions of the second layers 315 of the layer stack 305 remain under the dummy gate structures 505 after the etch operation to form the source/drain recesses 705. The portions of the second layers 315 under the dummy gate structures 505 form the nanostructure channels 220 of the nanostructure transistors of the semiconductor device 200. The nanostructure channels 220 extend between adjacent source/drain recesses 705.

As shown in the cross-sectional plane B-B in FIG. 7B, the first layers 310 are laterally etched (e.g., in a direction that is approximately parallel to a length of the first layers 310) in an etch operation, thereby forming cavities 710 between portions of the nanostructure channels 220. In particular, the etch tool 108 laterally etches ends of the first layers 310 under the dummy gate structures 505 through the source/drain recesses 705 to form the cavities 710 between ends of the nanostructure channels 220. In implementations where the first layers 310 are silicon germanium (SiGe) and the second layers 315 are silicon (Si), the etch tool 108 may selectively etch the first layers 310 using a wet etchant such as, a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 705 to etch the first layers 310 from the source/drain recesses 705. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 60° Celsius to approximately 90° Celsius. However, other values for the parameters of the etch operation are within the scope of the present disclosure.

The cavities 710 may be formed to an approximately curved shape, an approximately concave shape, an approximately triangular shape, an approximately square shape, or to another shape. In some implementations, the depth of one or more of the cavities 710 (e.g., the dimension of the cavities extending into the first layers 310 from the source/drain recesses 705) is in a range of approximately 0.5 nanometers to about 5 nanometers. In some implementations, the depth of one or more of the cavities 710 is in a range of approximately 1 nanometer to approximately 3 nanometers. However, other values for the depth of the cavities 710 are within the scope of the present disclosure. In some implementations, the etch tool 108 forms the cavities 710 to a length (e.g., the dimension of the cavities extending from a nanostructure channel 220 below a first layer 310 to another nanostructure channel 220 above the first layer 310) such that the cavities 710 partially extend into the sides of the nanostructure channels 220 (e.g., such that the width or length of the cavities 710 are greater than the thickness of the first layers 310). In this way, the inner spacers that are to be formed in the cavities 710 may extend into a portion of the ends of the nanostructure channels 220.

As shown in the cross-sectional plane A-A and in the cross-sectional plane B-B in FIG. 7C, an insulating layer 715 is conformally deposited along the bottom and along the sidewalls of the source/drain recesses 705. The insulating layer 715 further extends along the spacer layer 520. The deposition tool 102 may deposit the insulating layer 715 using a CVD technique, a PVD technique, and ALD technique, and/or another deposition technique. The insulating layer 715 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. The insulating layer 715 may include a material that is different from the material of spacer layers 520.

The deposition tool 102 forms the insulating layer 715 to a thickness sufficient to fill in the cavities 710 between the nanostructure channels 220 with the insulating layer 715. For example, the insulating layer 715 may be formed to a thickness in a range of approximately 1 nanometer to approximately 10 nanometers. As another example, the insulating layer 715 may be formed to a thickness in a range of approximately 2 nanometers to approximately 5 nanometers. However, other values for the thickness of the insulating layer 715 are within the scope of the present disclosure.

As shown in the cross-sectional plane A-A and in the cross sectional plane B-B in FIG. 7D, the insulating layer 715 is partially removed such that remaining portions of the insulating layer 715 correspond to the inner spacers 245 in the cavities 710. The etch tool 108 may perform an etch operation to partially remove the insulating layer 715.

In some implementations, the etch operation may result in the surfaces of the inner spacers 245 facing the source/drain recesses 705 being curved or recessed. The depth of the recesses in the inner spacers 245 may be in a range of approximately 0.2 nanometers to approximately 3 nanometers. As another example, the depth of the recesses in the inner spacers 245 may be in a range of approximately 0.5 nanometers to approximately 2 nanometers. As another example, the depth of the recesses in the inner spacers 245 may be in a range of less than approximately 0.5 nanometers. In some implementations, the surfaces of the inner spacers 245 facing the source/drain recesses 705 are approximately flat such that the surfaces of the inner spacers 245 and the surfaces of the ends of the nanostructure channels 220 are approximately even and flush.

As indicated above, FIGS. 7A-7D are provided as examples. Other examples may differ from what is described with regard to FIGS. 7A-7D. Example implementation 700 may include additional operations, fewer operations, different operations, and/or a different order of operations than those described in connection with FIGS. 7A-7D.

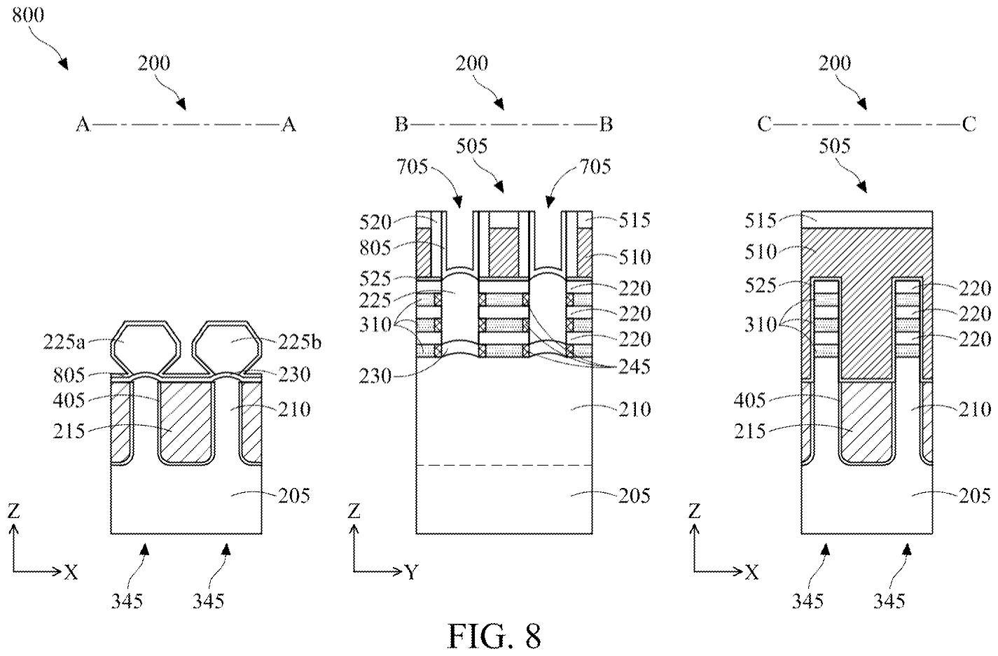

FIG. 8 is a diagram of an example implementation 800 of a source/drain region formation process described herein. The example implementation 800 includes an example of forming the source/drain regions 225 in the source/drain recesses 705 for the semiconductor device 200. In particular, the example implementation 800 includes an example of forming a p-type source/drain region 225a for a PMOS nanostructure transistor (e.g., a PMOS field effect transistor (PFET)) of the semiconductor device 200 and an n-type source/drain region 225b for an NMOS nanostructure transistor (e.g., an NMOS field effect transistor (NFET)) of the semiconductor device 200.

FIG. 8 is illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 800 are performed after the processes described in connection with FIGS. 3A-7D.

As shown in the cross-sectional plane A-A and the cross-sectional plane B-B in FIG. 8, the source/drain recesses 705 are filled with one or more layers to form the source/drain regions 225 in the source/drain recesses 705. For example, the deposition tool 102 may deposit a buffer region 230 at the bottom of the source/drain recesses 705, the deposition tool 102 may deposit the source/drain regions 225 on the buffer region 230, and the deposition tool 102 may deposit a contact etch stop layer (CESL) 805 on the source/drain regions 225. In some implementations, a capping layer 235 (not shown) is deposited on the source/drain regions 225 prior to forming the CESL 805.

The buffer region 230 may include silicon (Si), silicon doped with boron (SiB) or another dopant, and/or another material. The buffer region 230 may be included to reduce, minimize, and/or prevent dopant migration and/or current leakage from the source/drain regions 225 into the mesa regions 210, which might otherwise cause short channel effects in the semiconductor device 200. Accordingly, the buffer region 230 may increase the performance of the semiconductor device 200 and/or increase yield of the semiconductor device 200. In some implementations, the buffer region 230 is omitted from one or more of the source/drain regions 225.

The source/drain regions 225 may include one or more layers of epitaxially grown material. For example, the deposition tool 102 may epitaxially grow a first layer of the source/drain regions 225 (referred to as an L1) over the buffer region 230, and may epitaxially grow a second layer of the source/drain regions 225 (referred to as an L2, an L2-1, and/or an L2-2) over the first layer. The p-type source/drain region 225a may include a semiconductor material (e.g., silicon (Si), silicon germanium (SiGe)) doped with a p-type dopant such as boron (B) (e.g., boron-doped silicon (SiB) and/or boron-doped silicon germanium (SiGeB), among other examples). Additionally and/or alternatively, the p-type source/drain region 225a may include silicon germanium (SiGe). The n-type source/drain region 225b may include undoped silicon (Si) and/or silicon doped with an n-type dopant such as phosphorous (P) (e.g., phosphorous-doped silicon (SiP)) and/or arsenic (As) (arsenic-doped silicon (SiAs)), among other examples.

In some implementations, the CESL 805 is conformally deposited (e.g., using the deposition tool 102) over the source/drain regions 225, including the p-type source/drain region 225a and the n-type source/drain region 225b, prior to formation of the ILD layer 250. The ILD layer 250 is then formed on the CESL 805. The CESL 805 may provide a mechanism to stop an etch process when forming contacts or vias for the source/drain regions 225. The CESL 805 may be formed of a dielectric material having a different etch selectivity from adjacent layers or components. The CESL 805 may include or may be a nitrogen containing material, a silicon containing material, and/or a carbon containing material. Furthermore, the CESL 805 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 805 may be deposited using a deposition technique such as ALD, CVD, or another deposition technique.

As indicated above, FIG. 8 is provided as an example. Other examples may differ from what is described with regard to FIG. 8. Example implementation 800 may include additional operations, fewer operations, different operations, and/or a different order of operations than those described in connection with FIG. 8.

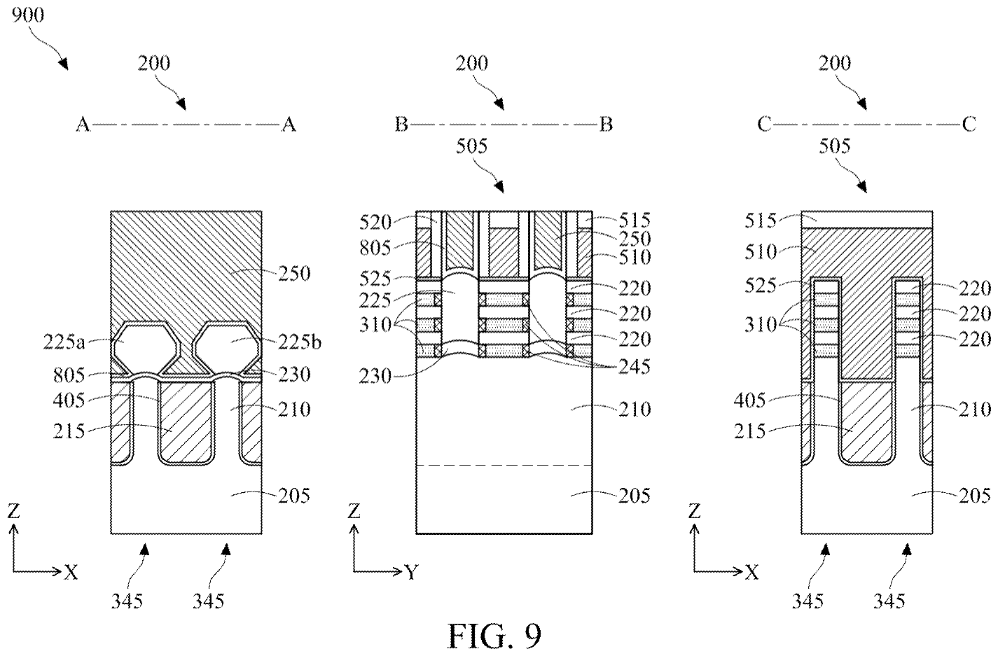

FIG. 9 is a diagram of an example implementation 900 of an ILD formation process described herein. FIG. 9 is illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 900 are performed after the operations described in connection with FIGS. 3A-8.

As shown in the cross-sectional plane A-A and the cross-sectional plane B-B in FIG. 9, the ILD layer 250 is formed over the source/drain regions 225, including the p-type source/drain region 225a and the n-type source/drain region 225b. In particular, the ILD layer 250 may be formed on the CESL 805 that is over the source/drain regions 225, including the p-type source/drain region 225a and the n-type source/drain region 225b. The ILD layer 250 fills in areas between the dummy gate structures 505, and the areas above the source/drain regions 225. The ILD layer 250 is formed to reduce the likelihood of and/or prevent damage to the source/drain regions 225 during the replacement gate process. The ILD layer 250 may be referred to as an ILD zero (ILDO) layer or another ILD layer.

A deposition tool 102 may be used to deposit the ILD layer 250 using a PVD technique, an ALD technique, a CVD technique, an oxidation technique, another type of deposition technique described in connection with FIG. 1, and/or another suitable deposition technique. The ILD layer 250 may be deposited in one or more deposition operations. In some implementations, a planarization tool 110 may be used to planarize the ILD layer 250 after the ILD layer 250 is deposited.

As indicated above, the number and arrangement of operations and devices shown in FIG. 9 are provided as one or more examples. In practice, there may be additional operations and devices, fewer operations and devices, different operations and devices, or differently arranged operations and devices than those shown in FIG. 9.

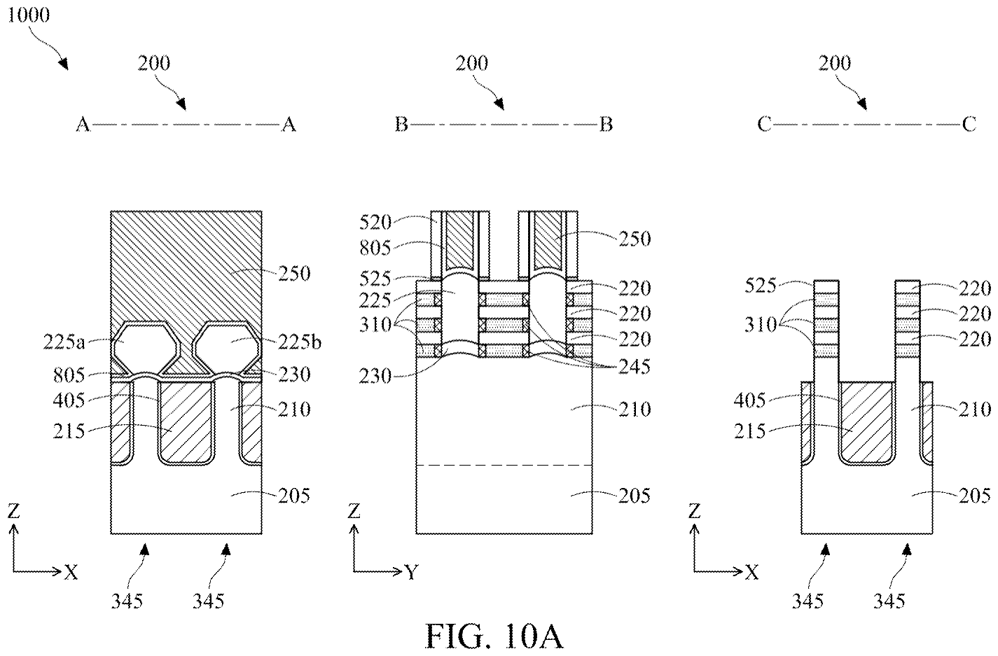

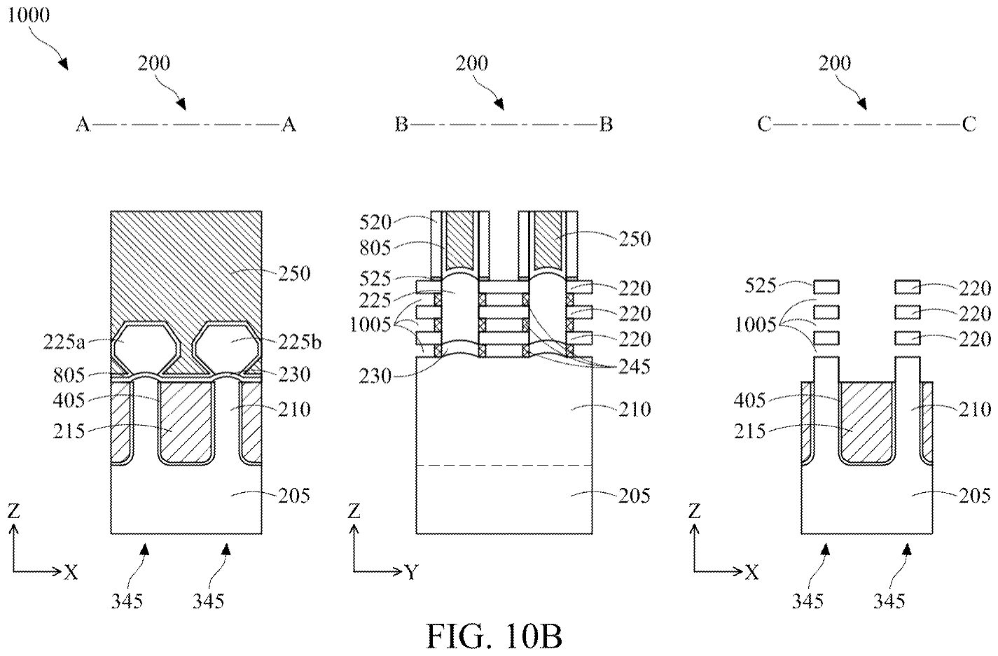

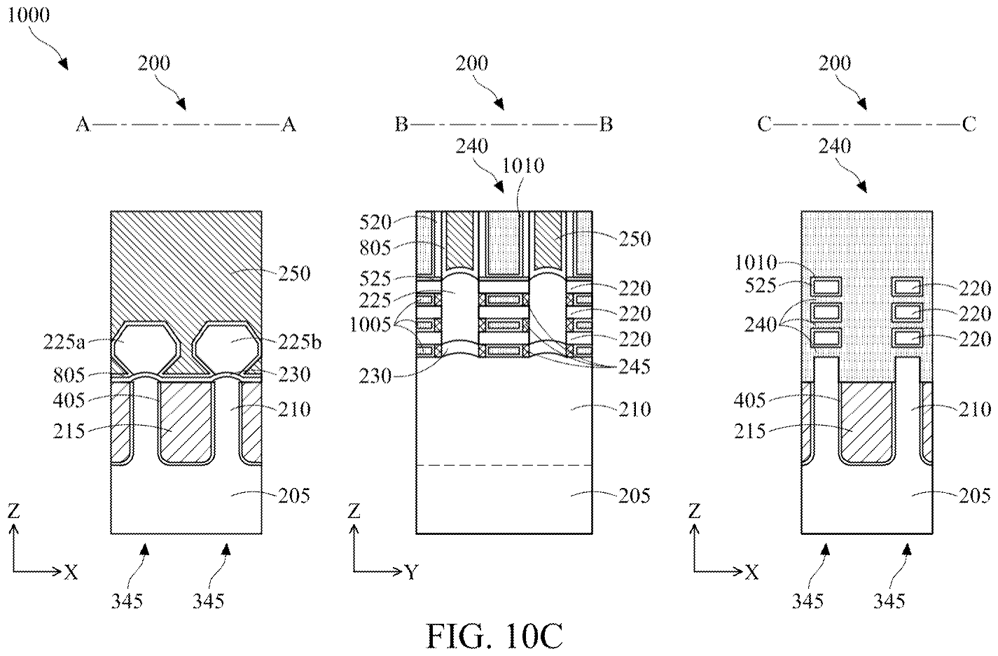

FIGS. 10A-10C are diagrams of an example implementation 1000 of a replacement gate (RPG) process described herein. The example implementation 1000 includes an example of a replacement gate process for replacing the dummy gate structures 505 with the gate structures 240 (e.g., the replacement gate structures) of the semiconductor device 200. FIGS. 10A-10C are illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 1000 are performed after the operations described in connection with FIGS. 3A-9.

As shown in the cross-sectional plane B-B and the cross-sectional plane C-C in FIG. 10A, the replacement gate operation is performed (e.g., by one or more of the semiconductor processing tools 102-112) to remove the dummy gate structures 505 from the semiconductor device 200. The removal of the dummy gate structures 505 leaves behind openings (or recesses) 1005 between the ILD layer 250 over the source/drain regions 225. The dummy gate structures 505 may be removed in one or more etch operations. Such etch operations may include a plasma etch technique, a wet chemical etch technique, and/or another type of etch technique.

As shown in the cross-sectional plane B-B and the cross-sectional plane C-C in FIG. 10B, a nanostructure release operation (e.g., an SiGe release operation) is performed to remove the first layers 310 (e.g., the silicon germanium layers). This results in openings 1005 between the nanostructures channels 220 (e.g., the areas around the nanostructure channels 220). The nanostructure release operation may include the etch tool 108 performing an etch operation to remove the first layer 310 based on a difference in etch selectivity between the material of the first layers 310 and the material of the nanostructure channels 220, and between the material of the first layers 310 and the material of the inner spacers 245. The inner spacers 245 may function as etch stop layers in the etch operation to protect the source/drain regions 225 from being etched.

As shown in the cross-sectional plan B-B and the cross-sectional plane C-C in FIG. 10C, the replacement gate operation continues where deposition tool 102 and/or the plating tool 112 forms the gate structures (e.g., replacement gate structures) 240 in the openings 1005 between the source/drain regions 225. In particular, the gate structures 240 fill the areas between and around the nanostructure channels 220 that were previously occupied by the first layers 310 such that the gate structures 240 wrap around the nanostructure channels 220 and surround the nanostructure channels 220 on at least three sides of the nanostructure channels 220. In some implementations, the gate structures 240 fully wrap around the nanostructure channels 220 and surround the nanostructure channels 220 on all four sides of the nanostructure channels 220. The gate structures 240 may include metal gate structures. A conformal high-k dielectric liner 1010 may be deposited onto the nanostructure channels 220 and on sidewalls prior to formation of the gate structures 240. The high-k dielectric liner 1010 may be a gate dielectric layer between the gate structures 240 and the nanostructure channels 220. The gate structures 240 may include additional layers such as an interfacial layer, a work function tuning layer, and/or a metal electrode structure, among other examples.

The high-k dielectric liner 1010 may include one or more high-k materials (e.g., dielectric materials having a dielectric constant greater than silicon dioxide (SiO₂-dielectric constant of approximately 3.9). Examples include lanthanum oxide (LaOₓ), hafnium oxide (HfOₓ), and/or aluminum oxide (AlₓO_{y}), among other examples. The gate structures 240 include one or more metal materials, such as ruthenium (Ru), tungsten (W), cobalt (Co), copper (Cu), and/or molybdenum (Mo), among other examples. In some implementations, a glue layer is included between a high-k dielectric layer 1010 and a gate structure 240 to promote adhesion between the high-k dielectric liner 1010 and the gate structure 240. Examples of materials for the glue layer may include tantalum nitride (TaN), titanium nitride (TiN), and/or another suitable glue layer material.

As indicated above, the number and arrangement of operations and devices shown in FIGS. 10A-10C are provided as one or more examples. In practice, there may be additional operations and devices, fewer operations and devices, different operations and devices, or differently arranged operations and devices than those shown in FIGS. 10A-10C.

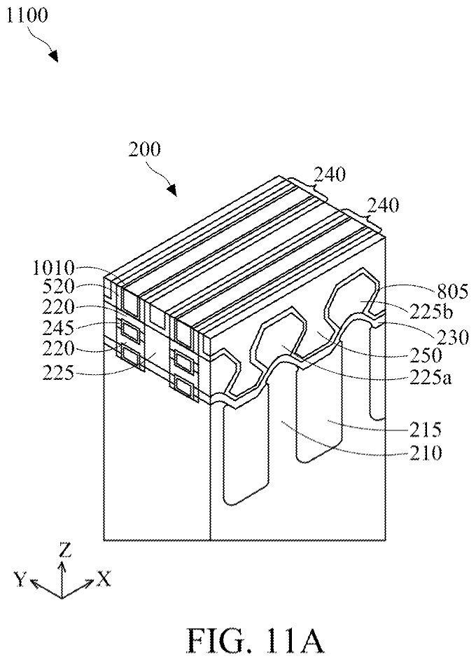

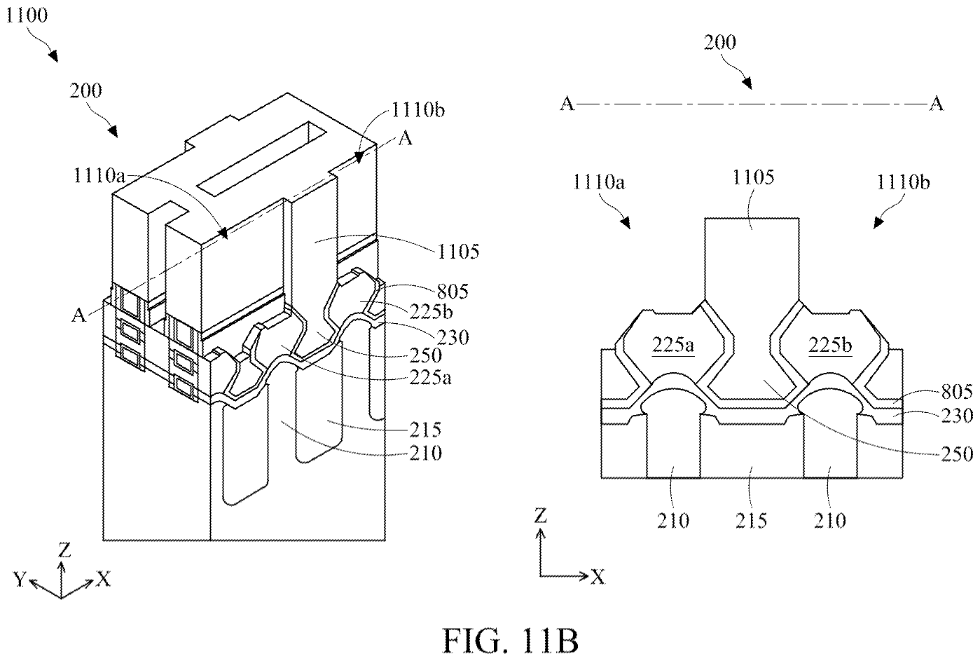

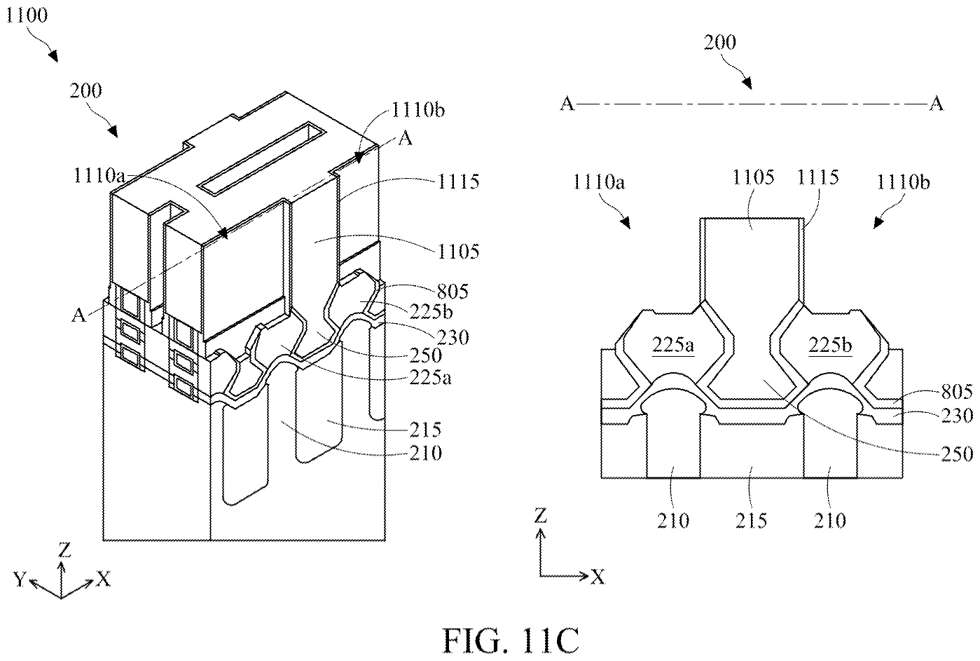

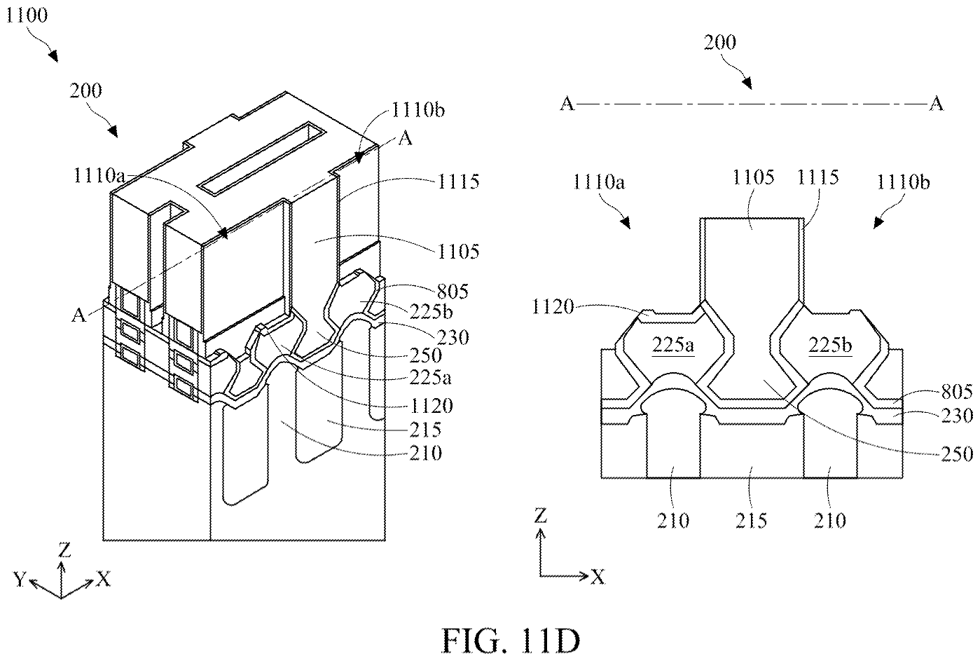

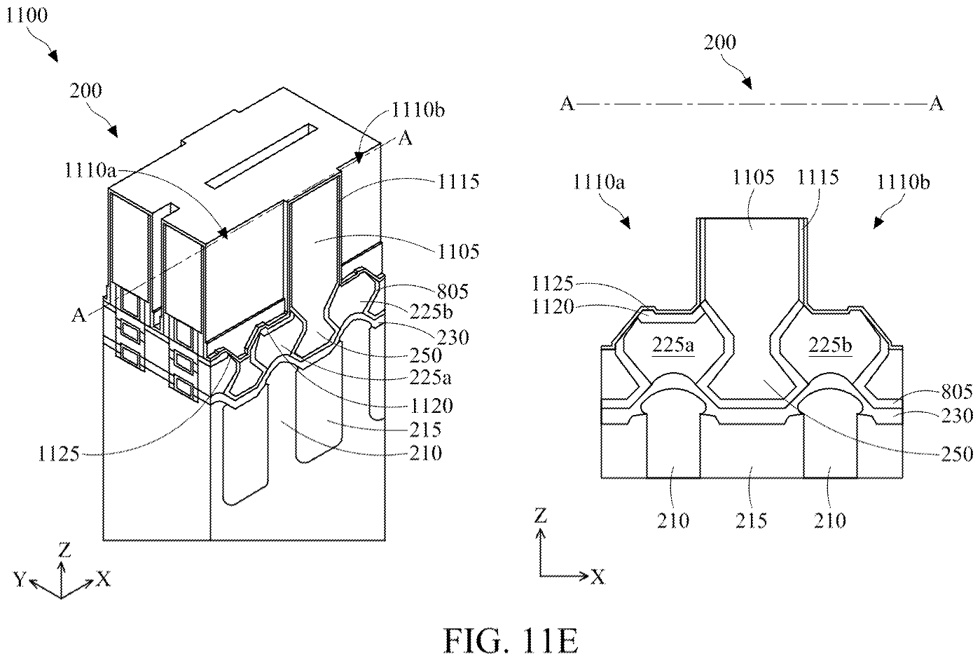

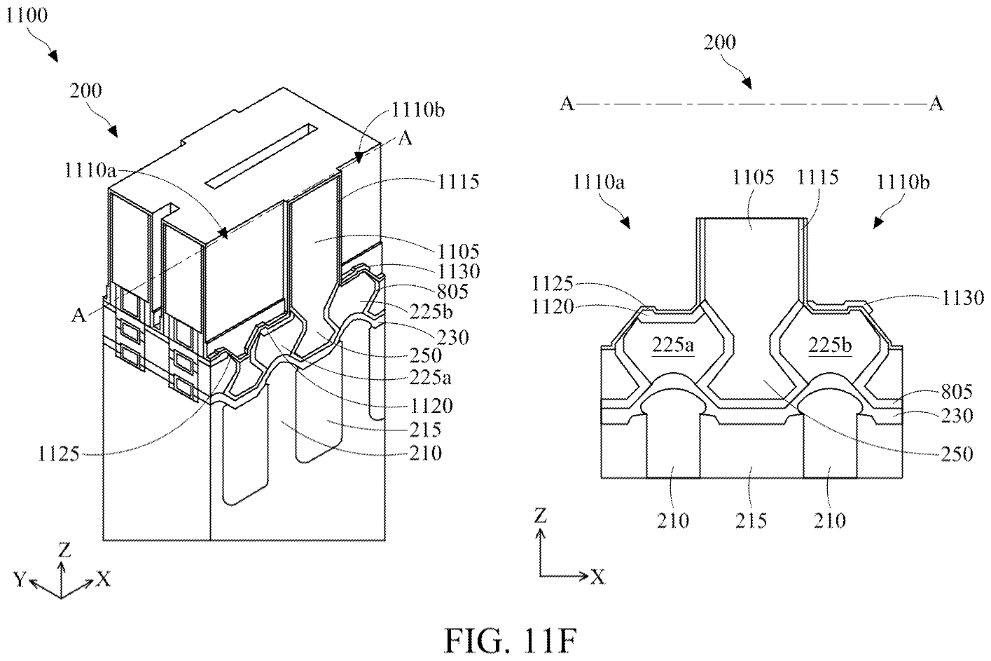

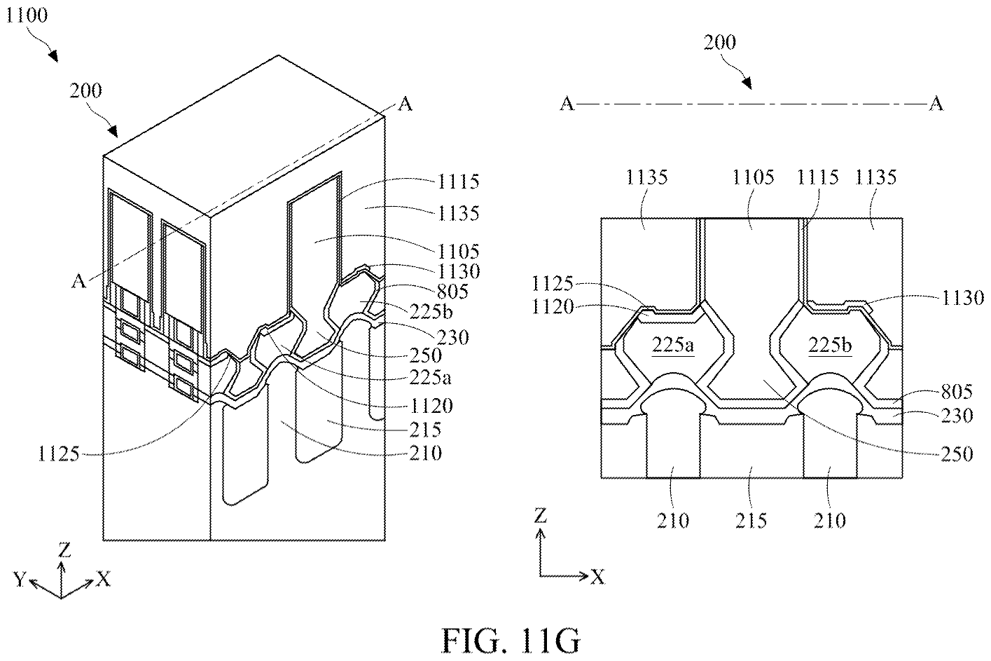

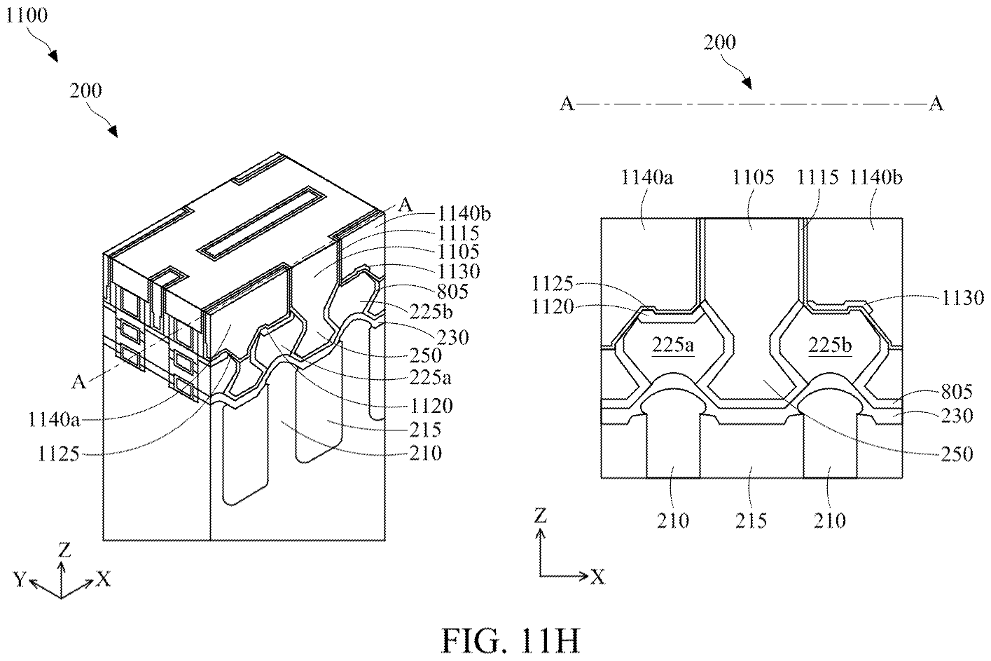

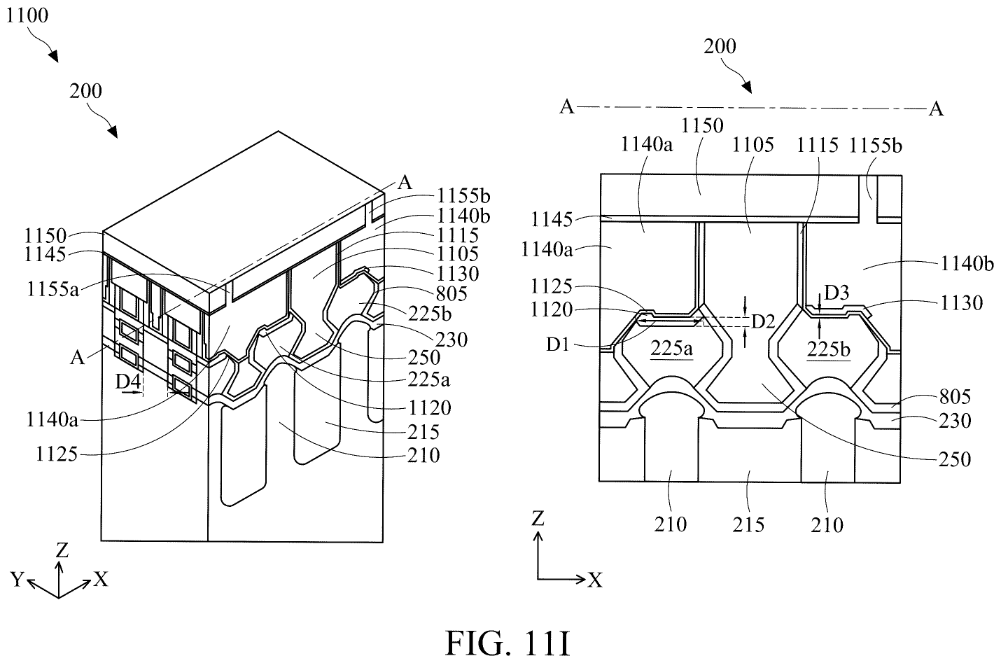

FIGS. 11A-11I are diagrams of an example implementation 1100 of forming an active region isolation structure described herein. One or more of FIGS. 11A-11I are illustrated from one or more perspectives illustrated in FIG. 5, including the perspective of the cross-sectional plane A-A in FIG. 5 (e.g., in the x-direction across a plurality of source/drain regions 225 that are adjacent to a sidewall of a gate structure 240).

The example implementation 1100 includes an example of selectively forming a p-type metal silicide layer on a p-type source/drain region 225a of the semiconductor device 200. The p-type metal silicide layer may be selectively formed on the p-type source/drain region in that one or more p-type metals are deposited on the p-type source/drain region and annealed to react with the material of the p-type source/drain region, where the one or more p-type metals do not react (or minimally react) with the material of the n-type source/drain region.

Turning to FIG. 11A, the operations described in connection with the example implementation 1100 are performed after the operations described in connection with FIGS. 3A-10C.

As shown in FIG. 11B, a dielectric layer 1105 (e.g., an ILD layer) may be formed over the ILD layer 250 and over the gate structures 240 of the semiconductor device 200. A deposition tool 102 may be used to deposit the dielectric layer 1105 using a PVD technique, an ALD technique, a CVD technique, an oxidation technique, another type of deposition technique described in connection with FIG. 1, and/or another suitable deposition technique. The dielectric layer 1105 may be deposited in one or more deposition operations. In some implementations, a planarization tool 110 may be used to planarize the dielectric layer 1105 after the dielectric layer 1105 is deposited. In some implementations, the dielectric layer 1105 includes silicon carbide (SiC), lanthanum oxide (LaₓO_{y}), aluminum oxide (AlₓO_{y}), aluminum oxynitride (AlON), zirconium oxide (ZrOₓ), hafnium oxide (HfOₓ), silicon nitride (SiₓN_{y}), silicon (Si), zinc oxide (ZnO), zirconium nitride (ZrN), zirconium aluminum oxide (ZrAlO), titanium oxide (TiOₓ), yttrium oxide (YₓO_{y}), tantalum carbonitride (TaCN), zirconium silicide (ZrSi), silicon oxycarbonitride (SiOCN), silicon oxycarbide (SiOC), silicon carbonitride (SiCN), hafnium silicide (HfSi), and/or silicon oxide (SiOₓ), among other examples.

As further shown in FIG. 11B, a source/drain recess 1110a may be formed over the p-type source/drain region 225a and a source/drain recess 1110b may be formed over the n-type source/drain region 225b. The source/drain recess 1110a may be formed through the dielectric layer 1105, through the ILD layer 250, and/or through the CESL 805 such that a top surface of the p-type source/drain region 225a is exposed through the source/drain recess 1110a. In some implementations, the source/drain recess 1110a extends into a portion of the p-type source/drain region 225a. The source/drain recess 1110b may be formed through the dielectric layer 1105, through the ILD layer 250, and/or through the CESL 805 such that a top surface of the n-type source/drain region 225b is exposed through the source/drain recess 1110b. In some implementations, the source/drain recess 1110b extends into a portion of the n-type source/drain region 225b.

In some implementations, a pattern in a photoresist layer is used to etch the dielectric layer 1105, the ILD layer 250, and/or the CESL 805 to form the source/drain recesses 1110a and 1110b. In these implementations, the deposition tool 102 may be used to form the photoresist layer on the dielectric layer 1105. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 1105, the ILD layer 250, and/or the CESL 805 based on the pattern to form the source/drain recesses 1110a and 1110b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 1105, the ILD layer 250, and/or the CESL 805 based on a pattern.

As shown in FIG. 11C, a silicide blocking layer 1115 is formed on the sidewalls of the dielectric layer 1105 in the source/drain recesses 1110a and 1110b. The silicide blocking layer 1115 is conformally deposited on the sidewalls of the dielectric layer 1105 to prevent or to prohibit silicide growth on the sidewalls of the dielectric layer 1105. The silicide blocking layer 1115 may be blanket deposited in the source/drain recesses 1110a and 1110b and may be subsequently removed from the exposed surfaces of the p-type source/drain region 225a and the n-type source/drain region 225b such that the silicide blocking layer 1115 remains on the sidewalls of the dielectric layer 1105 in the source/drain recesses 1110a and 1110b.

A deposition tool 102 may be used to deposit the silicide blocking layer 1115 using a PVD technique, an ALD technique, a CVD technique, an oxidation technique, another type of deposition technique described in connection with FIG. 1, and/or another suitable deposition technique. The silicide blocking layer 1115 may be deposited in one or more deposition operations. The silicide blocking layer 1115 includes one or more dielectric materials that resist silicide formation, such as a nitride-containing dielectric material (e.g., silicon nitride (SiₓN_{y}), among other examples). In some implementations, the silicide blocking layer 1115 includes the same or similar material composition as the CESL 805. In some implementations, the silicide blocking layer 1115 includes silicon carbide (SiC), lanthanum oxide (LaₓO_{y}), aluminum oxide (AlₓO_{y}), aluminum oxynitride (AlON), zirconium oxide (ZrOₓ), hafnium oxide (HfOₓ), silicon nitride (SiₓN_{y}), silicon (Si), zinc oxide (ZnO), zirconium nitride (ZrN), zirconium aluminum oxide (ZrAlO), titanium oxide (TiOₓ), yttrium oxide (YₓO_{y}), tantalum carbonitride (TaCN), zirconium silicide (ZrSi), silicon oxycarbonitride (SiOCN), silicon oxycarbide (SiOC), silicon carbonitride (SiCN), hafnium silicide (HfSi), and/or silicon oxide (SiOₓ), among other examples.

An etch tool 108 may be used to perform an anisotropic etch of the silicide blocking layer 1115 to remove the silicide blocking layer 1115 from the bottoms of the source/drain recesses 1110a and 1110b (and thus, from the top surfaces of the p-type source/drain region 225a and the n-type source/drain region 225b) without removing (or with minimally removing) the silicide blocking layer 1115 from the sidewalls of the source/drain recesses 1110a and 1110b. The anisotropic etch may include the use of a highly directional etch technique, such as a plasma-based etch technique to etch the silicide blocking layer 1115 in the z-direction in the semiconductor device 200.

As shown in FIG. 11D, a p-type metal silicide layer 1120 is selectively formed on the p-type source/drain region 225a. The p-type metal silicide layer 1120 is selectively formed on the p-type source/drain region 225a in that the p-type metal silicide layer 1120 is formed only on the p-type source/drain region 225a (and not on the n-type source/drain region 225b) without the use of additional masking layers to prevent the p-type metal silicide layer 1120 from being formed on the n-type source/drain region 225b and/or other surfaces of the semiconductor device 200.

To form the p-type metal silicide layer 1120, a layer of p-type metal is deposited over the semiconductor device 200, including over the p-type source/drain region 225a and the n-type source/drain region 225b. The p-type metal includes one or more p-type metals that react with the material of the p-type source/drain region 225a (e.g., that react with germanium (Ge) of the silicon germanium (SiGe) of the p-type source/drain region 225a) and that do not react with the material of the n-type source/drain region 225b (e.g., that do not react with the silicon of the n-type source/drain region 225b). Examples of such p-type metals include iridium (Ir), ruthenium (Ru), molybdenum (Mo), rhodium (Rh), tungsten (W), and/or niobium (Nb), among other examples. Thus, the p-type metal silicide layer 1120 may include an iridium silicide (IrSi), a ruthenium silicide (RuSi), a molybdenum silicide (MoSi), a rhodium silicide (RhSi), a tungsten silicide (WSi), and/or a niobium silicide (NbSi), among other examples. A deposition tool 102 may be used to deposit the p-type metal using a PVD technique, an ALD technique, a CVD technique, another type of deposition technique described in connection with FIG. 1, and/or another suitable deposition technique.

The p-type metal is then annealed to initiate a reaction between the p-type metal and the material of the p-type source/drain region 225a, thereby forming the p-type metal silicide layer 1120 on the p-type source/drain region 225a. Unreacted p-type metal may be subsequently removed from the semiconductor device 200. The anneal of the p-type metal may be “in-situ” in that the elevated temperature at which the p-type metal is deposited may initiate the annealing of the p-type metal. In-situ annealing may be implemented for p-type metal silicide layers 1120 having lesser thicknesses, or a separate annealing operation may be performed after deposition of the p-type metal for p-type metal silicide layers 1120 having greater thicknesses.

As shown in FIG. 11E, an n-type metal silicide layer 1125 is formed over and/or on the exposed top surface of the n-type source/drain region 225b in the source/drain recess 1110b. To form the n-type metal silicide layer 1125, a layer of n-type metal may be blanket deposited in the source/drain recesses 1110a and 1110b and then annealed (in-situ or separately, as described above) to cause a reaction between the n-type metal and the n-type source/drain region 225b to form the n-type metal silicide layer 1125. The n-type metal may also react with the p-type source/drain region 225a to form the n-type metal silicide layer 1125 on the p-type metal silicide layer 1120 over the p-type source/drain region 225a. Unreacted n-type metal may be removed from the semiconductor device 200. In some implementations, the n-type metal silicide layer 1125 is subsequently removed from the p-type source/drain region 225a. Alternatively, the n-type metal silicide layer 1125 may remain on the p-type metal silicide layer 1120 over the p-type source/drain region 225a.

The n-type metal may include antimony (Sb), titanium (Ti), zirconium (Zr), yttrium (Y), and/or scandium (Sc), among other examples. Thus, the n-type metal silicide layer 1125 may include an antimony silicide (SbSi), a titanium silicide (TiSi), a zirconium silicide (ZrSi), a yttrium silicide (Ysi), and/or a scandium silicide (ScSi), among other examples. A deposition tool 102 may be used to deposit the n-type metal using a PVD technique, an ALD technique, a CVD technique, another type of deposition technique described in connection with FIG. 1, and/or another suitable deposition technique.

The p-type metal silicide layer 1120 being formed on the p-type source/drain region 225a and the n-type metal silicide layer 1125 being formed on the n-type source/drain region 225b enables the contact resistance to be respectively and independently tuned for the p-type source/drain region 225a and the n-type source/drain region 225b. The silicide layer that is in direct contact with the p-type source/drain region 225a may have the most impact on the contact resistance of the p-type source/drain region 225a. Thus, if the n-type metal silicide layer 1125 remains on the p-type metal silicide layer 1120 over the p-type source/drain region 225a, the n-type metal silicide layer 1125 has minimal impact on the contact resistance of the p-type source/drain region 225a because the n-type metal silicide layer 1125 is not in direct contact with the p-type source/drain region 225a. Thus, the semiconductor processing complexity, time, and/or cost for the semiconductor device 200 can be reduced with minimal performance impact by not removing the n-type metal silicide layer 1125 from the p-type source/drain region 225a if the p-type metal silicide layer 1120 is between the n-type metal silicide layer 1125 and the p-type source/drain region 225a.

As shown in FIG. 11F, a capping layer 1130 is formed above the n-type source/drain region 225b on the n-type metal silicide layer 1125. Alternatively, the capping layer 1130 may be omitted from the n-type source/drain region 225b. The capping layer 1130 may include a layer of titanium silicide (TiSi) that is formed “in-situ” with the n-type metal silicide layer 1125. In other words, the layer of titanium silicide is formed under the same vacuum (e.g., in the same processing chamber without breaking the vacuum pressure in the processing chamber) as the n-type metal silicide layer 1125 is formed. This minimizes and/or reduces the likelihood of exposure of the semiconductor device 200 to atmospheric oxygen prior to formation of the layer of titanium silicide. The atmospheric oxygen might otherwise cause the layer of titanium silicide to oxidize. After formation of the layer of titanium silicide, a deposition tool 102 may be used to perform a nitridation process in which the layer of titanium silicide is nitrated. This increases the nitrogen concentration in the layer of titanium silicide, which reduces the likelihood of oxidization in the layer of titanium silicide after the vacuum is removed. Alternatively, the capping layer 1130 may be formed from another metal silicide material if another type of n-type metal silicide (e.g., other than titanium silicide) is used for the n-type metal silicide layer 1125. A similar capping layer (e.g., titanium silicide or another type of metal silicide) may also be formed on the p-type metal silicide layer 1120 over the p-type source/drain region 225a.

After formation of the capping layer 1130, the layer stack on the top of the p-type source/drain region 225a may include the p-type metal silicide layer 1120 alone or in combination with the n-type metal silicide layer 1125 on the p-type metal silicide layer 1120 and/or the capping layer 1130 on the n-type metal silicide layer 1125. The layer stack on the top of the n-type source/drain region 225b may include the n-type metal silicide layer 1125 alone or in combination with the capping layer 1130 on the n-type metal silicide layer 1125.

In this way, the semiconductor device 200 may include a plurality of nanostructure channels 220 that are arranged in a direction (e.g., the z-direction) that is approximately perpendicular to a semiconductor substrate 205 of the semiconductor device 200, a gate structure 240 wrapping around each of the nanostructure channels 220, a p-type source/drain region 225a adjacent to the nanostructure channel 220, an n-type source/drain region 225b adjacent to the nanostructure channels 220, a p-type metal silicide layer 1120 on the p-type source/drain region 225a, and an n-type metal silicide layer 1125 on the n-type source/drain region 225b. If the n-type metal silicide layer 1125 is not removed from the p-type metal silicide layer 1120 over the p-type source/drain region 225a, the n-type metal silicide layer 1125 may also be included on the p-type metal silicide layer 1120 between the p-type metal silicide layer 1120 and the source/drain contact 1140a.

As shown in FIG. 11G, a conductive layer 1135 is formed in the source/drain recesses 1110a and 1110b, and over the dielectric layer 1105. The conductive layer 1135 is formed over the p-type source/drain region 225a in the source/drain recess 1110a, as well as over the p-type metal silicide layer 1120 and the n-type metal silicide layer 1125 (if not removed) in the source/drain recess 1110a. The conductive layer 1135 is also formed over the n-type source/drain region 225b in the source/drain recess 1110b, as well as over the n-type metal silicide layer 1125 and the capping layer 1130 (if formed) in the source/drain recess 1110b. A deposition tool 102 and/or a plating tool 112 may be used to deposit the conductive layer 1135 using a CVD technique, a PVD technique, an ALD technique, an electroplating technique, another deposition technique described above in connection with FIG. 1, and/or another suitable deposition technique. The conductive layer 1135 may be deposited in one or more deposition operations. In some implementations, a seed layer is first deposited, and the conductive layer 1135 is deposited on the seed layer. In some implementations, one or more liner layers (e.g., adhesion layers, glue layers, barrier layers) are included between the conductive layer 1135 and the sidewalls of the source/drain recesses 1110a and 1110b. The one or more liner layers may include a titanium silicide (TiSi), molybdenum (Mo), zirconium (Zr), ruthenium (Ru), tungsten (W), titanium nitride (TiN), yttrium (Y), iridium (Ir), antimony (Sb), scandium (Sc), niobium (Nb), rhodium (Rh), molybdenum silicon nitride (MoSiN), zirconium silicon nitride (ZrSiN), ruthenium silicon nitride (RuSiN), tungsten silicon nitride (WSiN), titanium nitride (TiN), yttrium silicon nitride (YSiN), iridium silicon nitride (IrSiN), antimony silicon nitride (SbSiN), scandium silicon nitride (ScSiN), rhodium silicon nitride (RhSiN), and/or niobium silicon nitride (NbSiN), among other examples.

As shown in FIG. 11H, a planarization tool 110 may be used to perform a CMP operation and/or another type of planarization operation to planarize the conductive layer 1135 after the conductive layer 1135 is deposited. The planarization operation results in removal of material from the conductive layer 1135. Remaining material of the conductive layer 1135 corresponds to a source/drain contact 1140a over and/or on the p-type source/drain region 225a (with the p-type metal silicide layer 1120 between the p-type source/drain region 225a and the source/drain contact 1140a) and a source/drain contact 1140b over and/or on the n-type source/drain region 225b (with the n-type metal silicide layer 1125 between the n-type source/drain region 225b and the source/drain contact 1140b).

In some implementations, the n-type metal silicide layer 1125 is also included between the p-type metal silicide layer 1120 and the source/drain contact 1140a if the n-type metal silicide layer 1125 is not removed from the p-type metal silicide layer 1120. In some implementations, the source/drain contact 1140a is included directly on the p-type metal silicide layer 1120 if the n-type metal silicide layer 1125 is removed from the p-type metal silicide layer 1120.

In some implementations, the capping layer 1130 is also included between the n-type metal silicide layer 1125 and the source/drain contact 1140b if the capping layer 1130 is formed on the n-type metal silicide layer 1125. In some implementations, the source/drain contact 1140b is included directly on the n-type metal silicide layer 1125 if the capping layer 1130 is omitted from the n-type source/drain region 225b.

As shown in FIG. 11I, an etch stop layer (ESL) 1145 is formed over and/or on the dielectric layer 1105. The ESL 1145 may also be formed over and/or on the source/drain contacts 1140a and 1140b. Another dielectric layer 1150 (e.g., another ILD layer) is formed over and/or on the ESL 1145. The ESL 1145 may include a silicon nitride (SiₓN_{y}), silicon carbon nitride (SiCN), carbon nitride (CN), silicon oxynitride (SiON), silicon carbon oxide (SiCO), or a combination thereof, among other examples. In some implementations, the dielectric layer 1150 includes silicon carbide (SiC), lanthanum oxide (LaₓO_{y}), aluminum oxide (AlₓO_{y}), aluminum oxynitride (AlON), zirconium oxide (ZrOₓ), hafnium oxide (HfOₓ), silicon nitride (SiₓN_{y}), silicon (Si), zinc oxide (ZnO), zirconium nitride (ZrN), zirconium aluminum oxide (ZrAlO), titanium oxide (TiOₓ), yttrium oxide (YₓO_{y}), tantalum carbonitride (TaCN), zirconium silicide (ZrSi), silicon oxycarbonitride (SiOCN), silicon oxycarbide (SiOC), silicon carbonitride (SiCN), hafnium silicide (HfSi), and/or silicon oxide (SiOₓ), among other examples.

A deposition tool 102 may be used to deposit the ESL 1145 using a PVD technique, an ALD technique, a CVD technique, an oxidation technique, another type of deposition technique described in connection with FIG. 1, and/or another suitable deposition technique. The ESL 1145 may be deposited in one or more deposition operations. In some implementations, a planarization tool 110 may be used to planarize the ESL 1145 after the ESL 1145 is deposited. A deposition tool 102 may be used to deposit the dielectric layer 1150 using a PVD technique, an ALD technique, a CVD technique, an oxidation technique, another type of deposition technique described in connection with FIG. 1, and/or another suitable deposition technique. The dielectric layer 1150 may be deposited in one or more deposition operations. In some implementations, a planarization tool 110 may be used to planarize the dielectric layer 1150 after the dielectric layer 1150 is deposited.

As further shown in FIG. 11I, a source/drain interconnect 1155a is formed through the dielectric layer 1150 and the ESL 1145, and is electrically coupled and/or physically coupled with the source/drain contact 1140a. A source/drain interconnect 1155b is formed through the dielectric layer 1150 and the ESL 1145, and is electrically coupled and/or physically coupled with the source/drain contact 1140b. The source/drain interconnects 1155a and 1155b may be connected with other metallization layers and/or interconnects in an interconnect structure in the semiconductor device 200.

In some implementations, a pattern in a photoresist layer is used to etch the dielectric layer 1150 and the ESL 1145 to form recesses through the dielectric layer 1150 and through the ESL 1145. A recess may be formed over the source/drain contact 1140a such that a top surface of the source/drain contact 1140a is exposed through the recess. Another recess may be formed over the source/drain contact 1140b such that a top surface of the source/drain contact 1140b is exposed through the recess. In these implementations, a deposition tool 102 may be used to form the photoresist layer on the dielectric layer 1150. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 1150 and/or the ESL 1145 based on the pattern to form the recesses in the dielectric layer 1150 and/or in the ESL 1145. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 1150 and/or the ESL 1145 based on a pattern.

A deposition tool 102 and/or a plating tool 112 may be used to deposit the source/drain interconnect 1155a in the recess above the source/drain contact 1140a using a CVD technique, a PVD technique, an ALD technique, an electroplating technique, another deposition technique described above in connection with FIG. 1, and/or another suitable deposition technique. The source/drain interconnect 1155a may be deposited in one or more deposition operations. In some implementations, a seed layer is first deposited, and the source/drain interconnect 1155a is deposited on the seed layer. In some implementations, a planarization tool 110 may be used to planarize the source/drain interconnect 1155a after the source/drain interconnect 1155a is deposited.

A deposition tool 102 and/or a plating tool 112 may be used to deposit the source/drain interconnect 1155b in the recess above the source/drain contact 1140b using a CVD technique, a PVD technique, an ALD technique, an electroplating technique, another deposition technique described above in connection with FIG. 1, and/or another suitable deposition technique. The source/drain interconnect 1155b may be deposited in one or more deposition operations. In some implementations, a seed layer is first deposited, and the source/drain interconnect 1155b is deposited on the seed layer. In some implementations, a planarization tool 110 may be used to planarize the source/drain interconnect 1155b after the source/drain interconnect 1155b is deposited.

As further shown in FIG. 11I, the semiconductor device 200 may have one or more dimensions. An example dimension D1 includes an x-direction width of the p-type metal silicide layer 1120 on the p-type source/drain region 225a. In some implementations, the dimension D1 is included in a range of approximately 1 nanometer to approximately 100 nanometers to achieve a sufficiently low contact resistance for the p-type source/drain region 225a. However, other values for the range are within the scope of the present disclosure. Another example dimension D2 includes a z-direction thickness of the p-type metal silicide layer 1120. In some implementations, the dimension D2 is included in a range of approximately 1 nanometer to approximately 10 nanometers to achieve a sufficiently low contact resistance for the p-type source/drain region 225a. However, other values for the range are within the scope of the present disclosure.

An example dimension D3 includes a z-direction thickness of the n-type metal silicide layer 1125 on the n-type source/drain region 225b. In some implementations, the dimension D3 is included in a range of approximately 1 nanometer to approximately 10 nanometers to achieve a sufficiently low contact resistance for the n-type source/drain region 225b. However, other values for the range are within the scope of the present disclosure. Another example dimension D4 includes a y-direction width of the p-type metal silicide layer 1120. In some implementations, the dimension D4 is included in a range of approximately 1 nanometer to approximately 30 nanometers to achieve a sufficiently low contact resistance for the p-type source/drain region 225a. However, other values for the range are within the scope of the present disclosure.

As indicated above, the number and arrangement of operations and devices shown in FIGS. 11A-11I are provided as one or more examples. In practice, there may be additional operations and devices, fewer operations and devices, different operations and devices, or differently arranged operations and devices than those shown in FIGS. 11A-11I.

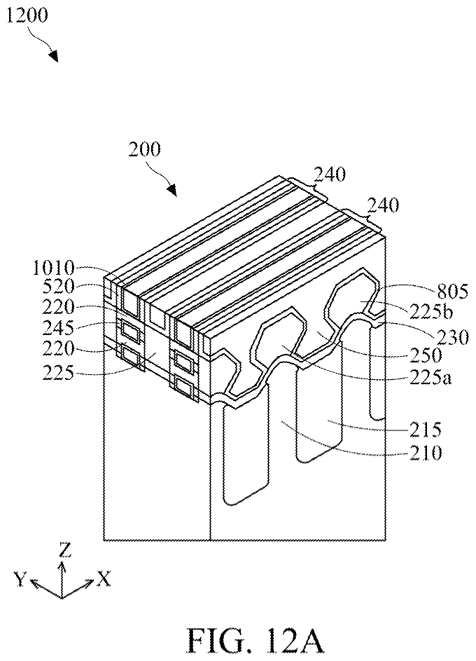

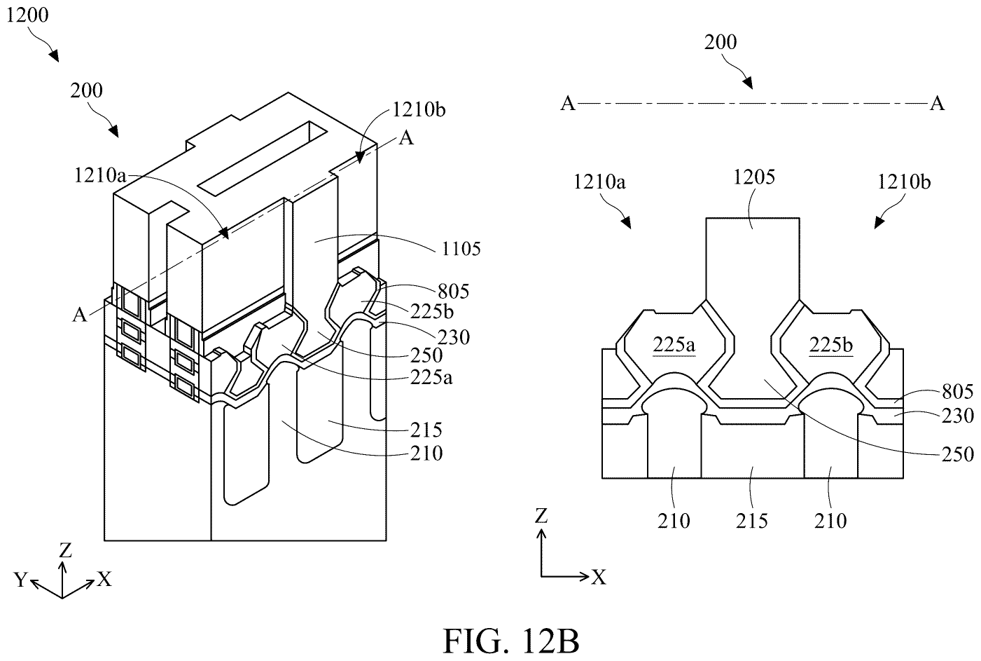

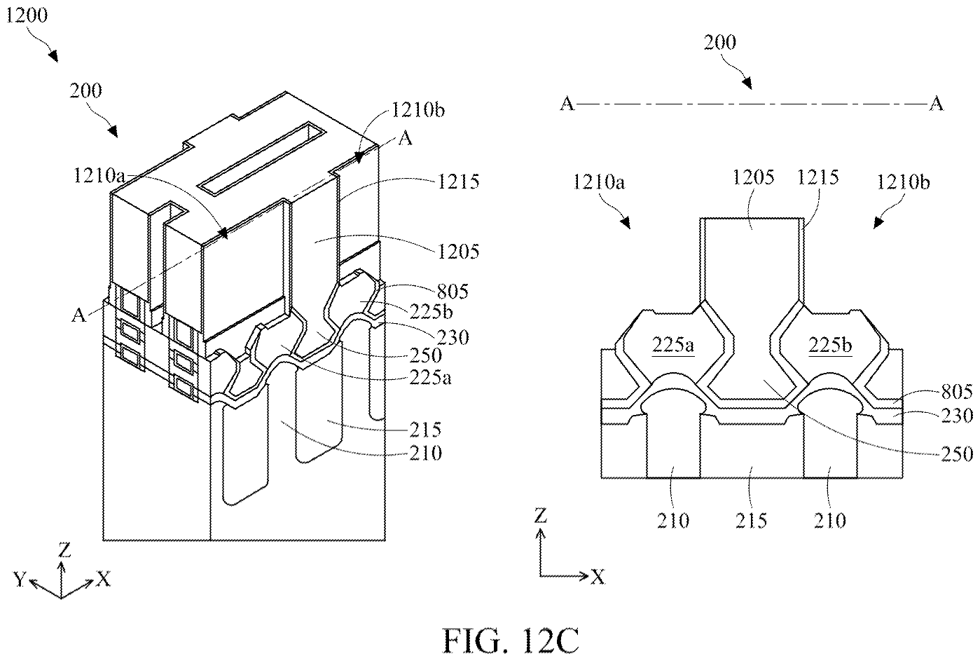

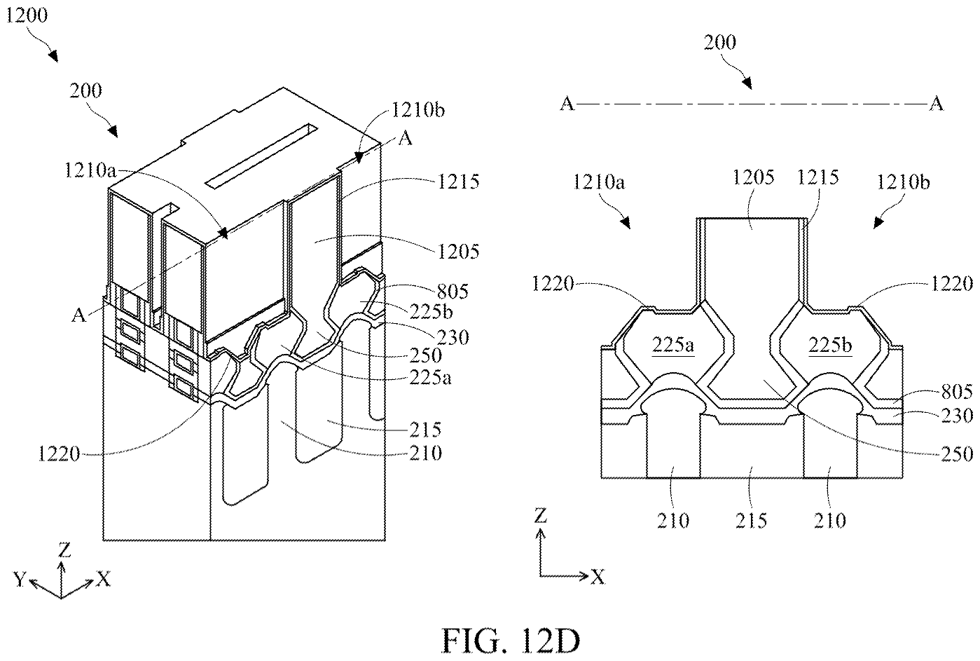

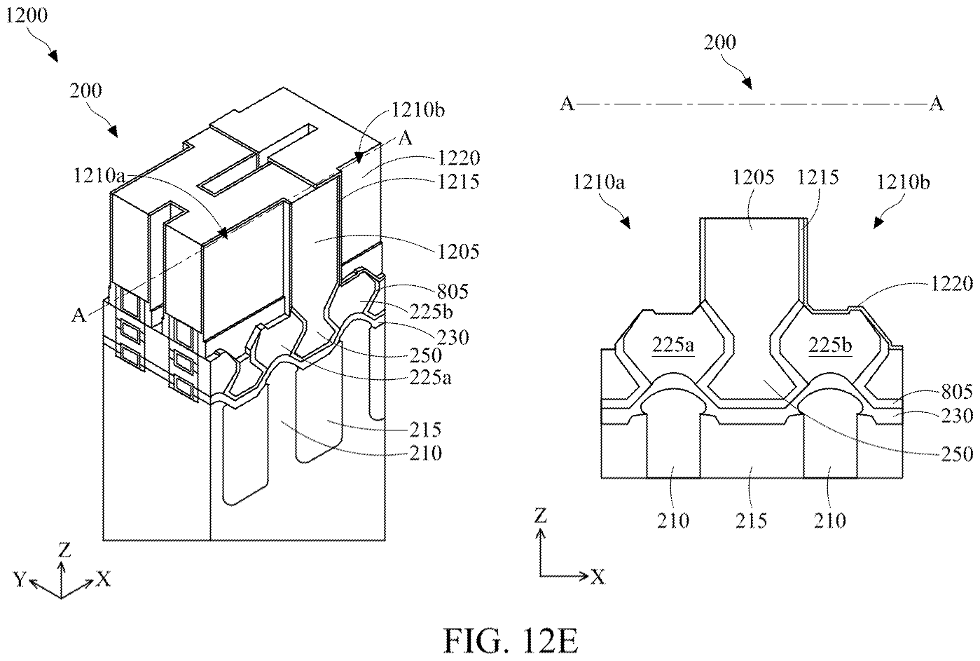

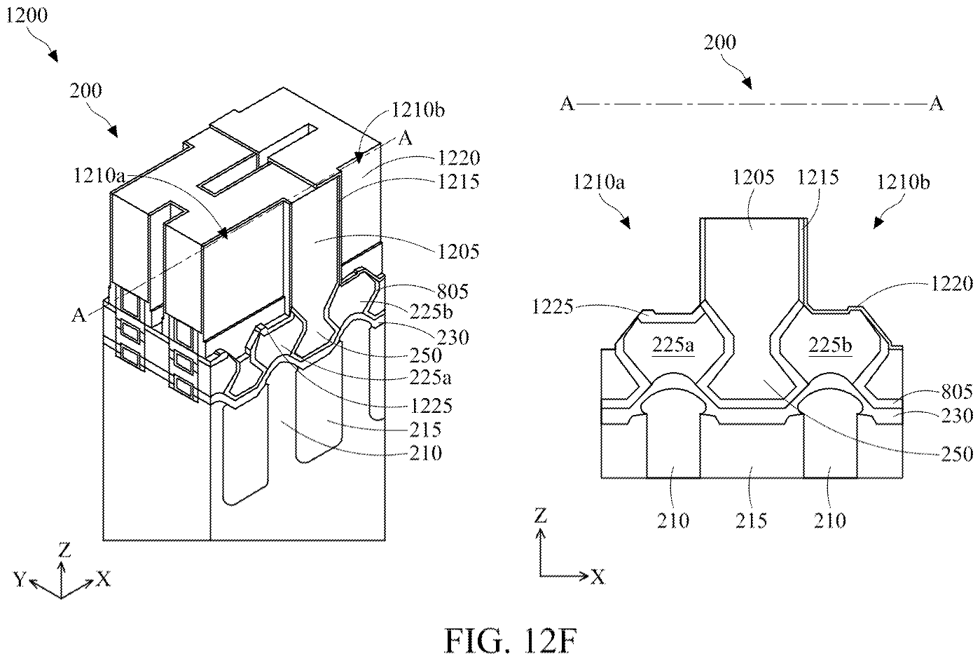

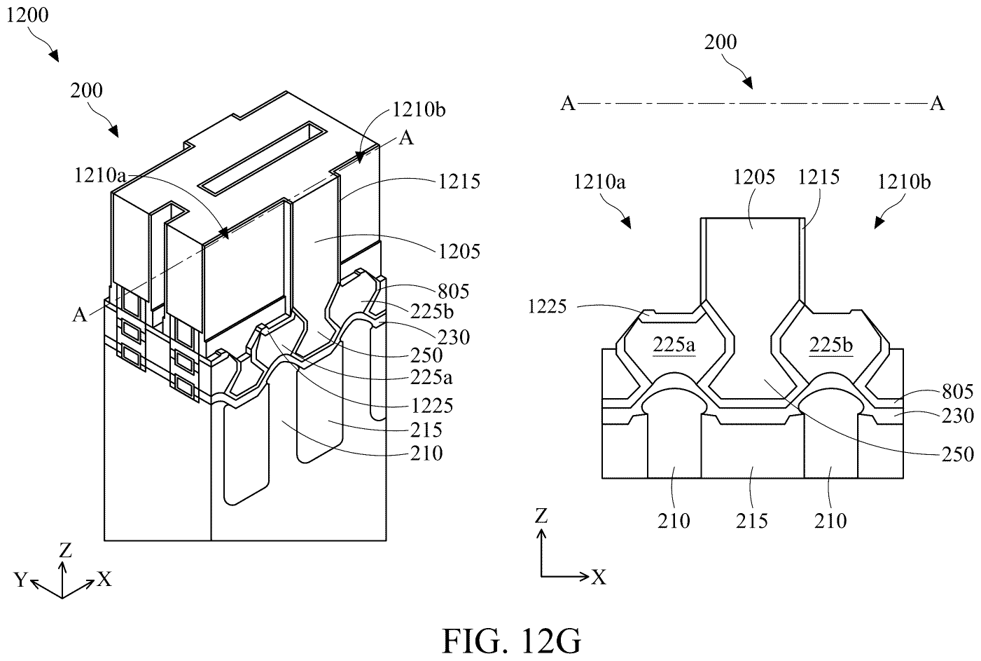

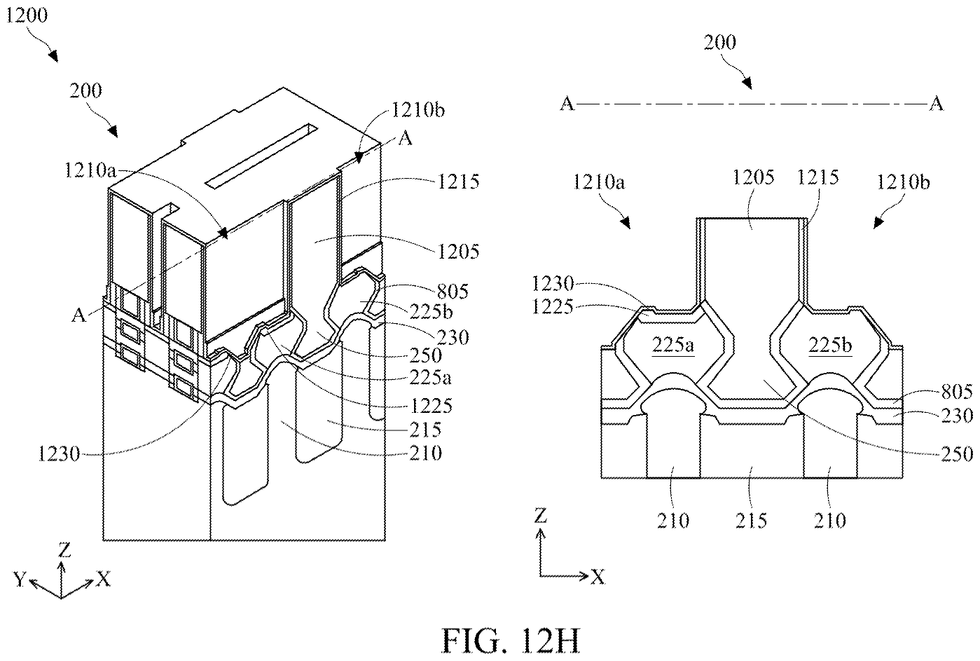

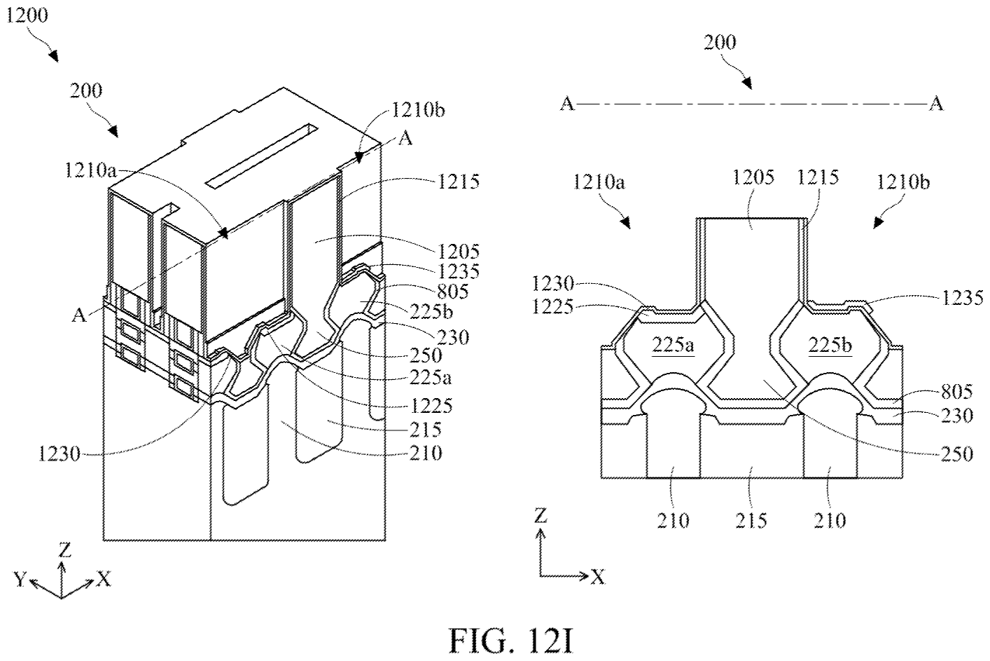

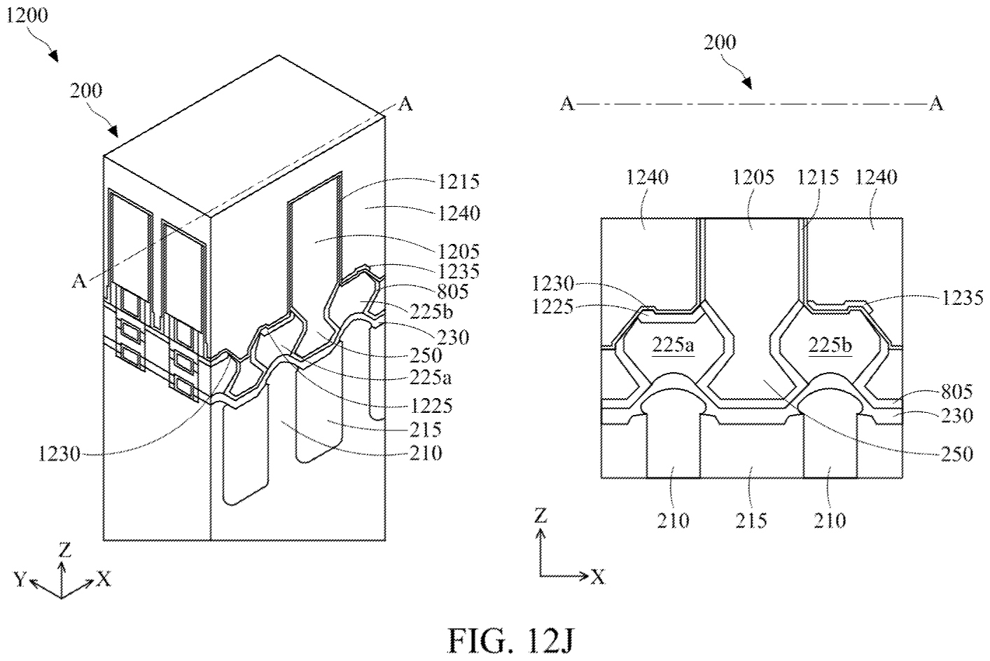

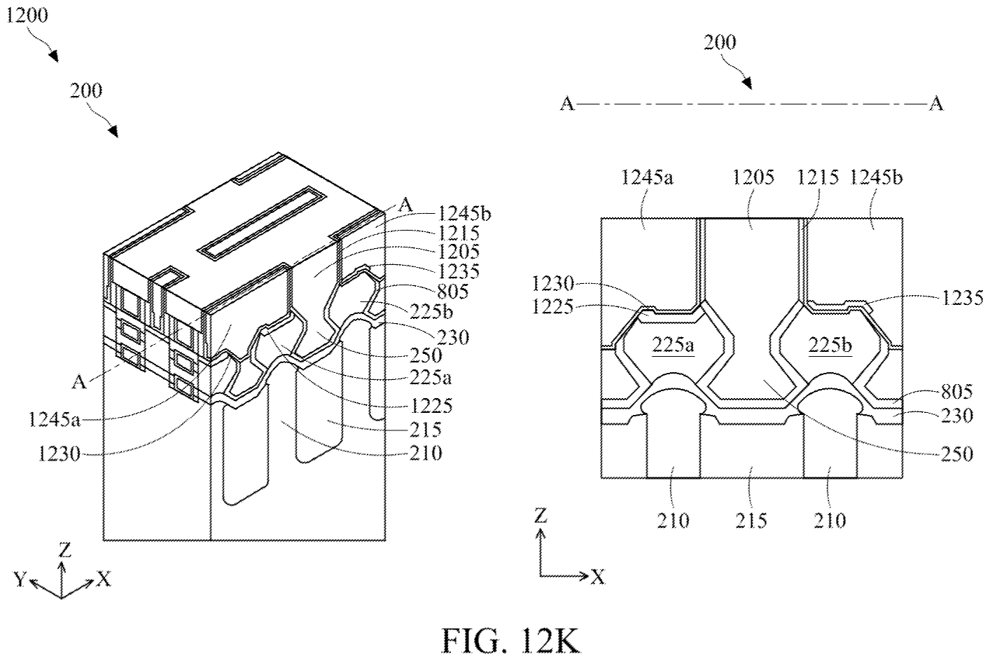

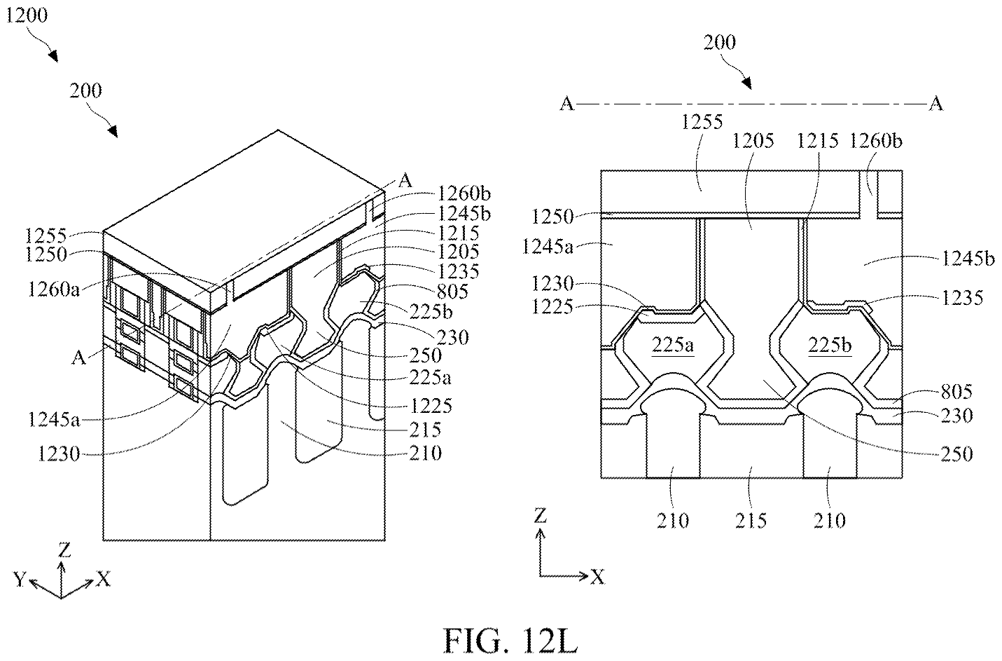

FIGS. 12A-12L are diagrams of an example implementation 1200 of forming an active region isolation structure described herein. One or more of FIGS. 12A-12L are illustrated from one or more perspectives illustrated in FIG. 5, including the perspective of the cross-sectional plane A-A in FIG. 5 (e.g., in the x-direction across a plurality of source/drain regions 225 that are adjacent to a sidewall of a gate structure 240).

The example implementation 1200 includes an example of forming a p-type metal silicide layer on a p-type source/drain region 225a of the semiconductor device 200 using a masking layer over the n-type source/drain region 225b. The use of the masking layer of the n-type source/drain region 225b enables metals to be used for the p-type metal silicide layer that might otherwise also form on the n-type source/drain region 225b such as titanium silicide (TiSi). In other words, the use of the masking layer enables the p-type metal silicide layer to be formed using non-selective metals.

Turning to FIG. 12A, the operations described in connection with the example implementation 1200 are performed after the operations described in connection with FIGS. 3A-10C.

As shown in FIG. 12B, a dielectric layer 1205 is formed in a similar manner as described above in connection with FIG. 11B for the dielectric layer 1105. Source/drain recesses 1210a and 1210b are formed in a similar manner as described above in connection with FIG. 11B for the source/drain recesses 1110a and 1110b, respectively.

As shown in FIG. 12C, a silicide blocking layer 1215 is formed on the sidewalls of the dielectric layer 1105. The silicide blocking layer 1215 may be formed in a similar manner as described above in connection with FIG. 11C for the silicide blocking layer 1115.

As shown in FIG. 12D, a masking layer 1220 is formed over the semiconductor device 200. The masking layer 1220 may be formed in the source/drain recess 1210a over the p-type source/drain region 225a, and in the source/drain recess 1210b over the n-type source/drain region 225b. The masking layer 1220 may include an aluminum oxide (AlₓO_{y}) and/or another suitable hard mask material. A deposition tool 102 may be used to deposit the masking layer 1220 using a PVD technique, an ALD technique, a CVD technique, an oxidation technique, another type of deposition technique described in connection with FIG. 1, and/or another suitable deposition technique. The masking layer 1220 may be deposited in one or more deposition operations.

As shown in FIG. 12E, a portion of the masking layer 1220 is removed from the semiconductor device 200, including from the source/drain recess 1210a. Removing the portion of the masking layer 1220 results in the p-type source/drain region 225a being exposed through the masking layer 1220. A remaining portion of the masking layer 1220 remains over the n-type source/drain region 225b in the source/drain recess 1210b.

In some implementations, a pattern in a photoresist layer is used to etch the masking layer 1220 to remove the portion of the masking layer 1220. In these implementations, a deposition tool 102 may be used to form the photoresist layer on the masking layer 1220. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the masking layer 1220 based on the pattern to remove the portion of the masking layer 1220. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the masking layer 1220 based on a pattern.

As shown in FIG. 12F, a p-type metal silicide layer 1225 is formed on the top surface of the p-type source/drain region 225a in the source/drain recess 1210a. The p-type metal silicide layer 1225 may be formed in a similar manner as described above in connection with FIG. 11D for the p-type metal silicide layer 1120, except that the remaining portion of the masking layer 1220 protects the n-type source/drain region 225b from p-type metal silicide formation in the example implementation 1200. This enables non-selective p-type metals to be used for the p-type metal silicide layer 1225 such as titanium (Ti). Thus, the p-type metal silicide layer 1225 may include a titanium silicide (TiSi), alone or in combination with one or more of the other p-type metal silicide materials described above in connection with FIGS. 11A-11I.

As shown in FIG. 12G, the remaining portions of the masking layer 1220 are removed from the semiconductor device 200 (e.g., from the source/drain recess 1210b and from the n-type source/drain region 225b in the source/drain recess 1210b). In some implementations, an etch tool 108 is used to etch the masking layer 1220 to remove the remaining portions of the masking layer 1220. In some implementations, another technique is used to remove the remaining portions of the masking layer 1220.

As shown in FIG. 12H, an n-type metal silicide layer 1230 is formed on the n-type source/drain region 225b in the source/drain recess 1210b and on the p-type metal silicide layer 1225 in the source/drain recess 1210a after the masking layer is removed. The n-type metal silicide layer 1230 may be formed in a similar manner as described above in connection with FIG. 11E for the n-type metal silicide layer 1125. The n-type metal silicide layer 1230 includes one or more n-type metal silicide materials described above in connection with FIGS. 11A-11I, among other examples of n-type metal silicide materials.

As shown in FIG. 121, a capping layer 1235 may be formed on the n-type metal silicide layer 1230 over the n-type source/drain region 225b and/or on the n-type metal silicide layer 1230 over the p-type source/drain region 225a, in a similar manner as described above in connection with FIG. 11F for the capping layer 1130. The capping layer 1235, if formed, is formed in-situ with the n-type metal silicide layer 1230.

After the capping layer(s) 1235 are formed, the layer stack on the top surface of the p-type source/drain region 225a may include the p-type metal silicide layer 1225 (which may include a titanium silicide layer and/or another type of p-type metal silicide layer), alone or in combination with the n-type metal silicide layer 1230 on the p-type metal silicide layer 1225 and/or a capping layer 1235 on the n-type metal silicide layer 1230. After the capping layer(s) 1235 are formed, the layer stack on the top surface of the n-type source/drain region 225b may include the n-type metal silicide layer 1230, alone or in combination with a capping layer 1235 on the n-type metal silicide layer 1230.

In this way, the semiconductor device 200 may include a plurality of nanostructure channels 220 that are arranged in a direction (e.g., the z-direction) that is approximately perpendicular to a semiconductor substrate 205 of the semiconductor device 200, a gate structure 240 wrapping around each of the nanostructure channels 220, a p-type source/drain region 225a adjacent to the nanostructure channel 220, an n-type source/drain region 225b adjacent to the nanostructure channels 220, a p-type metal silicide layer 1225 (e.g., a titanium silicide layer and/or another type of p-type metal silicide layer) on the p-type source/drain region 225a, and an n-type metal silicide layer 1230 on the p-type metal silicide layer 1225 and on the n-type source/drain region 225b. Capping layers 1235 may be included on the n-type metal silicide layer 1230 over the p-type source/drain region 225a and/or over the n-type source/drain region 225b.

As shown in FIG. 12J, a conductive layer 1240 is formed over the semiconductor device 200 such that the conductive layer 1240 fills in the source/drain recesses 1210a and 1210b. The conductive layer 1240 may be formed in a similar manner as described above in connection with FIG. 11G for the conductive layer 1135.

As shown in FIG. 12K, a planarization operation is performed to planarize the conductive layer 1240 to form source/drain contacts 1245a and 1245b in a similar manner as described above in connection with FIG. 11H for the source/drain contacts 1140a and 1140b.

As shown in FIG. 12L, an ESL 1250, a dielectric layer 1255, and source/drain interconnects 1260a and 1260b may be formed in a similar manner as described above in connection with FIG. 11I for the ESL 1145, the dielectric layer 1150, and the source/drain interconnects 1155a and 1155b, respectively.

As indicated above, the number and arrangement of operations and devices shown in FIGS. 12A-12L are provided as one or more examples. In practice, there may be additional operations and devices, fewer operations and devices, different operations and devices, or differently arranged operations and devices than those shown in FIGS. 12A-12L.

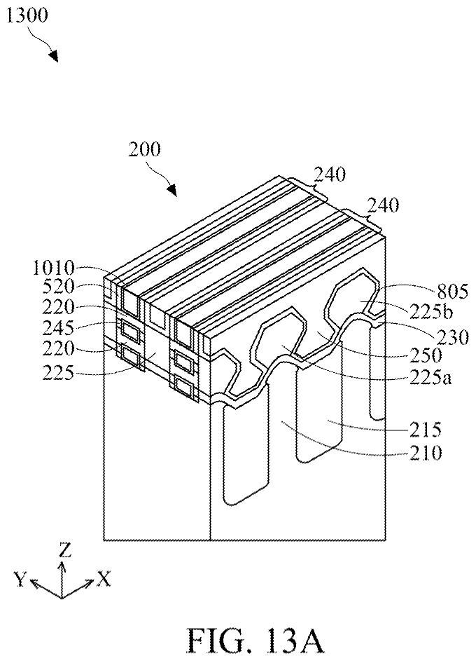

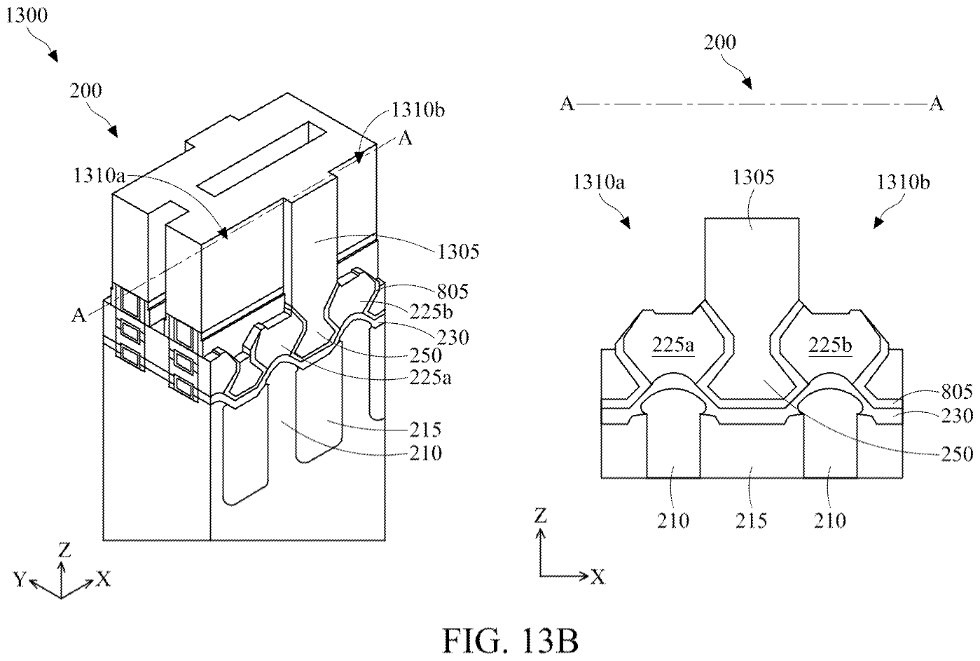

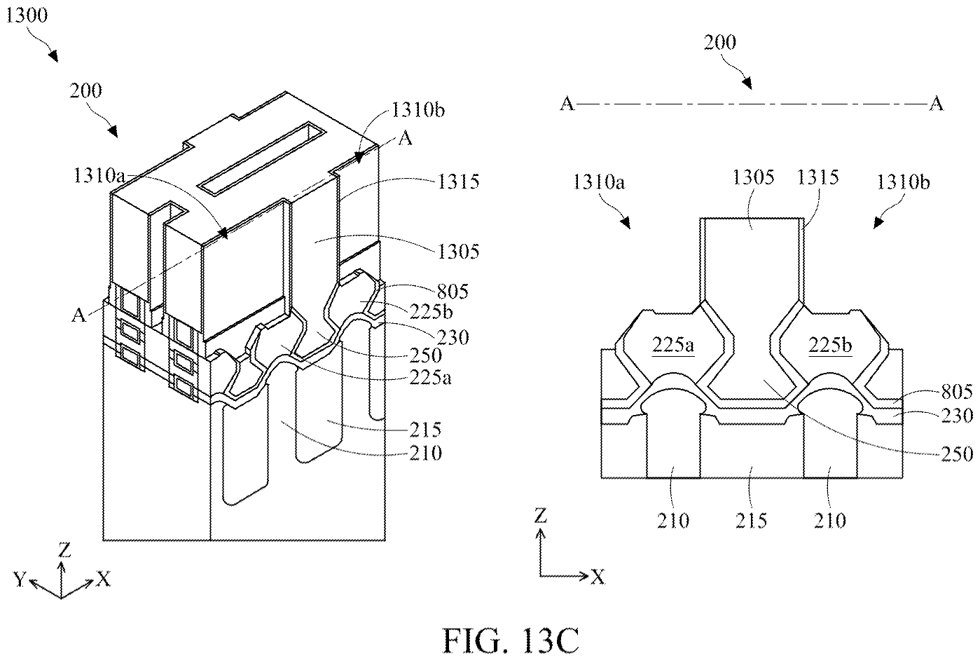

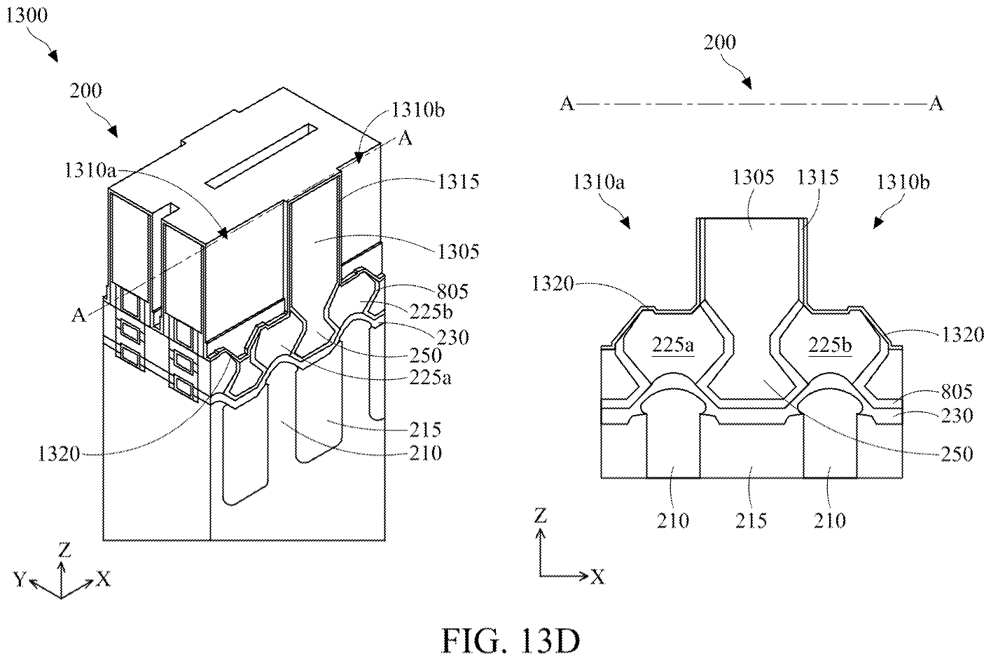

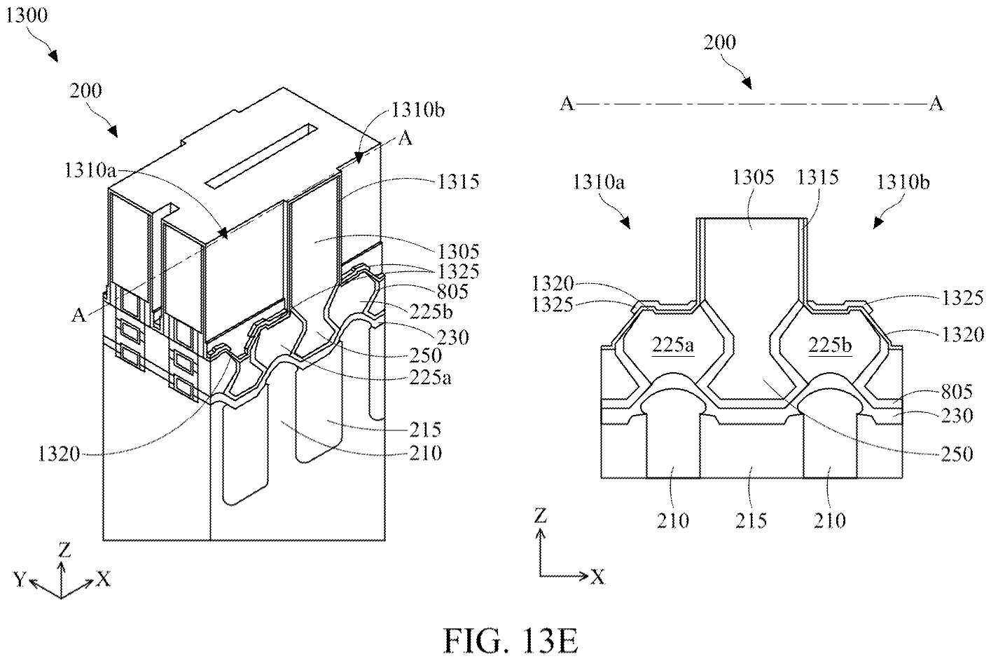

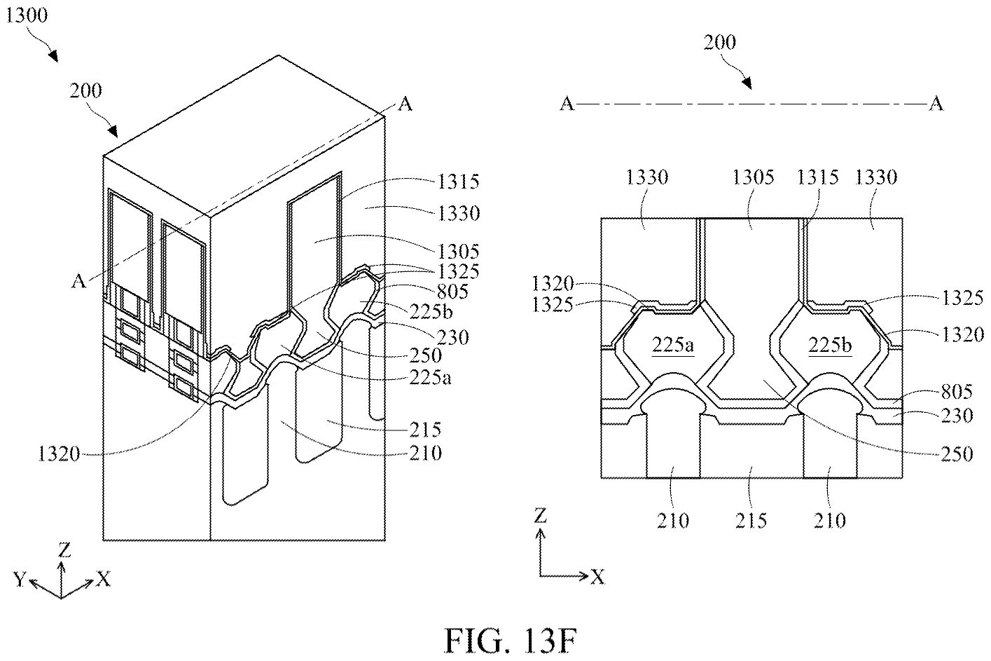

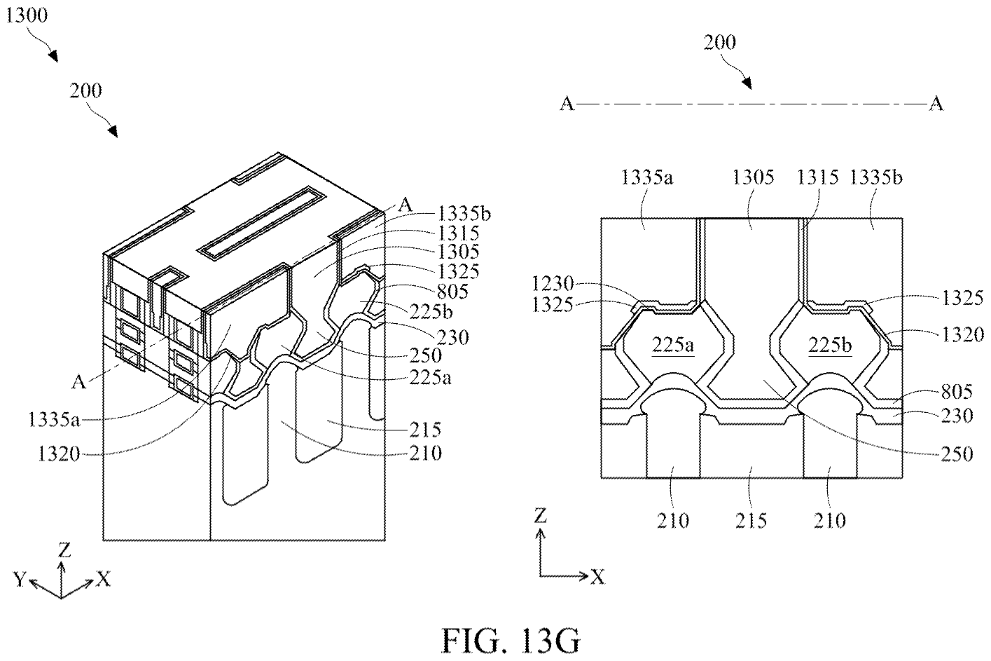

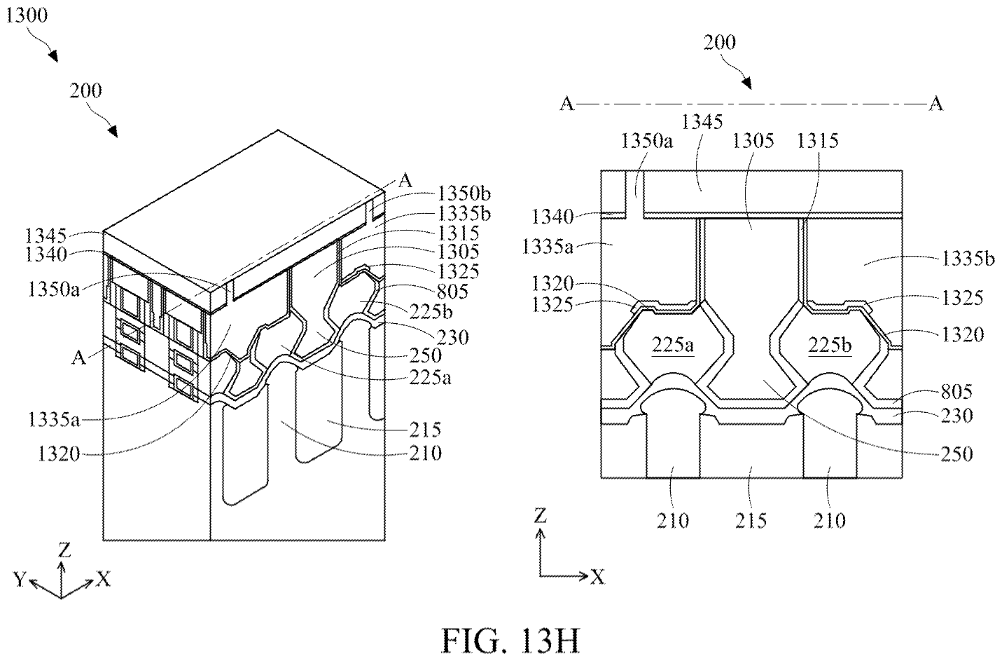

FIGS. 13A-13H are diagrams of an example implementation 1300 of forming an active region isolation structure described herein. One or more of FIGS. 13A-13H are illustrated from one or more perspectives illustrated in FIG. 5, including the perspective of the cross-sectional plane A-A in FIG. 5 (e.g., in the x-direction across a plurality of source/drain regions 225 that are adjacent to a sidewall of a gate structure 240).

The example implementation 1300 includes an example of forming a first metal silicide layer of a first type on a p-type source/drain region 225a and on an n-type source/drain region 225b of the semiconductor device 200 without using a masking layer, and then forming a second metal silicide layer of a second type different from the first type on the first metal silicide layer over the p-type source/drain region 225a and over the n-type source/drain region 225b without using a masking layer. The quantity of process steps for forming the semiconductor device 200 can be reduced by not using masking layers for forming the silicide layers for the p-type source/drain region 225a and for the n-type source/drain region 225b, which reduces the complexity, cost, and/or time of manufacturing the semiconductor device 200 relative to using masking layers.

The metal silicide type for the first metal silicide layer that is formed can be selected based on the performance effects of the first metal silicide layer on the p-type source/drain region 225a, the performance effects on the first metal silicide layer on the n-type source/drain region 225b, and/or the overall performance effects on the semiconductor device 200. For example, in some implementations, forming a p-type metal silicide layer on the p-type source/drain region 225a and on the n-type source/drain region 225b first may result in lesser overall contact resistance for semiconductor device 200 than if an n-type metal silicide layer were formed first. Thus, in these implementations, the p-type metal silicide layer may be formed first, and the n-type metal silicide layer may be formed on the p-type metal silicide layer. As another example, in some implementations, if forming a p-type metal silicide layer on the p-type source/drain region 225a and on the n-type source/drain region 225b first may result in greatly increased contact resistance for the n-type source/drain region 225b, an n-type metal silicide layer may be formed on the p-type source/drain region 225a and on the n-type source/drain region 225b first, followed by the p-type metal silicide layer on the n-type metal silicide layer.

Turning to FIG. 13A, the operations described in connection with the example implementation 1300 are performed after the operations described in connection with FIGS. 3A-10C.

As shown in FIG. 13B, a dielectric layer 1305 is formed in a similar manner as described above in connection with FIG. 11B for the dielectric layer 1105. Source/drain recesses 1310a and 1310b are formed in a similar manner as described above in connection with FIG. 11B for the source/drain recesses 1110a and 1110b, respectively.

As shown in FIG. 13C, a silicide blocking layer 1315 is formed on the sidewalls of the dielectric layer 1305. The silicide blocking layer 1315 may be formed in a similar manner as described above in connection with FIG. 11C for the silicide blocking layer 1115.

As shown in FIG. 13D, a first metal silicide layer 1320 is formed on the top surface of the p-type source/drain region 225a in the source/drain recess 1310a, and on the top surface of the n-type source/drain region 225b in the source/drain recess 1310b. In some implementations, the first metal silicide layer 1320 includes a p-type metal silicide layer, and is formed in a similar manner as described above in connection with FIG. 11D for the p-type metal silicide layer 1120. In these implementations, the first metal silicide layer 1320 may include a titanium silicide (TiSi), alone or in combination with one or more of the other p-type metal silicide materials described above in connection with FIGS. 11A-11I. In some implementations, the first metal silicide layer 1320 includes an n-type metal silicide layer, and is formed on the p-type source/drain region 225a in the source/drain recess 1310a and on the n-type source/drain region 225b in the source/drain recess 1310b in a similar manner as described above in connection with FIG. 11E for the n-type metal silicide layer 1125. In these implementations, the first metal silicide layer 1320 may include one or more of the n-type metal silicide materials described above in connection with FIGS. 11A-11I, among other examples of n-type metal silicide materials. Unreacted metal material from forming the first metal silicide layer 1320 may be removed from the semiconductor device 200.

As shown in FIG. 13E, a second metal silicide layer 1325 is formed on the first metal silicide layer 1320 that is over the p-type source/drain region 225a in the source/drain recess 1310a, and is formed on the first metal silicide layer 1320 that is over the n-type source/drain region 225b in the source/drain recess 1310b. The metal type (e.g., p-type, n-type) of the second metal silicide layer 1325 is different from the first metal silicide layer 1320. For example, if the first metal silicide layer 1320 includes a p-type metal silicide layer, the second metal silicide layer 1325 may be formed as an n-type metal silicide layer. As another example, if the first metal silicide layer 1320 includes an n-type metal silicide layer, the second metal silicide layer 1325 may be formed as a p-type metal silicide layer.

In some implementations, the second metal silicide layer 1325 includes a p-type metal silicide layer, and is formed in a similar manner as described above in connection with FIG. 11D for the p-type metal silicide layer 1120. In these implementations, the second metal silicide layer 1325 may include a titanium silicide (TiSi), alone or in combination with one or more of the other p-type metal silicide materials described above in connection with FIGS. 11A-11I. In some implementations, the second metal silicide layer 1325 includes an n-type metal silicide layer, and is formed on the p-type source/drain region 225a in the source/drain recess 1310a and on the n-type source/drain region 225b in the source/drain recess 1310b in a similar manner as described above in connection with FIG. 11E for the n-type metal silicide layer 1125. In these implementations, the second metal silicide layer 1325 may include one or more of the n-type metal silicide materials described above in connection with FIGS. 11A-11I, among other examples of n-type metal silicide materials. Unreacted metal material from forming the second metal silicide layer 1325 may be removed from the semiconductor device 200.

In some implementations, a capping layer (not shown) may be formed on the second metal silicide layer 1325 over the p-type source/drain region 225a and/or on the n-type source/drain region 225b, in a similar manner as described above in connection with FIG. 11F for the capping layer 1130. The capping layer, if formed, is formed in-situ with the second metal silicide layer 1325.

After the capping layer(s) are formed, the layer stack on the top surface of the p-type source/drain region 225a and on the top surface of the n-type source/drain region 225b may include a p-type metal silicide layer (which may include a titanium silicide and/or another type of p-type metal silicide material), an n-type metal silicide layer on the p-type metal silicide layer (which may include one or more n-type metal silicide materials), and/or a capping layer on the n-type metal silicide layer. Alternatively, the layer stack on the top surface of the p-type source/drain region 225a and on the top surface of the n-type source/drain region 225b may include n-type metal silicide layer (which may include one or more n-type metal silicide materials), a p-type metal silicide layer on the n-type metal silicide layer (which may include a titanium silicide and/or another type of p-type metal silicide material), and/or a capping layer on the p-type metal silicide layer.

In this way, the semiconductor device 200 may include a plurality of nanostructure channels 220 that are arranged in a direction (e.g., the z-direction) that is approximately perpendicular to a semiconductor substrate 205 of the semiconductor device 200, a gate structure 240 wrapping around each of the nanostructure channels 220, a p-type source/drain region 225a adjacent to the nanostructure channel 220, an n-type source/drain region 225b adjacent to the nanostructure channels 220, a first metal silicide layer 1320 on the p-type source/drain region 225a and on the n-type source/drain region 225b, and a second metal silicide layer 1325 on the first metal silicide layer 1320 over the p-type source/drain region 225a and the n-type source/drain region 250b. The first metal silicide layer includes a first metal type, and the second metal silicide layer includes a second metal type that is different from the first metal type. In some implementations, capping layers may be included on the second metal silicide layer 1325 over the p-type source/drain region 225a and/or over the n-type source/drain region 225b.

As shown in FIG. 13F, a conductive layer 1330 is formed over the semiconductor device 200 such that the conductive layer 1330 fills in the source/drain recesses 1310a and 1310b. The conductive layer 1330 may be formed in a similar manner as described above in connection with FIG. 11G for the conductive layer 1135.

As shown in FIG. 13G, a planarization operation is performed to planarize the conductive layer 1330 to form source/drain contacts 1335a and 1335b in a similar manner as described above in connection with FIG. 11H for the source/drain contacts 1140a and 1140b.

As shown in FIG. 13H, an ESL 1340, a dielectric layer 1345, and source/drain interconnects 1350a and 1350b may be formed in a similar manner as described above in connection with FIG. 11I for the ESL 1145, the dielectric layer 1150, and the source/drain interconnects 1155a and 1155b, respectively.

As indicated above, the number and arrangement of operations and devices shown in FIGS. 13A-13H are provided as one or more examples. In practice, there may be additional operations and devices, fewer operations and devices, different operations and devices, or differently arranged operations and devices than those shown in FIGS. 13A-13H.

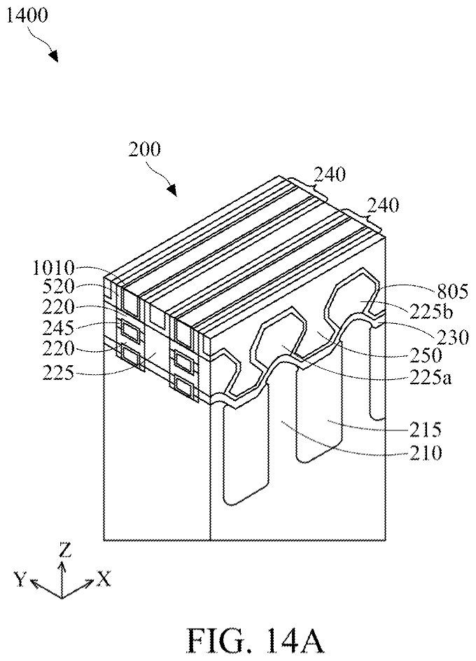

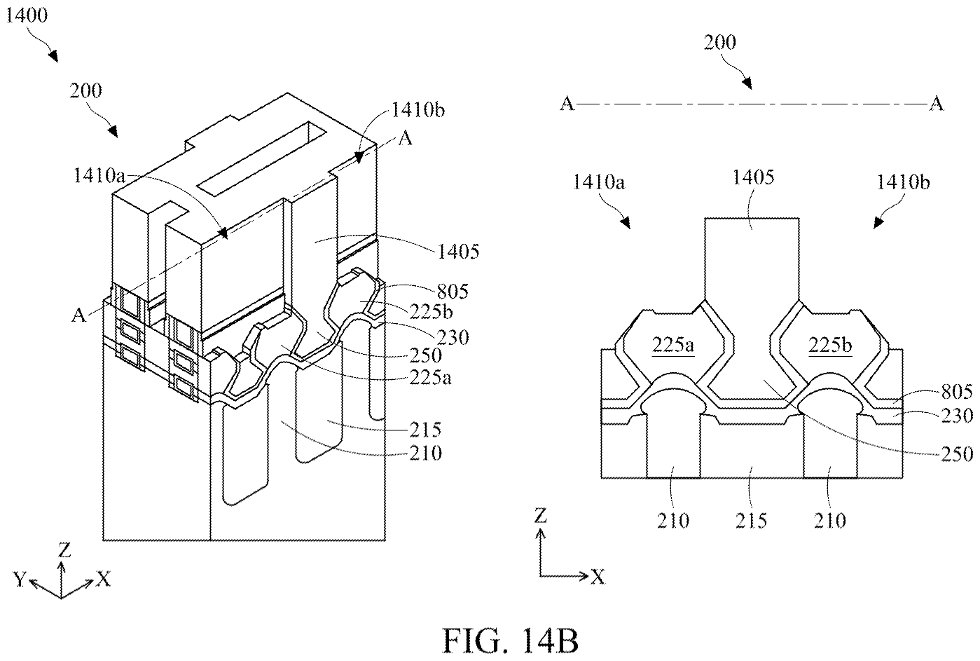

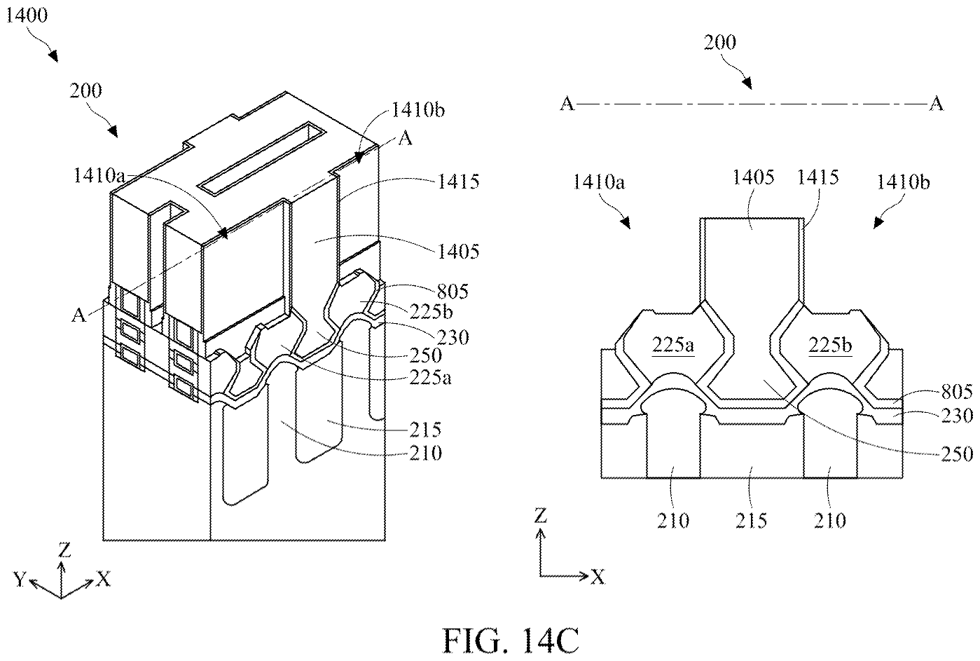

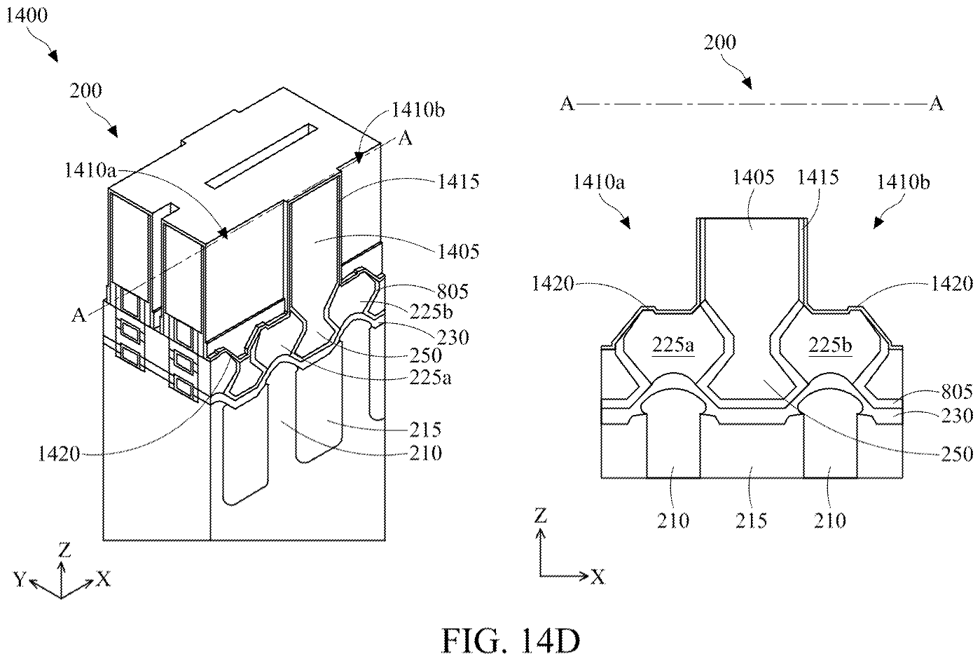

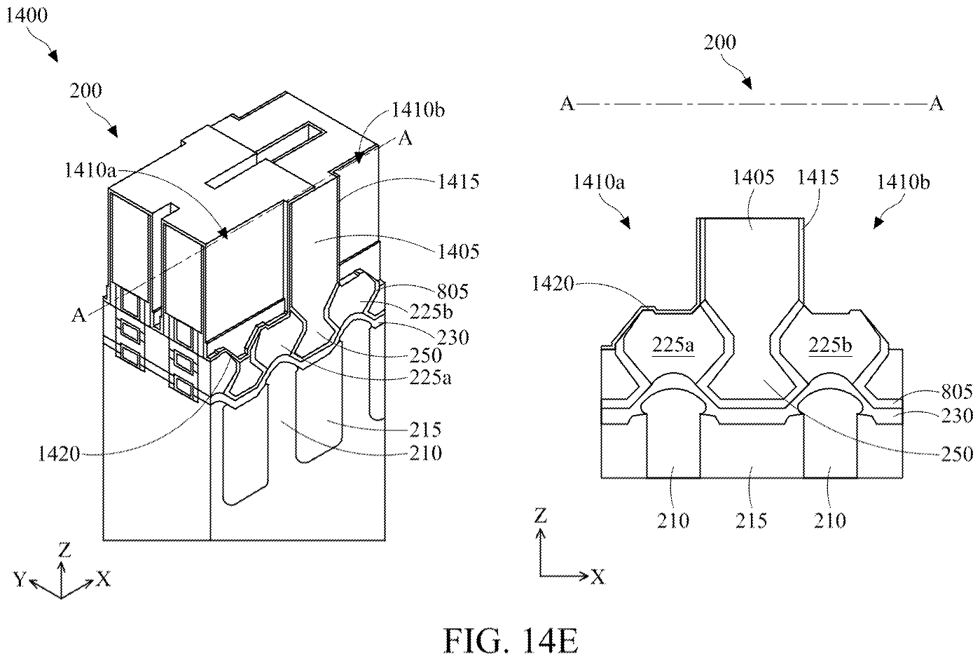

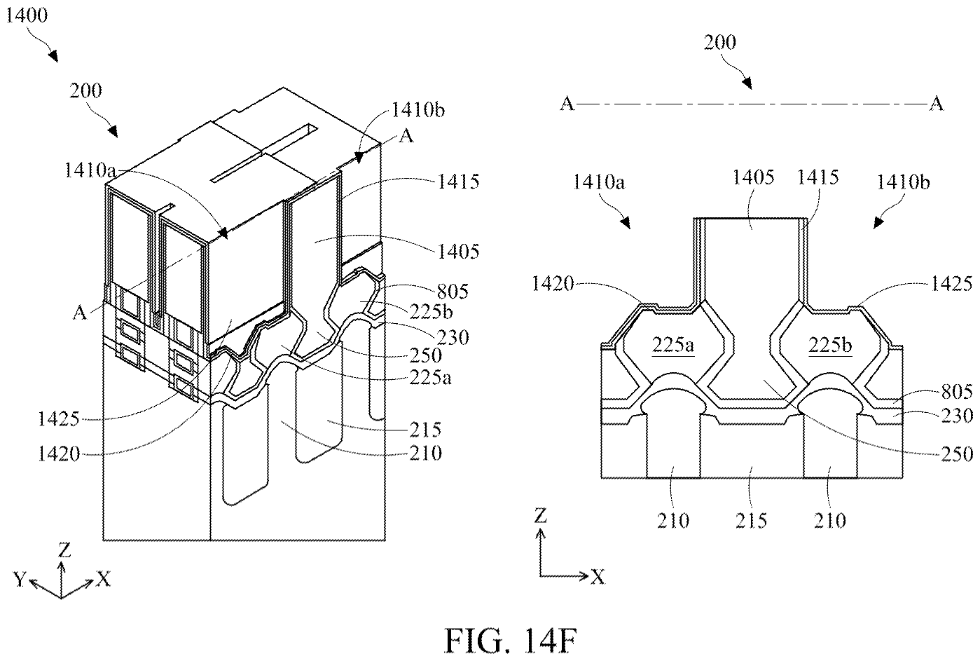

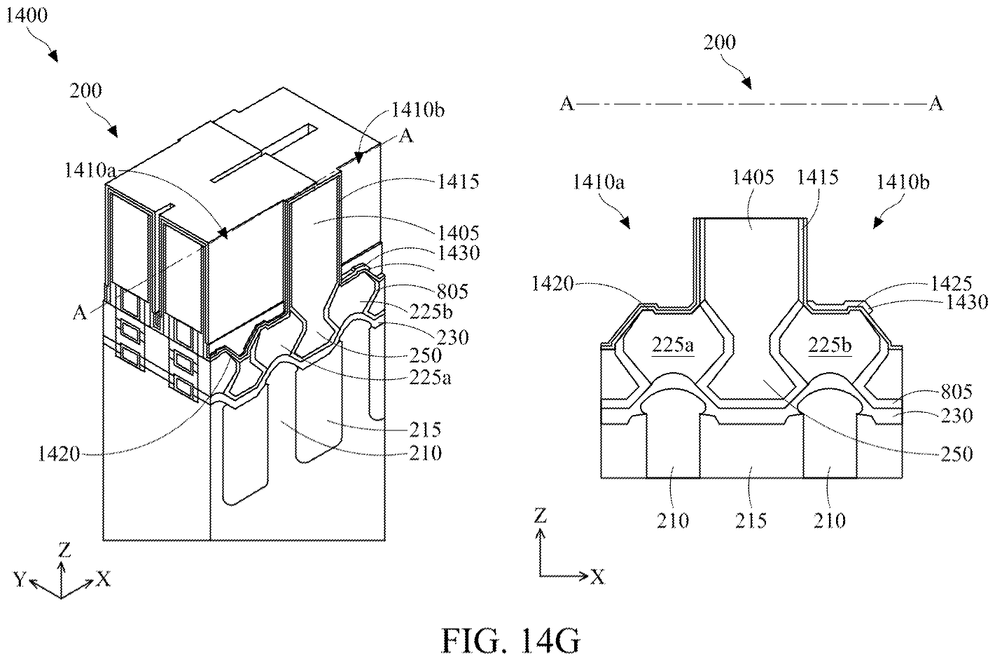

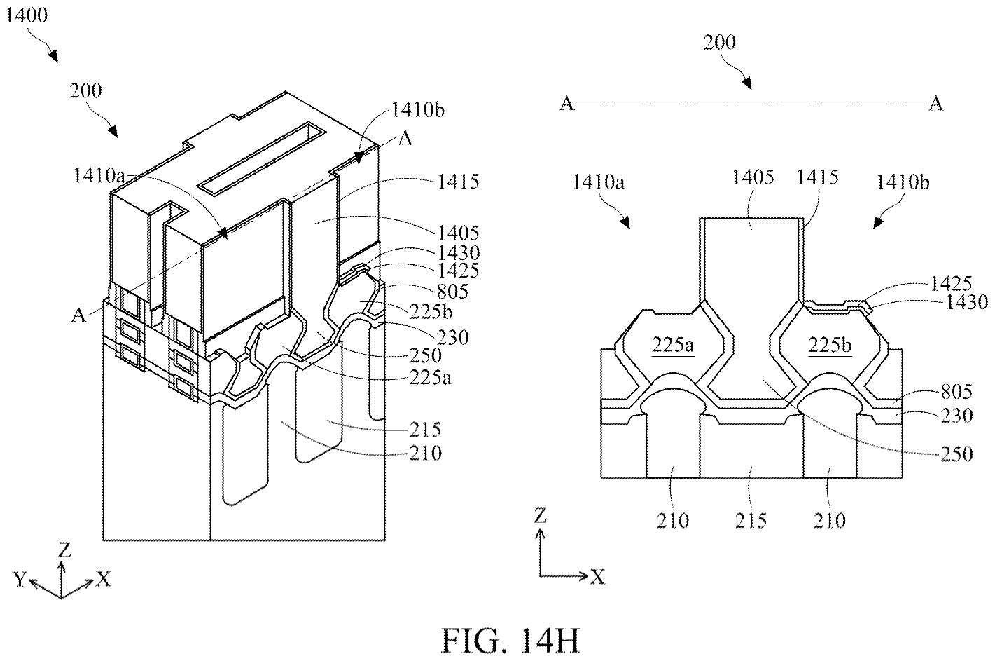

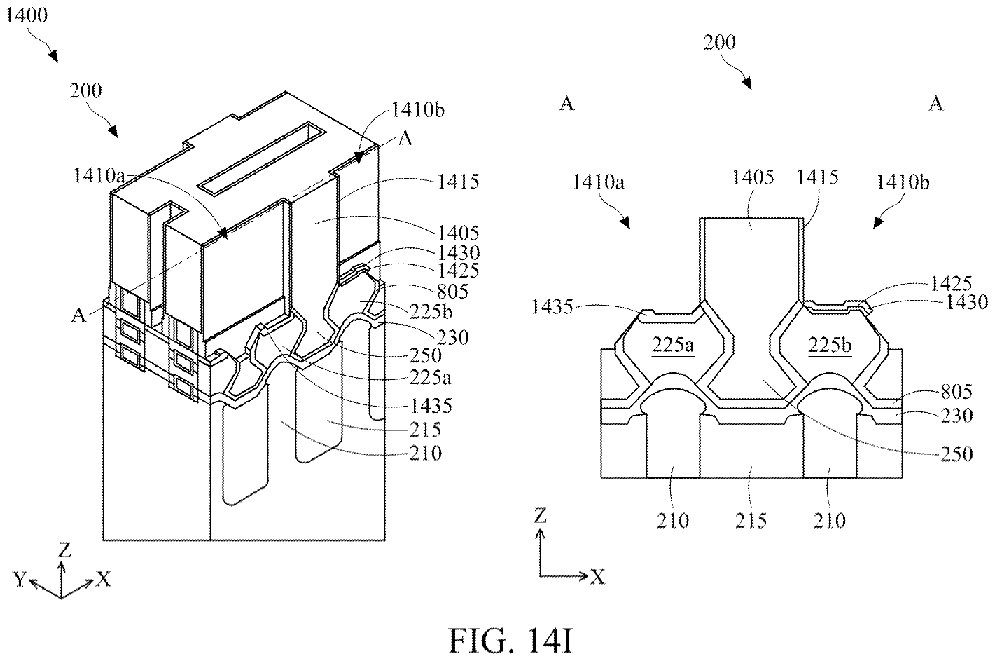

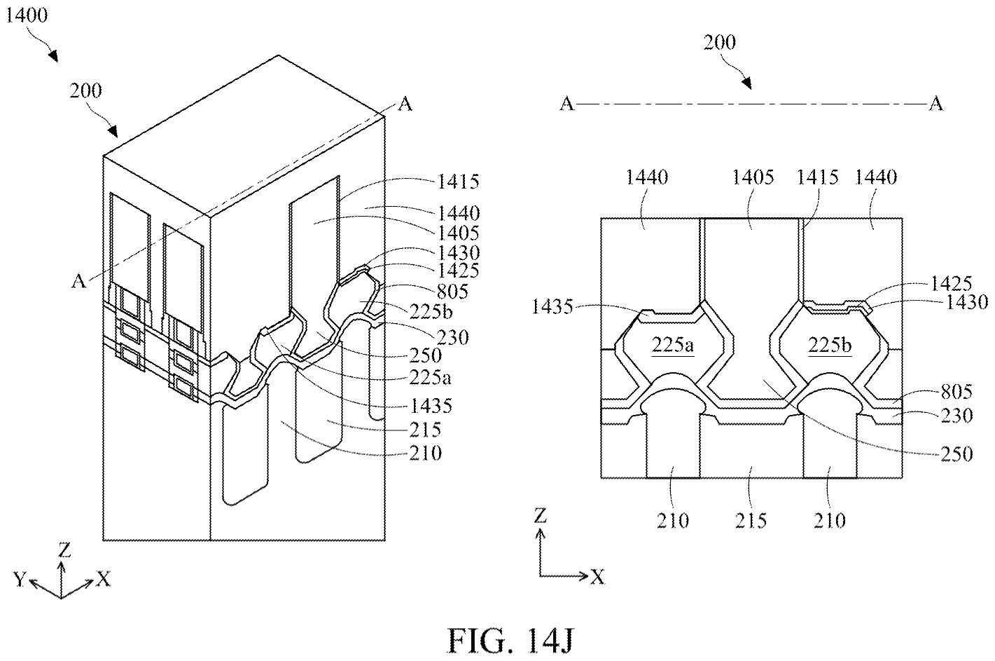

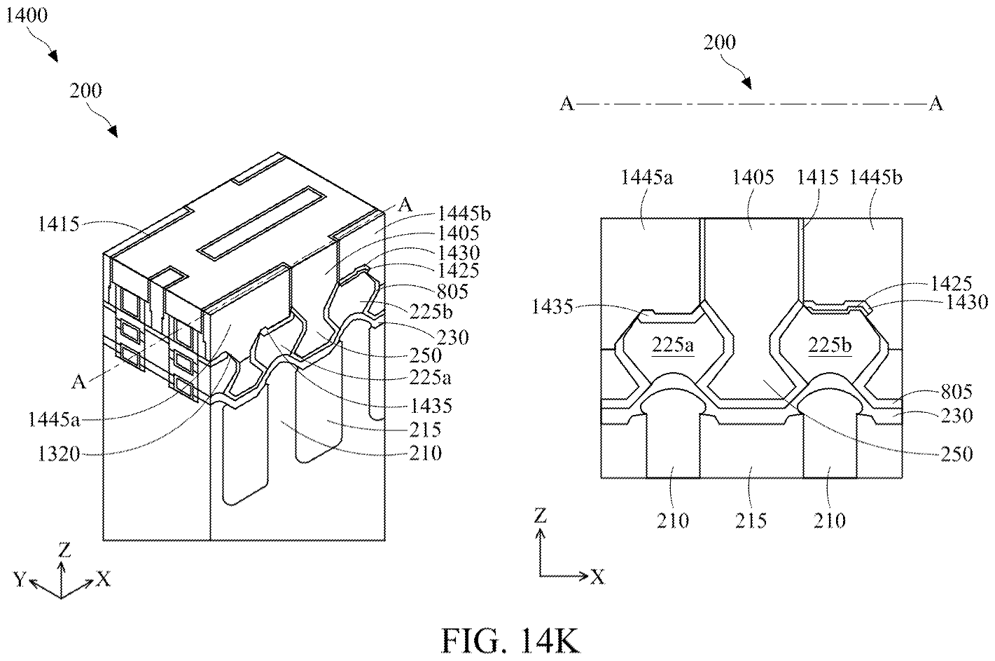

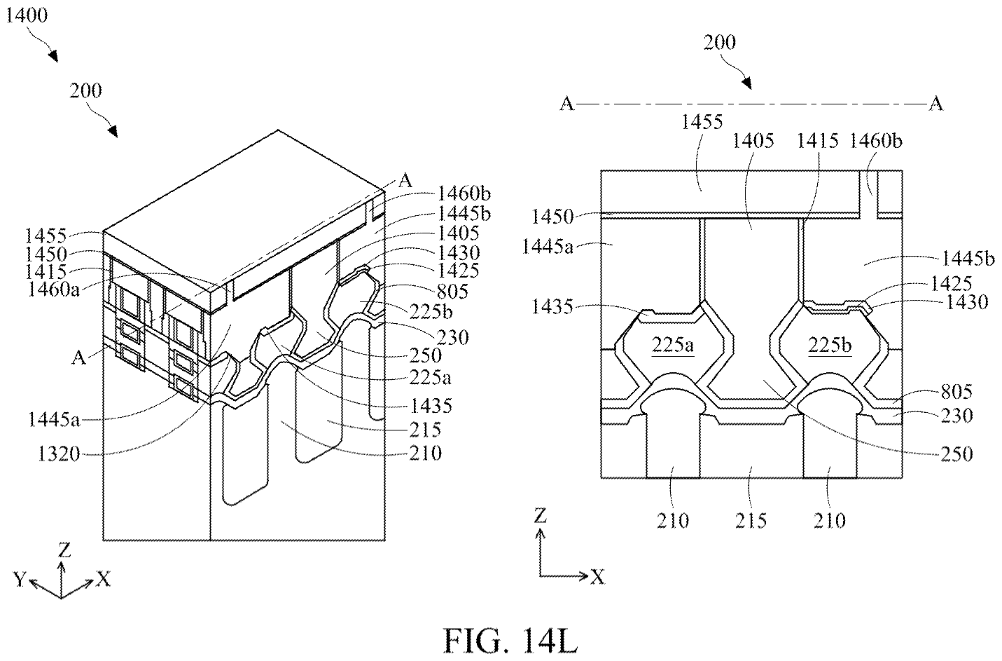

FIGS. 14A-14L are diagrams of an example implementation 1400 of forming an active region isolation structure described herein. One or more of FIGS. 14A-14L are illustrated from one or more perspectives illustrated in FIG. 5, including the perspective of the cross-sectional plane A-A in FIG. 5 (e.g., in the x-direction across a plurality of source/drain regions 225 that are adjacent to a sidewall of a gate structure 240).

The example implementation 1400 includes an example of forming an n-type metal silicide layer on a n-type source/drain region 225b of the semiconductor device 200 using a masking layer over the p-type source/drain region 225a. The use of the masking layer of the p-type source/drain region 225a enables the n-type metal silicide layer to be formed directly on the n-type source/drain region 225b without forming the n-type metal silicide layer on the p-type source/drain region 225a. The p-type metal silicide layer can be subsequently formed directly on the p-type source/drain region 225a without the use of a masking layer, as the p-type metal silicide layer that is formed on the n-type metal silicide layer may have minimal impact on the contact resistance of the n-type source/drain region 225b.

Turning to FIG. 14A, the operations described in connection with the example implementation 1400 are performed after the operations described in connection with FIGS. 3A-10C.

As shown in FIG. 14B, a dielectric layer 1405 is formed in a similar manner as described above in connection with FIG. 11B for the dielectric layer 1105. Source/drain recesses 1410a and 1410b are formed in a similar manner as described above in connection with FIG. 11B for the source/drain recesses 1110a and 1110b, respectively.

As shown in FIG. 14C, a silicide blocking layer 1415 is formed on the sidewalls of the dielectric layer 1405. The silicide blocking layer 1415 may be formed in a similar manner as described above in connection with FIG. 11C for the silicide blocking layer 1115.

As shown in FIG. 14D, a masking layer 1420 is formed over the semiconductor device 200. The masking layer 1420 may be formed in the source/drain recess 1410a over the p-type source/drain region 225a, and in the source/drain recess 1410b over the n-type source/drain region 225b. The masking layer 1420 may include an aluminum oxide (AlₓO_{y}) and/or another suitable hard mask material. A deposition tool 102 may be used to deposit the masking layer 1420 using a PVD technique, an ALD technique, a CVD technique, an oxidation technique, another type of deposition technique described in connection with FIG. 1, and/or another suitable deposition technique. The masking layer 1420 may be deposited in one or more deposition operations.

As shown in FIG. 14E, a portion of the masking layer 1420 is removed from the semiconductor device 200, including from the source/drain recess 1410b. Removing the portion of the masking layer 1420 results in the n-type source/drain region 225b being exposed through the masking layer 1420. A remaining portion of the masking layer 1420 remains over the p-type source/drain region 225a in the source/drain recess 1410a.

In some implementations, a pattern in a photoresist layer is used to etch the masking layer 1420 to remove the portion of the masking layer 1420. In these implementations, a deposition tool 102 may be used to form the photoresist layer on the masking layer 1420. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the masking layer 1420 based on the pattern to remove the portion of the masking layer 1420. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the masking layer 1420 based on a pattern.

As shown in FIG. 14F, an n-type metal silicide layer 1425 is formed directly on the n-type source/drain region 225b in the source/drain recess 1410b. The masking layer 1420 over the p-type source/drain region 225a prevents the n-type silicide layer 1425 from being formed on the p-type source/drain region 225a. The n-type metal silicide layer 1425 may be formed in a similar manner as described above in connection with FIG. 11E for the n-type metal silicide layer 1125. The n-type metal silicide layer 1425 includes one or more n-type metal silicide materials described above in connection with FIGS. 11A-11I, among other examples of n-type metal silicide materials.

As shown in FIG. 14G, a capping layer 1430 may be formed on the n-type metal silicide layer 1425 over the n-type source/drain region 225b in a similar manner as described above in connection with FIG. 11F for the capping layer 1130. The capping layer 1430, if formed, is formed in-situ with the n-type metal silicide layer 1425. Alternatively, the capping layer 1430 may be omitted from the n-type source/drain region 225b.

As shown in FIG. 14H, the remaining portions of the masking layer 1420 are removed from the semiconductor device 200 (e.g., from the source/drain recess 1410a and from the p-type source/drain region 225a in the source/drain recess 1410a). In some implementations, an etch tool 108 is used to etch the masking layer 1420 to remove the remaining portions of the masking layer 1420. In some implementations, another technique is used to remove the remaining portions of the masking layer 1420.

As shown in FIG. 14I, a p-type metal silicide layer 1435 is formed directly on the top surface of the p-type source/drain region 225a in the source/drain recess 1410a after the masking layer 1420 is removed. The p-type metal silicide layer 1435 may be formed in a similar manner as described above in connection with FIG. 11D for the p-type metal silicide layer 1120. The p-type metal silicide layer 1435 may include a titanium silicide (TiSi), alone or in combination with one or more of the other p-type metal silicide materials described above in connection with FIGS. 11A-11I. In some implementations, a capping layer (not shown) may be formed on the p-type metal silicide layer 1435. In some implementations, the p-type metal silicide layer 1435 is also formed on the n-type metal silicide layer 1425 and/or on the capping layer 1430 that is over the n-type source/drain region 225b.

After the p-type metal silicide layer 1435 is formed, the layer stack on the top surface of the p-type source/drain region 225a may include the p-type metal silicide layer 1435 (which may include a titanium silicide layer and/or another type of p-type metal silicide layer), alone or in combination with a capping layer (e.g., a titanium silicide layer and/or another type of capping silicide) on the p-type metal silicide layer 1435. After the p-type metal silicide layer 1435 is formed, the layer stack on the top surface of the n-type source/drain region 225b may include the n-type metal silicide layer 1425, alone or in combination with a capping layer 1430 on the n-type metal silicide layer 1425, a p-type metal silicide layer 1435 on the capping layer 1430, and/or another capping layer on the p-type metal silicide layer 1435, among other examples.

In this way, the semiconductor device 200 may include a plurality of nanostructure channels 220 that are arranged in a direction (e.g., the z-direction) that is approximately perpendicular to a semiconductor substrate 205 of the semiconductor device 200, a gate structure 240 wrapping around each of the nanostructure channels 220, a p-type source/drain region 225a adjacent to the nanostructure channel 220, an n-type source/drain region 225b adjacent to the nanostructure channels 220, an n-type metal silicide layer 1425 on the n-type source/drain region 225b, and a p-type metal silicide layer 1435 on the p-type source/drain region 225a and on the n-type metal silicide layer 1425. Capping layers 1430 may be included on the n-type metal silicide layer 1425 over the n-type source/drain region 225b and/or on the p-type metal silicide layer 1435 that is over the p-type source/drain region 225a and/or over n-type source/drain region 225b.

As shown in FIG. 14J, a conductive layer 1440 is formed over the semiconductor device 200 such that the conductive layer 1440 fills in the source/drain recesses 1410a and 1410b. The conductive layer 1440 may be formed in a similar manner as described above in connection with FIG. 11G for the conductive layer 1135.

As shown in FIG. 14K, a planarization operation is performed to planarize the conductive layer 1440 to form source/drain contacts 1445a and 1445b in a similar manner as described above in connection with FIG. 11H for the source/drain contacts 1140a and 1140b.

As shown in FIG. 14L, an ESL 1450, a dielectric layer 1455, and source/drain interconnects 1460a and 1460b may be formed in a similar manner as described above in connection with FIG. 11I for the ESL 1145, the dielectric layer 1150, and the source/drain interconnects 1155a and 1155b, respectively.

As indicated above, the number and arrangement of operations and devices shown in FIGS. 14A-14L are provided as one or more examples. In practice, there may be additional operations and devices, fewer operations and devices, different operations and devices, or differently arranged operations and devices than those shown in FIGS. 14A-14L.

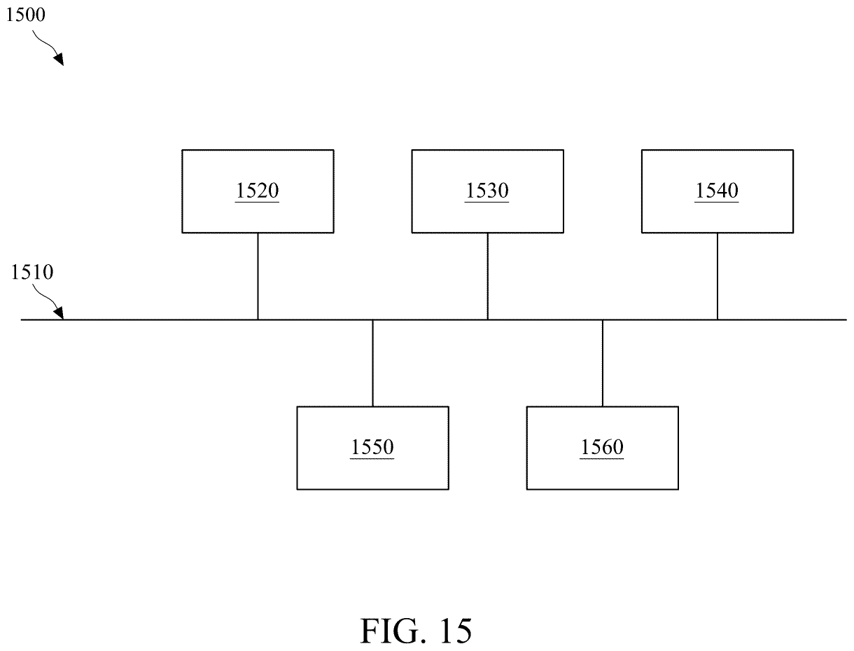

FIG. 15 is a diagram of example components of a device 1500 described herein. In some implementations, one or more of the semiconductor processing tools 102-112 and/or the wafer/die transport tool 114 may include one or more devices 1500 and/or one or more components of the device 1500. As shown in FIG. 15, the device 1500 may include a bus 1510, a processor 1520, a memory 1530, an input component 1540, an output component 1550, and/or a communication component 1560.

The bus 1510 may include one or more components that enable wired and/or wireless communication among the components of the device 1500. The bus 1510 may couple together two or more components of FIG. 15, such as via operative coupling, communicative coupling, electronic coupling, and/or electric coupling. For example, the bus 1510 may include an electrical connection (e.g., a wire, a trace, and/or a lead) and/or a wireless bus. The processor 1520 may include a central processing unit, a graphics processing unit, a microprocessor, a controller, a microcontroller, a digital signal processor, a field-programmable gate array, an application-specific integrated circuit, and/or another type of processing component. The processor 1520 may be implemented in hardware, firmware, or a combination of hardware and software. In some implementations, the processor 1520 may include one or more processors capable of being programmed to perform one or more operations or processes described elsewhere herein.

The memory 1530 may include volatile and/or nonvolatile memory. For example, the memory 1530 may include random access memory (RAM), read only memory (ROM), a hard disk drive, and/or another type of memory (e.g., a flash memory, a magnetic memory, and/or an optical memory). The memory 1530 may include internal memory (e.g., RAM, ROM, or a hard disk drive) and/or removable memory (e.g., removable via a universal serial bus connection). The memory 1530 may be a non-transitory computer-readable medium. The memory 1530 may store information, one or more instructions, and/or software (e.g., one or more software applications) related to the operation of the device 1500. In some implementations, the memory 1530 may include one or more memories that are coupled (e.g., communicatively coupled) to one or more processors (e.g., processor 1520), such as via the bus 1510. Communicative coupling between a processor 1520 and a memory 1530 may enable the processor 1520 to read and/or process information stored in the memory 1530 and/or to store information in the memory 1530.

The input component 1540 may enable the device 1500 to receive input, such as user input and/or sensed input. For example, the input component 1540 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1550 may enable the device 1500 to provide output, such as via a display, a speaker, and/or a light-emitting diode. The communication component 1560 may enable the device 1500 to communicate with other devices via a wired connection and/or a wireless connection. For example, the communication component 1560 may include a receiver, a transmitter, a transceiver, a modem, a network interface card, and/or an antenna.

The device 1500 may perform one or more operations or processes described herein. For example, a non-transitory computer-readable medium (e.g., memory 1530) may store a set of instructions (e.g., one or more instructions or code) for execution by the processor 1520. The processor 1520 may execute the set of instructions to perform one or more operations or processes described herein. In some implementations, execution of the set of instructions, by one or more processors 1520, causes the one or more processors 1520 and/or the device 1500 to perform one or more operations or processes described herein. In some implementations, hardwired circuitry may be used instead of or in combination with the instructions to perform one or more operations or processes described herein. Additionally, or alternatively, the processor 1520 may be configured to perform one or more operations or processes described herein. Thus, implementations described herein are not limited to any specific combination of hardware circuitry and software.

The number and arrangement of components shown in FIG. 15 are provided as an example. The device 1500 may include additional components, fewer components, different components, or differently arranged components than those shown in FIG. 15. Additionally, or alternatively, a set of components (e.g., one or more components) of the device 1500 may perform one or more functions described as being performed by another set of components of the device 1500.

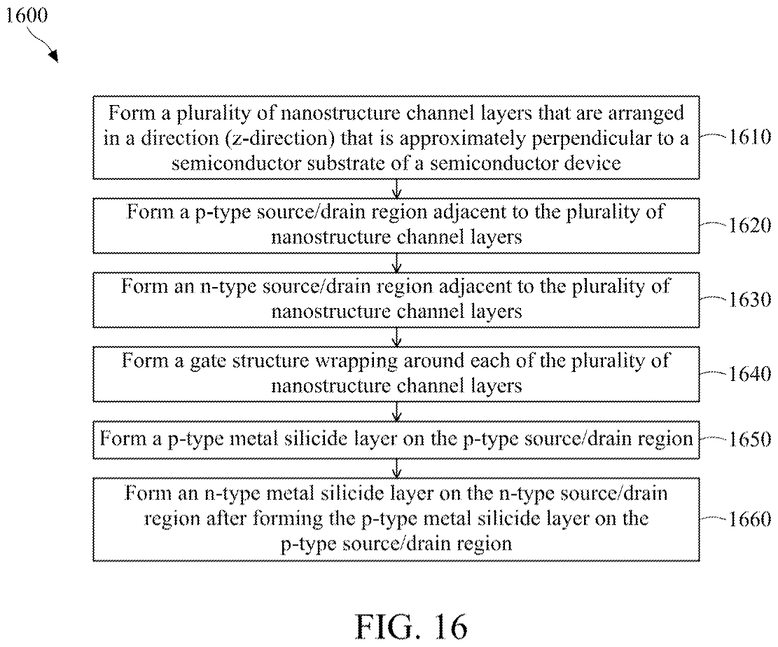

FIG. 16 is a flowchart of an example process 1600 associated with forming a semiconductor device described herein. In some implementations, one or more process blocks of FIG. 16 are performed using one or more semiconductor processing tools (e.g., one or more of the semiconductor processing tools 102-112). Additionally, or alternatively, one or more process blocks of FIG. 16 may be performed using one or more components of device 1500, such as processor 1520, memory 1530, input component 1540, output component 1550, and/or communication component 1560.

As shown in FIG. 16, process 1600 may include forming a plurality of nanostructure channel layers that are arranged in a direction (z-direction) that is approximately perpendicular to a semiconductor substrate of a semiconductor device (block 1610). For example, one or more of the semiconductor processing tools 102-112 may be used to form a plurality of nanostructure channel layers (e.g., nanostructure channels 220) that are arranged in a direction (e.g., a z-direction) that is approximately perpendicular to a semiconductor substrate (e.g., a semiconductor substrate 205) of a semiconductor device (e.g., a semiconductor device 200), as described herein.

As further shown in FIG. 16, process 1600 may include forming a p-type source/drain region adjacent to the plurality of nanostructure channel layers (block 1620). For example, one or more of the semiconductor processing tools 102-112 may be used to form a p-type source/drain region (e.g., a p-type source/drain region 225a) adjacent to the plurality of nanostructure channel layers, as described herein.

As further shown in FIG. 16, process 1600 may include forming an n-type source/drain region adjacent to the plurality of nanostructure channel layers (block 1630). For example, one or more of the semiconductor processing tools 102-112 may be used to form an n-type source/drain region (e.g., an n-type source/drain region 225b) adjacent to the plurality of nanostructure channel layers, as described herein.

As further shown in FIG. 16, process 1600 may include forming a gate structure wrapping around each of the plurality of nanostructure channel layers (block 1640). For example, one or more of the semiconductor processing tools 102-112 may be used to form a gate structure (e.g., a gate structure 240) wrapping around each of the plurality of nanostructure channel layers, as described herein.

As further shown in FIG. 16, process 1600 may include forming a p-type metal silicide layer on the p-type source/drain region (block 1650). For example, one or more of the semiconductor processing tools 102-112 may be used to form a p-type metal silicide layer (e.g., a p-type metal silicide layer 1120, a p-type metal silicide layer 1225) on the p-type source/drain region, as described herein.

As further shown in FIG. 16, process 1600 may include forming an n-type metal silicide layer on the n-type source/drain region after forming the p-type metal silicide layer on the p-type source/drain region (block 1660). For example, one or more of the semiconductor processing tools 102-112 may be used to form an n-type metal silicide layer (e.g., an n-type metal silicide layer 1125, an n-type metal silicide layer 1230) on the n-type source/drain region after forming the p-type metal silicide layer on the p-type source/drain region, as described herein.

Process 1600 may include additional implementations, such as any single implementation or any combination of implementations described below and/or in connection with one or more other processes described elsewhere herein.

In a first implementation, process 1600 includes forming a first source/drain contact (e.g., a source/drain contact 1140a, a source/drain contact 1245a) over the p-type metal silicide layer, and forming a second source/drain contact (e.g., a source/drain contact 1140b, a source/drain contact 1245b) over the n-type metal silicide layer.

In a second implementation, alone or in combination with the first implementation, forming the n-type metal silicide layer includes forming a portion of the n-type metal silicide layer on the p-type metal silicide layer, and wherein forming the first source/drain contact includes forming the first source/drain contact over the portion of the n-type metal silicide layer that is on the p-type metal silicide layer.

In a third implementation, alone or in combination with one or more of the first and second implementations, forming the n-type metal silicide layer includes forming a portion of the n-type metal silicide layer on the p-type metal silicide layer, where the process 1600 further includes removing the portion of the n-type metal silicide layer from the p-type metal silicide layer, and where forming the first source/drain contact includes forming the first source/drain contact after removing the portion of the n-type metal silicide layer from the p-type metal silicide layer.

In a fourth implementation, alone or in combination with one or more of the first through third implementations, the p-type metal silicide layer is selectively formed on the p-type source/drain region and without a masking layer over the n-type source/drain region. For example, the p-type metal silicide layer is formed such that the p-type metal silicide layer grows only on the p-type source/drain region, which enables the p-type metal silicide layer to be formed without the use of a masking layer over the n-type source/drain region. The p-type metal silicide layer may be selectively formed on the p-type source/drain region in that one or more p-type metals (e.g., iridium (Ir), ruthenium (Ru), molybdenum (Mo), rhodium (Rh), and/or niobium (Nb), among other examples) are deposited on the p-type source/drain region and annealed to react with the material of the p-type source/drain region, where the one or more p-type metals do not react (or minimally react) with the material of the n-type source/drain region.

In a fifth implementation, alone or in combination with one or more of the first through fourth implementations, process 1600 includes forming, prior to forming the p-type metal silicide layer, a masking layer (e.g., a masking layer 1220) over the n-type source/drain region, where forming the p-type metal silicide layer includes forming the p-type metal silicide layer while the masking layer protects the n-type source/drain region.

In a sixth implementation, alone or in combination with one or more of the first through fifth implementations, process 1600 includes forming a capping layer (e.g., a capping layer 1130, a capping layer 1235) on the p-type metal silicide layer and on the n-type metal silicide layer, where the p-type metal silicide layer, the n-type metal silicide layer, and the capping layer are all formed under a same vacuum (e.g., are all formed “in-situ”).

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

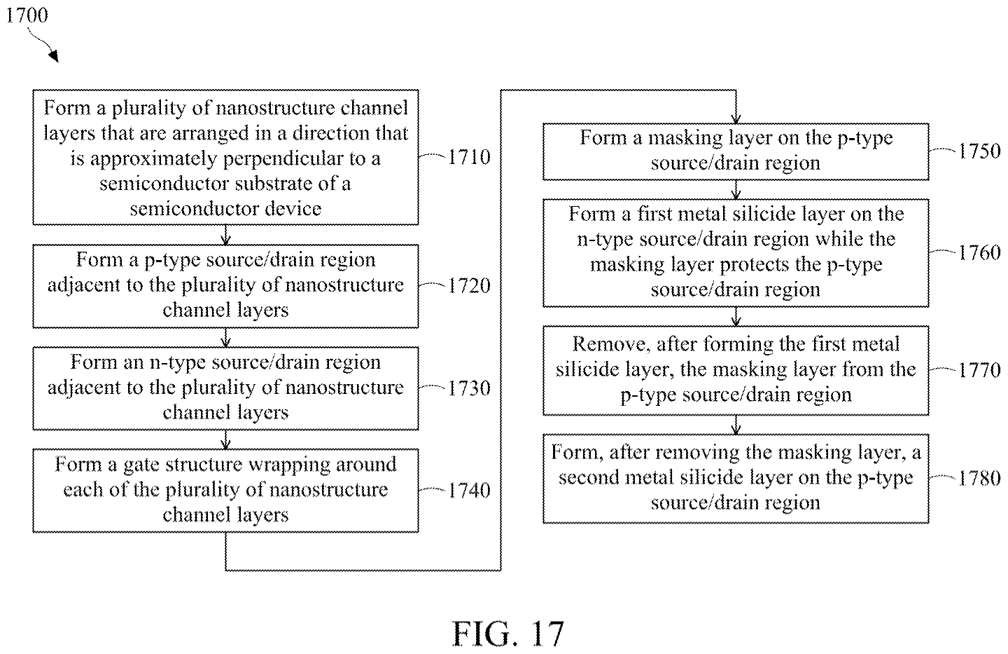

FIG. 17 is a flowchart of an example process 1700 associated with forming a semiconductor device described herein. In some implementations, one or more process blocks of FIG. 17 are performed using one or more semiconductor processing tools (e.g., one or more of the semiconductor processing tools 102-112). Additionally, or alternatively, one or more process blocks of FIG. 17 may be performed using one or more components of device 1500, such as processor 1520, memory 1530, input component 1540, output component 1550, and/or communication component 1560.

As shown in FIG. 17, process 1700 may include forming a plurality of nanostructure channel layers that are arranged in a direction that is approximately perpendicular to a semiconductor substrate of a semiconductor device (block 1710). For example, one or more of the semiconductor processing tools 102-112 may be used to form a plurality of nanostructure channel layers (e.g., nanostructure channels 220) that are arranged in a direction (e.g., a z-direction) that is approximately perpendicular to a semiconductor substrate (e.g., a semiconductor substrate 205) of a semiconductor device (e.g., a semiconductor device 200), as described herein.

As further shown in FIG. 17, process 1700 may include forming a p-type source/drain region adjacent to the plurality of nanostructure channel layers (block 1720). For example, one or more of the semiconductor processing tools 102-112 may be used to form a p-type source/drain region (e.g., a p-type source/drain region 225a) adjacent to the plurality of nanostructure channel layers, as described herein.

As further shown in FIG. 17, process 1700 may include forming an n-type source/drain region adjacent to the plurality of nanostructure channel layers (block 1730). For example, one or more of the semiconductor processing tools 102-112 may be used to form an n-type source/drain region (e.g., an n-type source/drain region 225b) adjacent to the plurality of nanostructure channel layers, as described herein.

As further shown in FIG. 17, process 1700 may include forming a gate structure wrapping around each of the plurality of nanostructure channel layers (block 1740). For example, one or more of the semiconductor processing tools 102-112 may be used to form a gate structure (e.g., a gate structure 240) wrapping around each of the plurality of nanostructure channel layers, as described herein.

As further shown in FIG. 17, process 1700 may include forming a masking layer on the p-type source/drain region (block 1750). For example, one or more of the semiconductor processing tools 102-112 may be used to form a masking layer (e.g., a masking layer 1420) on the p-type source/drain region, as described herein.

As further shown in FIG. 17, process 1700 may include forming a first metal silicide layer on the n-type source/drain region while the masking layer protects the p-type source/drain region (block 1760). For example, one or more of the semiconductor processing tools 102-112 may be used to form a first metal silicide layer (e.g., an n-type metal silicide layer 1425) on the n-type source/drain region while the masking layer protects the p-type source/drain region, as described herein. In some implementations, the first metal silicide layer comprises an n-type metal silicide.

As further shown in FIG. 17, process 1700 may include removing, after forming the first metal silicide layer, the masking layer from the p-type source/drain region (block 1770). For example, one or more of the semiconductor processing tools 102-112 may be used to remove, after forming the first metal silicide layer, the masking layer from the p-type source/drain region, as described herein.

As further shown in FIG. 17, process 1700 may include forming, after removing the masking layer, a second metal silicide layer on the p-type source/drain region (block 1780). For example, one or more of the semiconductor processing tools 102-112 may be used to form, after removing the masking layer, a second metal silicide layer (e.g., a p-type metal silicide layer 1435) on the p-type source/drain region, as described herein.

Process 1700 may include additional implementations, such as any single implementation or any combination of implementations described below and/or in connection with one or more other processes described elsewhere herein.

In a first implementation, forming the masking layer includes forming the masking layer on the p-type source/drain region and on the n-type source/drain region, and removing a first portion of the masking layer from the n-type source/drain region, where a second portion of the masking layer remains on the p-type source/drain region.

In a second implementation, alone or in combination with the first implementation, forming the second metal silicide layer includes forming the second metal silicide layer on the first metal silicide layer that is on the n-type source/drain region.

In a third implementation, alone or in combination with one or more of the first and second implementations, the second metal silicide layer includes a p-type metal silicide.

In a fourth implementation, alone or in combination with one or more of the first through third implementations, the second metal silicide layer includes a titanium silicide (TiSi) layer.

In a fifth implementation, alone or in combination with one or more of the first through fourth implementations, process 1700 includes forming a titanium silicide (TiSi) layer (e.g., a capping layer 1430) on the first metal silicide layer.

Although FIG. 17 shows example blocks of process 1700, in some implementations, process 1700 includes additional blocks, fewer blocks, different blocks, or differently arranged blocks than those depicted in FIG. 17. Additionally, or alternatively, two or more of the blocks of process 1700 may be performed in parallel.

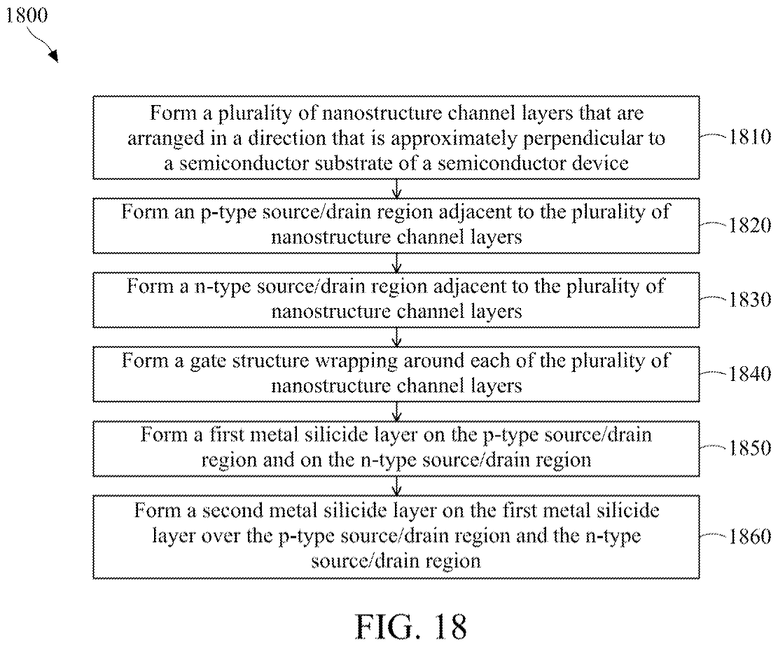

FIG. 18 is a flowchart of an example process 1800 associated with forming a semiconductor device described herein. In some implementations, one or more process blocks of FIG. 18 are performed using one or more semiconductor processing tools (e.g., one or more of the semiconductor processing tools 102-112). Additionally, or alternatively, one or more process blocks of FIG. 18 may be performed using one or more components of device 1500, such as processor 1520, memory 1530, input component 1540, output component 1550, and/or communication component 1560.

As shown in FIG. 18, process 1800 may include forming a plurality of nanostructure channel layers that are arranged in a direction that is approximately perpendicular to a semiconductor substrate of a semiconductor device (block 1810). For example, one or more of the semiconductor processing tools 102-112 may be used to form a plurality of nanostructure channel layers (e.g., nanostructure channels 220) that are arranged in a direction (e.g., a z-direction) that is approximately perpendicular to a semiconductor substrate (e.g., a semiconductor substrate 205) of a semiconductor device (e.g., a semiconductor device 200), as described herein.

As further shown in FIG. 18, process 1800 may include forming a p-type source/drain region adjacent to the plurality of nanostructure channel layers (block 1820). For example, one or more of the semiconductor processing tools 102-112 may be used to form a p-type source/drain region (e.g., a p-type source/drain region 225a) adjacent to the plurality of nanostructure channel layers, as described herein.

As further shown in FIG. 18, process 1800 may include forming an n-type source/drain region adjacent to the plurality of nanostructure channel layers (block 1830). For example, one or more of the semiconductor processing tools 102-112 may be used to form an n-type source/drain region (e.g., an n-type source/drain region 225b) adjacent to the plurality of nanostructure channel layers, as described herein.

As further shown in FIG. 18, process 1800 may include forming a gate structure wrapping around each of the plurality of nanostructure channel layers (block 1840). For example, one or more of the semiconductor processing tools 102-112 may be used to form a gate structure (e.g., a gate structure 240) wrapping around each of the plurality of nanostructure channel layers, as described herein.

As further shown in FIG. 18, process 1800 may include forming a first metal silicide layer on the p-type source/drain region and on the n-type source/drain region (block 1850). For example, one or more of the semiconductor processing tools 102-112 may be used to form a first metal silicide layer (e.g., a first metal silicide layer 1320) on the p-type source/drain region and on the n-type source/drain region, as described herein. In some implementations, the first metal silicide layer includes a first metal type.

As further shown in FIG. 18, process 1800 may include forming a second metal silicide layer on the first metal silicide layer over the p-type source/drain region and the n-type source/drain region (block 1860). For example, one or more of the semiconductor processing tools 102-112 may be used to form a second metal silicide layer (e.g., a second metal silicide layer 1325) on the first metal silicide layer over the p-type source/drain region and the n-type source/drain region, as described herein. In some implementations, the second metal silicide layer includes a second metal type that is different from the first metal type.

Process 1800 may include additional implementations, such as any single implementation or any combination of implementations described below and/or in connection with one or more other processes described elsewhere herein.

In a first implementation, the first metal type is an n-type metal and the second metal type is a p-type metal.

In a second implementation, alone or in combination with the first implementation, process 1800 includes forming a titanium silicide (TiSi) layer on the second metal silicide layer.

In a third implementation, alone or in combination with one or more of the first and second implementations, the p-type metal includes at least one of iridium (Ir), ruthenium (Ru), molybdenum (Mo), rhodium (Rh), or niobium (Nb).

In a fourth implementation, alone or in combination with one or more of the first through third implementations, the n-type metal includes at least one of antimony (Sb), zirconium (Zr), yttrium (Y), or scandium (Sc).

In a fifth implementation, alone or in combination with one or more of the first through fourth implementations, the first metal type is a p-type metal and the second metal type is an n-type metal.

In a sixth implementation, alone or in combination with one or more of the first through fifth implementations, process 1800 includes forming a titanium silicide (TiSi) layer on the second metal silicide layer.

Although FIG. 18 shows example blocks of process 1800, in some implementations, process 1800 includes additional blocks, fewer blocks, different blocks, or differently arranged blocks than those depicted in FIG. 18. Additionally, or alternatively, two or more of the blocks of process 1800 may be performed in parallel.

In this way, the techniques described herein enable respective (different) types of metal silicide layers to be formed for p-type source/drain regions and n-type source/drain regions of nanostructure transistors of a semiconductor device in a selective manner that reduces process complexity. For example, a p-type metal silicide layer may be selectively formed over a p-type source/drain region (e.g., such that the p-type metal silicide layer is not formed over the n-type source/drain region) of a first nanostructure transistor, and an n-type metal silicide layer may be formed over the n-type source/drain region (which may be selective or non-selective) of a second nanostructure transistor. This provides a low Schottky barrier height between the p-type metal silicide layer and the p-type source/drain region, as well as a low Schottky barrier height between the n-type metal silicide layer and the n-type source/drain region. This reduces the contact resistance for both p-type source/drain regions and n-type source/drain regions.

As described in greater detail above, some implementations described herein provide a method. The method includes forming a plurality of nanostructure channel layers that are arranged in a direction that is approximately perpendicular to a semiconductor substrate of a semiconductor device. The method includes forming a p-type source/drain region adjacent to the plurality of nanostructure channel layers. The method includes forming an n-type source/drain region adjacent to the plurality of nanostructure channel layers. The method includes forming a gate structure wrapping around each of the plurality of nanostructure channel layers. The method includes forming a p-type metal silicide layer on the p-type source/drain region. The method includes forming an n-type metal silicide layer on the n-type source/drain region after forming the p-type metal silicide layer on the p-type source/drain region.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes a first metal silicide layer on the p-type source/drain region and on the n-type source/drain region, where the first metal silicide layer includes a first metal type. The semiconductor device includes a second metal silicide layer on the first metal silicide layer over the p-type source/drain region and the n-type source/drain region, where the second metal silicide layer includes a second metal type that is different from the first metal type.

As described in greater detail above, some implementations described herein provide a method. The method includes forming a plurality of nanostructure channel layers that are arranged in a direction that is approximately perpendicular to a semiconductor substrate of a semiconductor device. The method includes forming a p-type source/drain region adjacent to the plurality of nanostructure channel layers. The method includes forming an n-type source/drain region adjacent to the plurality of nanostructure channel layers. The method includes forming a gate structure wrapping around each of the plurality of nanostructure channel layers. The method includes forming a masking layer on the p-type source/drain region. The method includes forming a first metal silicide layer on the n-type source/drain region while the masking layer protects the p-type source/drain region, where the first metal silicide layer comprises an n-type metal silicide. The method includes removing, after forming the first metal silicide layer, the masking layer from the p-type source/drain region. The method includes forming, after removing the masking layer, a second metal silicide layer on the p-type source/drain region.

As described in greater detail above, some implementations described herein provide a method. The method includes forming a plurality of nanostructure channel layers that are arranged in a direction that is approximately perpendicular to a semiconductor substrate of a semiconductor device. The method includes forming a p-type source/drain region adjacent to the plurality of nanostructure channel layers. The method includes forming an n-type source/drain region adjacent to the plurality of nanostructure channel layers. The method includes forming a gate structure wrapping around each of the plurality of nanostructure channel layers. The method includes forming a first metal silicide layer on the p-type source/drain region and on the n-type source/drain region, where the first metal silicide layer includes a first metal type. The method includes forming a second metal silicide layer on the first metal silicide layer over the p-type source/drain region and the n-type source/drain region, where the second metal silicide layer includes a second metal type that is different from the first metal type.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes a p-type metal silicide layer on the p-type source/drain region. The semiconductor device includes an n-type metal silicide layer on the n-type source/drain region.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes a p-type metal silicide layer on the p-type source/drain region. The semiconductor device includes an n-type metal silicide layer on the n-type source/drain region and on the p-type metal silicide layer.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes an n-type metal silicide layer on the p-type source/drain region and on the n-type source/drain region. The semiconductor device includes a p-type metal silicide layer on the n-type metal silicide layer.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes a p-type metal silicide layer on the p-type source/drain region and on the n-type source/drain region. The semiconductor device includes an n-type metal silicide layer on the p-type metal silicide layer.

As described in greater detail above, some implementations described herein provide a semiconductor device. The semiconductor device includes a plurality of nanostructure channel layers that are arranged in a direction that is approximately perpendicular to a semiconductor substrate of the semiconductor device. The semiconductor device includes a gate structure wrapping around each of the plurality of nanostructure channel layers. The semiconductor device includes a p-type source/drain region adjacent to the plurality of nanostructure channel layers. The semiconductor device includes an n-type source/drain region adjacent to the plurality of nanostructure channel layers. The semiconductor device includes an n-type metal silicide layer on the n-type source/drain region. The semiconductor device includes a p-type metal silicide layer on the p-type source/drain region and on the n-type metal silicide layer.

The terms “approximately” and “substantially” can indicate a value of a given quantity or magnitude that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channel layers that are arranged in a direction that is approximately perpendicular to a semiconductor substrate of a semiconductor device;
forming a p-type source/drain region adjacent to the plurality of nanostructure channel layers;
forming an n-type source/drain region adjacent to the plurality of nanostructure channel layers;
forming a gate structure wrapping around each of the plurality of nanostructure channel layers;
forming a p-type metal silicide layer on the p-type source/drain region; and
forming an n-type metal silicide layer on the n-type source/drain region after forming the p-type metal silicide layer on the p-type source/drain region.

2. The method of claim 1, further comprising:
forming a first source/drain contact over the p-type metal silicide layer; and
forming a second source/drain contact over the n-type metal silicide layer.

3. The method of claim 2, wherein forming the n-type metal silicide layer comprises:
forming a portion of the n-type metal silicide layer on the p-type metal silicide layer; and
wherein forming the first source/drain contact comprises:
forming the first source/drain contact over the portion of the n-type metal silicide layer that is on the p-type metal silicide layer.

4. The method of claim 2, wherein forming the n-type metal silicide layer comprises:
forming a portion of the n-type metal silicide layer on the p-type metal silicide layer;
wherein the method further comprises:
removing the portion of the n-type metal silicide layer from the p-type metal silicide layer; and
wherein forming the first source/drain contact comprises:
forming the first source/drain contact after removing the portion of the n-type metal silicide layer from the p-type metal silicide layer.

5. The method of claim 1, wherein the p-type metal silicide layer is selectively formed on the p-type source/drain region and without a masking layer over the n-type source/drain region.

6. The method of claim 1, further comprising:
forming, prior to forming the p-type metal silicide layer, a masking layer over the n-type source/drain region,
wherein forming the p-type metal silicide layer comprises:
forming the p-type metal silicide layer while the masking layer protects the n-type source/drain region.

7. The method of claim 1, further comprising:
forming a capping layer on the p-type metal silicide layer and on the n-type metal silicide layer,
wherein the p-type metal silicide layer, the n-type metal silicide layer, and the capping layer are all formed under a same vacuum.

8. A semiconductor device, comprising:
a plurality of nanostructure channel layers that are arranged in a direction that is approximately perpendicular to a semiconductor substrate of the semiconductor device;
a gate structure wrapping around each of the plurality of nanostructure channel layers;
a p-type source/drain region adjacent to the plurality of nanostructure channel layers;
an n-type source/drain region adjacent to the plurality of nanostructure channel layers;
a first metal silicide layer on the p-type source/drain region and on the n-type source/drain region,
wherein the first metal silicide layer includes a first metal type; and
a second metal silicide layer on the first metal silicide layer over the p-type source/drain region and the n-type source/drain region,
wherein the second metal silicide layer includes a second metal type that is different from the first metal type.

9. The semiconductor device of claim 8, wherein the first metal type is an n-type metal; and
wherein the second metal type is a p-type metal.

10. The semiconductor device of claim 9, further comprising:
a titanium silicide (TiSi) layer on the second metal silicide layer.

11. The semiconductor device of claim 9, wherein the p-type metal comprises at least one of:
iridium (Ir),
ruthenium (Ru),
molybdenum (Mo),
rhodium (Rh), or
niobium (Nb).

12. The semiconductor device of claim 9, wherein the n-type metal comprises at least one of:
antimony (Sb),
zirconium (Zr),
yttrium (Y), or
scandium (Sc).

13. The semiconductor device of claim 8, wherein the first metal type is a p-type metal; and
wherein the second metal type is an n-type metal.

14. The semiconductor device of claim 13, further comprising:
a titanium silicide (TiSi) layer on the second metal silicide layer.

15. A method, comprising:
forming a plurality of nanostructure channel layers that are arranged in a direction that is approximately perpendicular to a semiconductor substrate of a semiconductor device;
forming a p-type source/drain region adjacent to the plurality of nanostructure channel layers;
forming an n-type source/drain region adjacent to the plurality of nanostructure channel layers;
forming a gate structure wrapping around each of the plurality of nanostructure channel layers;
forming a masking layer on the p-type source/drain region;
forming a first metal silicide layer on the n-type source/drain region while the masking layer protects the p-type source/drain region,
wherein the first metal silicide layer comprises an n-type metal silicide;
removing, after forming the first metal silicide layer, the masking layer from the p-type source/drain region; and
forming, after removing the masking layer, a second metal silicide layer on the p-type source/drain region.

16. The method of claim 15, wherein forming the masking layer comprises:
forming the masking layer on the p-type source/drain region and on the n-type source/drain region; and
removing a first portion of the masking layer from the n-type source/drain region,
wherein a second portion of the masking layer remains on the p-type source/drain region.

17. The method of claim 15, wherein forming the second metal silicide layer comprises:
forming the second metal silicide layer on the first metal silicide layer that is on the n-type source/drain region.

18. The method of claim 15, wherein the second metal silicide layer comprises a p-type metal silicide.

19. The method of claim 15, wherein the second metal silicide layer comprises a titanium silicide (TiSi).

20. The method of claim 15, further comprising:
forming a titanium silicide (TiSi) layer on the first metal silicide layer.
